(19) United States
(12) Patent Application Publication
(10) Pub. No.: US 2026/0250462 A1
(43) Pub. Date: Aug. 27, 2026

(54) POLYIMIDE RESIN PRECURSOR

(71) Applicant: TOKYO OHKA KOGYO CO., LTD., Kawasaki-shi (JP)

(72) Inventors: Kazuaki EBISAWA, Kawasaki-shi (JP); Makiko IRIE, Kawasaki-shi (JP)

(21) Appl. No.: 18/870,059

(22) PCT Filed: Apr. 28, 2023
(86) PCT No.: PCT/JP2023/016823

§ 371 Date: Nov. 27, 2024

(30) Foreign Application Priority Data
Jun. 2, 2022 (JP) 2022-090501

(51) Int. Cl. C08G 73/12; G03F 7/028; G03F 7/16

(52) U.S. Cl. CPC C08G 73/127; G03F 7/028; G03F 7/168

(57) ABSTRACT

A polyimide resin precursor that yields a polyimide resin having a low dielectric loss tangent and yields a photosensitive resin composition having exceptional photolithography properties, a photosensitive resin composition including the polyimide resin precursor as a polymerizable resin, a patterned resin film in which the photosensitive resin composition is used, and a method for producing a patterned polyimide resin film. The polyimide resin precursor has, in a side chain thereof, an unsaturated group having 3 or more and 30 or less carbon atoms that is free of (meth)acryloyl groups and has one or more ethylenically unsaturated double bonds, and optionally having, in a side chain, a (meth)acryloyl-group-containing group, wherein the number of mol of the unsaturated group and the number of mol of the (meth)acryloyl-group-containing group in the side chains are each within a prescribed range.

### TECHNICAL FIELD

The present invention relates to a polyimide resin precursor, a photosensitive resin composition including the polyimide resin precursor, a patterned resin film using the photosensitive resin composition, and a production method for the patterned polyimide resin film.

### BACKGROUND ART

Polyimide resins and polyamide resins have properties such as excellent heat resistance, mechanical strength, insulation, and low dielectric constant. Therefore, polyimide resins and polyamide resins are widely used as insulating materials and protective materials in various devices and electrical and/or electronic components such as electronic boards such as multilayer wiring boards.

In recent years, communication equipment such as mobile phones are increasingly using higher frequencies. Therefore, the insulating parts that insulate the metal wiring included in communication equipment are also required to correspond to higher frequencies. Here, the higher the frequency is, the greater the transmission loss becomes. As the transmission loss increases, electrical signals are attenuated.

Accordingly, in order to further reduce transmission loss to correspond to higher frequencies, resins such as a polyimide resin and a polyamide resin are required to have a lower dielectric loss tangent and a lower dielectric constant in a high frequency band.

In view of the above requirements, as a composition capable of forming a resin film exhibiting good dielectric properties in a high frequency band, a photosensitive resin composition (see Patent Document 1, Examples) including an aromatic polyamide resin having a specific structure having a structural unit including a 4,4′-dioxybiphenyl skeleton derived from 4,4′-bis(4-aminophenoxy)biphenyl and a photopolymerization initiating agent has been proposed,

### CITATION LIST

### Patent Document

Patent Document 1: PCT International Publication No. WO2019/044874

### DISCLOSURE OF THE INVENTION

### Problems to be Solved by the Invention

When a photosensitive resin composition described in Patent Document 1 is used, a polyimide resin film with a somewhat low dielectric loss tangent can be formed. Meanwhile, the photosensitive resin composition described in Patent Document 1 is required to further improve the photolithographic properties.

The present invention was made in view of the above problems, and has an object to provide a polyimide resin precursor that gives a polyimide resin having a low dielectric loss tangent and a photosensitive resin composition having excellent photolithographic properties, a photosensitive resin composition including the polyimide resin precursor as a polymerizable resin (A), a patterned resin film made of the photosensitive resin composition, and a method for producing the patterned polyimide resin film.

### Means for Solving the Problems

The present inventors have found that the above-mentioned problems can be solved by a polyimide resin precursor including an unsaturated group G1 having 3 or more and 30 or less carbon atoms that does not include a (meth)acryloyl group but includes one or more ethylenically unsaturated double bonds in a side chain, and optionally including a (meth)acryloyl group-containing group G2 in a side chain, in which the number of moles of the unsaturated group G1 and the number of moles of the (meth)acryloyl group-containing group G2 in each side chain are controlled within predetermined ranges, respectively, and have completed the present invention. More specifically, the present invention provides the followings.

A first aspect of the present invention is a polyimide resin precursor comprising a structural unit represented by the following formula (1):

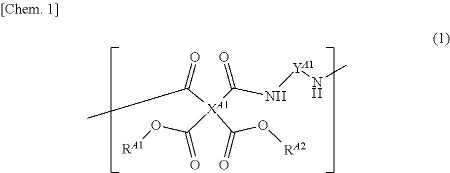

Wherein, in the formula (1), X^{A1} and Y^{A1} are organic groups having 4 or more and 40 or less carbon atoms,
R^{A1} and R^{A2} are each independently a hydrogen atom or an organic group having 1 or more and 30 or less carbon atoms, and the organic group as R^{A1} or R^{A2} bonds to an oxygen atom in an ester bond in the formula (1) through a C—O bond,
having the organic group as R^{A1} or R^{A2} are an unsaturated group G1 having 3 or more and 30 or less carbon atoms that does not include a (meth)acryloyl group but includes one or more ethylenically unsaturated double bonds, and the organic group as R^{A1} or R^{A2} optionally include a (meth)acryloyl group-containing group G2,
in the whole structural units, the proportion of the sum of the number of moles of the unsaturated group G1 and the number of moles of the (meth)acryloyl group-containing group G2 to the total number of moles of the organic groups as R^{A1} and R^{A2} is 60 mol % or more, and
in the whole structural units, the proportion of the number of moles of the unsaturated group G1 to the total number of moles of the organic groups as RA and R^{A2} is 10 mol % or more.

A second aspect of the present invention is a photosensitive resin composition including a polymerizable resin (A), a photoradical polymerization initiating agent (C), a solvent(S), wherein the polymerizable resin (A) is the polyimide resin precursor according to the first aspect.

A third aspect of the present invention is a production method for a patterned resin film, the method including: applying a photosensitive resin composition according to the second aspect onto a substrate to form a coating film, position-selectively exposing the coating film, and developing the coating film exposed.

A fourth aspect of the present invention is a production method for a patterned polyimide resin film, the method including heating the patterned resin film produced by the production method according to the third aspect, for generating the polyimide resin derived from the polyimide resin precursor.

### Effects of the Invention

According to the present invention, it is possible to provide a polyimide resin precursor that gives a polyimide resin having a low dielectric loss tangent and a photosensitive resin composition having excellent photolithographic properties, a photosensitive resin composition including the polyimide resin precursor as a polymerizable resin (A), a patterned resin film made of the photosensitive resin composition, and a method for producing the patterned polyimide resin film.

### PREFERRED MODE FOR CARRYING OUT THE INVENTION

### <<Polyimide Resin Precursor>>

The polyimide resin precursor comprises a structural unit represented by the following formula (1).

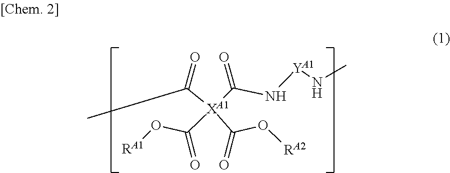

In the formula (1), X^{A1} and Y^{A1} are organic groups having 4 or more and 40 or less carbon atoms. R^{A1} and R^{A2} are each independently a hydrogen atom or an organic group having 1 or more and 30 or less carbon atoms. The organic group as R^{A1} or R^{A2} bonds to an oxygen atom in an ester bond in the formula (1) through a C—O bond.

The polyimide resin precursor includes, as the organic group as R^{A1} or R^{A2}, an unsaturated group G1 and optionally includes a (meth)acryloyl group-containing group G2. The unsaturated group G1 is an organic group having 3 or more and 30 or less carbon atoms that does not include a (meth)acryloyl group but includes one or more ethylenically unsaturated double bonds.

In the polyimide resin precursor, the proportion of the sum of the number of moles of the unsaturated group G1 and the number of moles of the (meth)acryloyl group-containing group G2 to the total number of moles of the organic groups as R^{A1} and R^{A2} in the whole structural units is 60 mol % or more.

In the polyimide resin precursor, the proportion of the number of moles of the unsaturated group G1 to the total number of moles of the organic groups as RA and R^{A2} in the whole structural units is 10 mol % or more.

The polyimide resin precursor gives a polyimide resin having a low dielectric loss tangent and gives a photosensitive resin composition having excellent photolithographic properties.

The polyimide resin precursor is typically a polymer of a diamine compound and a dicarboxylic acid that is a reactant of a tetracarboxylic acid dianhydride and an alcohol. However, the diamine compound, the dicarboxylic acid, the tetracarboxylic acid dianhydride, and the alcohol are selected such that the polyimide resin precursor satisfies the above predetermined requirements.

### [Diamine Compound]

The diamine compound is represented by the following formula (A2).

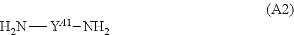

Wherein, In the formula (A2), Y^{A1} represents a divalent organic group.

Y^{A1} is a divalent organic group having 4 or more and 40 or less carbon atoms. A¹ may have one or a plurality of substituents in addition to the two amino groups. Suitable examples of the substituent preferably include a fluorine atom, an alkyl group having 1 or more and 6 or less carbon atoms, an alkoxy group having 1 or more and 6 or less carbon atoms, a fluorinated alkyl group having 1 or more and 6 or less carbon atoms, a fluorinated alkoxy group having 1 or more and 6 or less carbon atoms, a carboxy group, or a hydroxy group. When the substituent is a fluorinated alkyl group or a fluorinated alkoxy group, the substituent is preferably a perfluoroalkyl group or a perfluoroalkoxy group.

A lower limit of the number of carbon atoms in the organic group as Y^{A1} is preferably 4, and more preferably 6, and an upper limit is preferably 50, and more preferably 30. Y^{A1} may be an aliphatic group. A¹ is preferably an organic group including 1 or more aromatic rings.

When Y^{A1} is an organic group including one or more aromatic rings, the organic group may be one aromatic group itself, and may be a group in which two or more aromatic groups are bonded to each other via an aliphatic hydrocarbon group and a halogenated aliphatic hydrocarbon group, or a bond including a heteroatom such as an oxygen atom, a sulfur atom, or a nitrogen atom. Examples of the bond including a heteroatom such as an oxygen atom, a sulfur atom, or a nitrogen atom included in Y^{A1} include —CONH—, —NH—, —N═N—, —CH═N—, —COO—, —O—, —CO—, —SO—, —SO₂—, —S—, —S—S—, and the like, and —COO—, —O—, —CO—, and —S— are preferable.

The aromatic ring in Y^{A1} that is bonded to the amino group is preferably a benzene ring. When the ring bonded to the amino group in Y^{A1} is a condensed ring including two or more rings, the ring bonded to the amino group in the condensed ring is preferably a benzene ring. Furthermore, the aromatic ring included in Y^{A1} may be an aromatic heterocycle.

When Y^{A1} is an organic group including an aromatic ring, from the viewpoint of improving the electrical properties and mechanical properties of a polyimide resin formed using a polyimide resin precursor (A), the organic group is preferably at least one type of the groups represented by the following formulae (21) to (24).

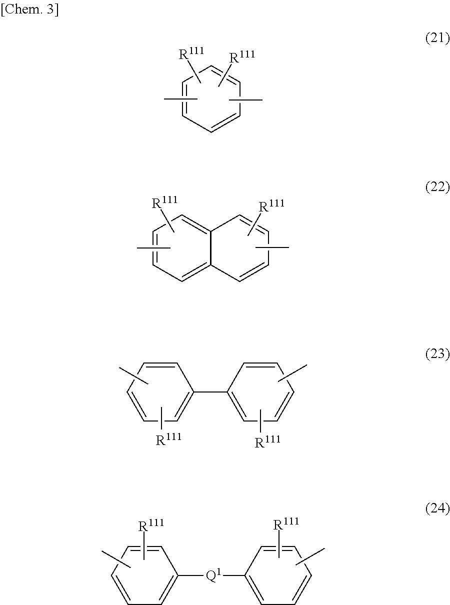

In (21) to (24), R¹¹¹ represents one selected from the group consisting of a hydrogen atom, a fluorine atom, a carboxy group, a sulfonic acid group, a hydroxy group, an alkyl group having 1 or more and 4 or less carbon atoms, and a halogenated alkyl group having 1 or more and 4 or less carbon atoms. In the formula (24), Q′ represents one selected from the group consisting of a 9,9′-fluorenylidene group, or groups represented by the formulae: —C₆H₄—, —C₆H₄—C₆H₄—, —O—C₆H₄—C₆H₄—O—, —O—C₆H₄—CO—C₆H₄—O—, —O—C₆H₄—C(CH₃)₂—C₆H₄—O—, —OCO—CH₄—COO—, —OCO—C₆H₄—C₆H₄—COO—, —OCO—, —O—, —CO—, —C(CF₃)₂—, —C(CH₃)₂—, —CH₂—, —O—C₆H₄—SO₂—C₆H₄—O—, —C(CH₃)₂—C₆H₄—C(CH₃)₂″>—O—C₁₀H₆—O—, —O—C₆H₄—O—, —O—CH₂—O—, and —O—(CH₂)ₙ—O—.

—C₆H₄— in the examples of Q¹ is a phenylene group. As the phenylene group, an m-phenylene group and a p-phenylene group are preferable, and a p-phenylene group is more preferable. Furthermore, —C₁₀H₆— is a naphthalenediyl group. As the naphthalenediyl group, a naphthalene-1,2-diyl group, a naphthalene-1,4-diyl group, a naphthalene-2,3-diyl group, a naphthalene-2,6-diyl group, and a naphthalene-2,7-diyl group are preferable, and a naphthalene-1,4-diyl group and a naphthalene-2,6-diyl group are more preferable. In the example of Q¹, n is an integer of 1 or more, preferably an integer of 1 or more and 20 or less, more preferably an integer of 1 or more and 12 or less, and even more preferably an integer of 1 or more and 6 or less.

As the diamine compound including a group represented by the formula (24) as Y^{A1}, a compound represented by the following formula (a2) is preferable. n in the formula (a2) is as described for Q¹ in the formula (24).

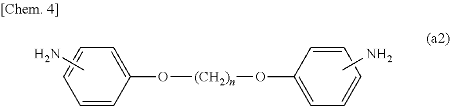

From the viewpoint of improving the electrical properties of the resin film formed, R¹¹¹ in the formulae (21) to (24) is more preferably a hydrogen atom, a fluorine atom, a methyl group, an ethyl group, or a trifluoromethyl group, and a hydrogen atom or a trifluoromethyl group is particularly preferable.

From the viewpoint of electrical properties and mechanical properties of the resin film to be formed, as Q¹ in the formula (24), —C₆H₄—C₆H₄—, —O—C₆H₄—C₆H₄—O—, —O—C₆H₄—CO—C₆H₄—O—, —O—C₆H₄—C(CH₃)₂—C₆H₄—O—, —OCO—C₆H₄—COO—, —OCO—C₆H₄—C₆H₄—COO—, —OCO—, —O—, —CO—, —C(CF₃)₂—, —C(CH₃)₂—, —CH₂—, —O—C₆H₄—SO₂—CH₄—O—, C(CH₃)₂—C₆H₄—C(CH₃)₂—, —O—C₁₀H₆—O—, —O—C₆H₄—O—, —O—CH₂—O—, —O—(CH₂)₂—O—, —O—(CH₂)₃—O—, —O—(CH₂)₄—O—, —O—(CH₂)₅—O—, and —O—(CH₂)₆—O— are preferable. From the viewpoint of improvement of electrical properties and mechanical properties of resin formed using the polyimide resin precursor, as Q¹ in the formula (24), —O—C₆H₄—C₆H₄—O—, —O—C₆H₄—C(CH₃)₂—C₆H₄—O— are more preferable, and a group represented by —O—C₆H₄—C₆H₄—O— and in which both —C₆H₄— are a p-phenylene group is particularly preferable.

When an aromatic diamine compound is used as a diamine compound represented by the formula (A2), for example, the below mentioned aromatic diamine compounds can be suitably used. Thus, examples of the aromatic diamine compound include p-phenylenediamine, m-phenylenediamine, 2,4-diaminotoluene, 4,4′-diaminobiphenyl, 3,3′-diaminobiphenyl, 3,4′-diaminobiphenyl, 1,5-diaminonaphthalene, 2,6-diaminonaphthalene, 9,10-diaminoanthracene, 9,10-bis(4-aminophenyl)anthracene, 4,4′-diamino-2,2′-bis(trifluoro methyl)biphenyl, 4,4′-diaminobenzophenone, 3,3′-diaminobenzophenone, 3,4′-diaminobenzophenone, 4,4′-diaminodiphenylsulfone, 3,3′-diaminodiphenylsulfone, 3,4′-diaminodiphenylsulfone, 4,4′-diaminodiphenyl sulfide, 3,3′-diaminodiphenyl sulfide, 3,4′-diaminodiphenyl sulfide, 4,4′-diaminodiphenylmethane, 3,3′-diaminodiphenylmethane, 3,4′-diaminodiphenylmethane, 2,2-bis(4-aminophenyl)propane, bis(3-amino-4-hydroxyphenyl)methane, 2,2-bis(3-amino-4-hydroxyphenyl)propane, 2,2-bis[4-(4-aminophenoxy)phenyl]propane, 2,2-bis[4-(4-aminophenoxy)phenyl]hexafluoropropane, 2,2′-bis[N-(3-amino benzoyl)-3-amino-4-hydroxyphenyl]propane, 2,2′-bis[N-(4-aminobenzoyl)-3-amino-4-hydroxyphenyl]propane, 4,4′-diaminodiphenyl ether, 3,4′-diaminodiphenyl ether, 3,3′-diaminodiphenyl ether, 3-carboxy-4,4′-diaminodiphenyl ether, 3-sulfo-4,4′-diaminodiphenyl ether, 4,4′-diaminobenzanilide, 3,3′-diaminobenzanilide, 1,4-bis(4-aminophenyl)benzene, 1,3-bis(4-aminophenyl)benzene, 1,4-bis(4-aminophenoxy)benzene, 1,3-bis(4-aminophenoxy)benzene, 1,3-bis(3-aminophenoxy)benzene, 1,2-bis(4-aminophenoxy)ethane, 1,3-bis(4-aminophenoxy)propane, 1,4-bis(4-aminophenoxy)butane, 1,5-bis(4-aminophenoxy)pentane, 1,6-bis(4-aminophenoxy)hexane, bis(3-amino-4-hydroxyphenyl)ether, bis[4-(4-aminophenoxy phenyl]ether, bis[4-(3-aminophenoxy)phenyl]ether, 4,4′-bis(4-aminophenoxy)biphenyl, 3,4′-bis(4-aminophenoxy)biphenyl, 3,3′-bis(4-aminophenoxy)biphenyl, bis(3-amino-4-hydroxyphenyl)sulfone, bis(4-aminophenoxyphenyl)sulfone, bis(3-aminophenoxyphenyl))sulfone, bis[4-(4-aminophenoxy)phenyl]sulfone, bis[4-(3-aminophenoxy)phenyl]sulfone, bis[N-(3-aminobenzoyl)-3-amino-4-hydroxyphenyl]sulfone, bis[N-(4-aminobenzoyl)-3-amino-4-hydroxyphenyl]sulfone, bis[4-(4-aminophenoxy)phenyl]ketone, 2,2-bis[4-{4-amino-2-(trifluoromethyl) phenoxy}phenyl]hexafluoropropane, 9,9-bis(4-aminophenyl) fluorene, 9,9-bis(4-amino-3-methylphenyl) fluorene, 9,9-bis(3-amino-4-hydroxyphenyl) fluorene, 9,9-bis[N-(3-aminobenzoyl)-3-amino-4-hydroxyphenyl]fluorene, 9,9-bis[N-(4-aminobenzoyl)-3-amino-4-hydroxyphenyl]fluorene, 2,7-diaminofluorene, 2-(4-aminophenyl)-5-aminobenzoxazole, 2-(3-aminophenyl)-5-aminobenzoxazole, 2-(4-aminophenyl)-6-aminobenzoxazole, 2-(3-aminophenyl)-6-aminobenzoxazole, 1,4-bis(5-amino-2-benzoxazolyl)benzene, 1,4-bis(6-amino-2-benzoxazolyl)benzene, 1,3-bis(5-amino-2-benzoxazolyl)benzene, 1,3-bis(6-amino-2-benzoxazolyl)benzene, 2,6-bis(4-aminophenyl)benzobisoxazole, 2,6-bis(3-aminophenyl)benzobisoxazole, bis[(3-aminophenyl)-5-benzoxazolyl], bis[(4-aminophenyl)-5-benzoxazolyl], bis[(3-aminophenyl)-6-benzoxazolyl], bis[(4-aminophenyl)-6-benzoxazolyl], N,N′-bis(3-aminobenzoyl)-2,5-diamino-1,4-dihydroxybenzene, N,N′-bis(4-aminobenzoyl)-2,5-diamino-1,4-dihydroxybenzene, N,N′-bis(4-aminobenzoyl)-4,4′-diamino-3,3-dihydroxybiphenyl, N,N′-bis(3-aminobenzoyl)-3,3′-diamino-4,4-dihydroxybiphenyl, N,N′-bis(4-aminobenzoyl)-3,3′-diamino-4,4-dihydroxybiphenyl, 3,4′-diaminodiphenyl sulfide, 4,4′-diaminodiphenyl sulfide, 4,4′-[1,4-phenylenebis(1-methylethane-1,1-diyl)]dianiline, 3,5-diaminobenzoic acid, 3,4-diaminobenzoic acid, 4-aminobenzoic acid 4-aminophenyl ester, 1,3-bis(4-anilino)tetramethyldisiloxane, 1,4-bis(3-aminopropyldimethylsilyl)benzene, ortho-tolidinesulfone, and the like. Among these, from the viewpoint of improving the electrical properties and mechanical properties, 4,4′-bis(4-aminophenoxy)biphenyl, 3,4′-bis(4-aminophenoxy)biphenyl, and 3,3′-bis(4-aminophenoxy)biphenyl are preferable.

Furthermore, as YA, a silicon atom-containing group which may have a chain aliphatic group and/or an aromatic ring can be employed. As such a silicon atom-containing group, typically, the groups shown below can be used.

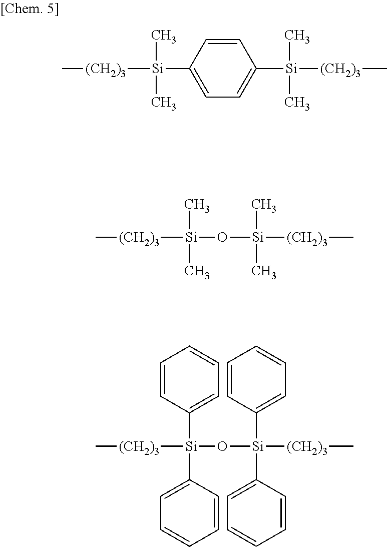

Specific examples of compounds having amino groups at both ends and a silicon atom-containing group include methylphenyl silicone modified with amino at both ends (for example, X-22-1660B-3 (number average molecular weight of about 4, 400) and X-22-9409 (number average molecular weight of about 1, 300) manufactured by Shin-Etsu Chemical Co., Ltd.), dimethyl silicone modified with amino at both ends (for example, X-22-161A (number average molecular weight of about 1, 600), X-22-161B (number average molecular weight of about 3,000), and KF8012 (number average molecular weight of about 4, 400) manufactured by Shin-Etsu Chemical Co., Ltd.; BY16-835U (number average molecular weight of about 900) manufactured by Dow Corning Toray Co., Ltd.; and Silaplane FM3311 (number average molecular weight of about 1,000) manufactured by JNC CORPORATION), and the like.

Furthermore, as the diamine compound represented by formula (A2), a diamine having an oxyalkylene group can also be preferably used. Preferable examples of the oxyalkylene group include an ethyleneoxy group, a propyleneoxy group (—C(CH₃)—CH₂—O—, —CH₂—C(CH₃)—O—, or —CH₂CH₂CH₂—O—). Diamine having an oxyalkylene group may include a combination of two or more types of oxyalkylene groups. When the diamine having an oxyalkylene group includes two or more types of oxyalkylene groups, the two or more types of oxyalkylene groups may be included in the diamine as a block or may be included in the diamine randomly. The diamine having an oxyalkylene group preferably does not contain a cyclic group, and more preferably does not contain an aromatic group. Specific examples of diamines having an oxyalkylene group include Jeffamine (registered trademark) KH-511, Jeffamine (registered trademark) ED-600, Jeffamine (registered trademark) ED-900, Jeffamine (registered trademark) ED-2003, Jeffamine (registered trademark) EDR-148, Jeffamine (registered trademark) EDR-176, Jeffamine (registered trademark) D-200, Jeffamine (registered trademark) D-400, Jeffamine (registered trademark) D-2000, and Jeffamine (registered trademark) D-4000, all manufactured by HUNTSUMAN, as well as 1-(2-(2-(2-aminopropoxy)ethoxy)propoxy)propan-2-amine, and 1-(1-(1-(2-aminopropoxy)propan-2-yl)oxy)propan-2-amine and the like.

Since the solubility of the polyimide resin precursor in an organic solvent and the dielectric properties of a polyimide resin formed using the polyimide resin precursor in a high frequency band are excellent, the diamine compound preferably includes one or more selected from the group consisting of a diamine compound (A-1) represented by a formula (A2) in which Y^{A1} is a group represented by a formula (A1-1) below, a diamine compound (A-2) represented by a formula (A2) in which Y^{A1} has a partial structure represented by a formula (A2-1) described later and not corresponding to the diamine compound (A-1), a diamine compound (A-3) having a partial structure represented by a formula (A3) described later and not corresponding to the diamine compound (A-1) and the diamine compound (A-2), and a dimer diamine compound (A-4). Among these compounds, the diamine compound (A-1) and the diamine compound (A-2) are preferable.

### (Diamine Compound (A-1))

The diamine compound (A-1) is a diamine compound represented by the formula (A2) in which Y^{A1} is a group represented by the following formula (A1-1).

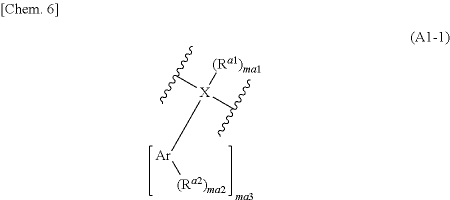

In the formula (A1-1), X is an organic group having 1 or more and 100 or less carbon atoms. R^{a1} is a hydroxy group, a carboxy group, or a halogen atom. R^{a2} is an aliphatic group having 1 or more and 20 or less carbon atoms, a hydroxy group, a carboxy group, a sulfonic acid group, or a halogen atom. Ar is a phenyl group optionally substituted with R=2 or a naphthyl group optionally substituted with R^{a2}.
ma1 is an integer of 0 or more and 10 or less.
ma2 is an integer of 0 or more and 7 or less.
ma3 is an integer of 1 or more and 10 or less.

In the formula (A1-1), Ar is a phenyl group which may be substituted with R^{a2} or a naphthyl group which may be substituted with R^{a2}, Ar is preferably a phenyl group or a naphthyl group. In other words, in the formula (A1-1), ma2 is preferably 0.

In the formula (A1-1), R^{a2} is an aliphatic group having 1 or more and 20 or less carbon atoms, a hydroxy group, a carboxy group, a sulfonic acid group, or a halogen atom. The organic group as R^{a2} may include a hetero atom such as O, N, S, P, B, Si, and a halogen atom. The number of carbon atoms in the aliphatic group as R^{a2} is preferably 1 or more and 12 or less, and more preferably 1 or more and 6 or less.

Aliphatic groups as R^{a2} include, chain alkyl groups such as a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, 2-ethylhexyl group, an n-nonyl group, an n-decyl group, an n-undecyl group, an n-tridecyl group, an n-tetradecyl group, an n-pentadecyl group, an n-hexadecyl group, an n-heptadecyl group, an n-octadecyl group, an n-nonadecyl group, and an n-icosyl group; chain alkenyl groups such as a vinyl group, a 1-propenyl group, a 2-n-propenyl group (allyl group), a 1-n-butenyl group, a 2-n-butenyl group, and a 3-n-butenyl group; cycloalkyl groups such as a cyclopropyl group, a cyclobutyl group, a cyclopentyl group, a cyclohexyl group, and a cycloheptyl group; halogenated chain alkyl groups such as a chloromethyl group, a dichloromethyl group, a trichloromethyl group, a bromomethyl group, a dibromomethyl group, a tribromomethyl group, a fluoromethyl group, a difluoromethyl group, a trifluoromethyl group, a 2,2,2-trifluoroethyl group, a pentafluoroethyl group, a heptafluoropropyl group, a perfluorobutyl group, a perfluoropentyl group, a perfluorohexyl group, a perfluoroheptyl group, a perfluorooctyl group, a perfluorononyl group, and a perfluorodecyl group; halogenated cycloalkyl groups such as a 2-chlorocyclohexyl group, a 3-chlorocyclohexyl group, a 4-chlorocyclohexyl group, a 2,4-dichlorocyclohexyl group, a 2-bromocyclohexyl group, a 3-bromocyclohexyl group, and a 4-bromocyclohexyl group; hydroxy chain alkyl groups such as a hydroxymethyl group, a 2-hydroxyethyl group, a 3-hydroxy-n-propyl group, and a 4-hydroxy-n-butyl group; hydroxycycloalkyl groups such as a 2-hydroxycyclohexyl group, a, 3-hydroxycyclohexyl group, and a 4-hydroxycyclohexyl group; chain alkoxy groups such as a methoxy group, an ethoxy group, an n-propoxy group, an isopropoxy group, an n-butyloxy group, an isobutyloxy group, a sec-butyloxy group, a tert-butyloxy group, an n-pentyloxy group, an n-hexyloxy group, an n-heptyloxy group, an n-octyloxy group, a 2-ethylhexyloxy group, an n-nonyloxy group, an n-decyloxy group, an n-undecyloxy group, an n-tridecyloxy group, an n-tetradecyloxy group, an n-pentadecyloxy group, an n-hexadecyloxy group, an n-heptadecyloxy group, an n-octadecyloxy group, an n-nonadecyloxy group, and an n-icosyloxy group; chain alkenyloxy groups such as a vinyloxy group, a 1-propenyloxy group, a 2-n-propenyloxy group (allyloxy group), a 1-n-butenyloxy group, a 2-n-butenyloxy group, and a 3-n-butenyloxy group; alkoxyalkyl groups such as a methoxymethyl group, an ethoxymethyl group, an n-propoxymethyl group, a 2-methoxyethyl group, a 2-ethoxyethyl group, a 2-n-propoxyethyl group, a 3-methoxy-n-propyl group, a 3-ethoxy-n-propyl group, a 3-n-propoxy-n-propyl group, a 4-methoxy-n-butyl group, a 4-ethoxy-n-butyl group, and a 4-n-propoxy-n-butyl group; alkoxyalkoxy groups such as a methoxymethoxy group, an ethoxymethoxy group, an n-propoxymethoxy group, a 2-methoxyethoxy group, a 2-ethoxyethoxy group, a 2-n-propoxyethoxy group, a 3-methoxy-n-propoxy group, a 3-ethoxy-n-propoxy group, a 3-n-propoxy-n-propoxy group, a 4-methoxy-n-butyloxy group, a 4-ethoxy-n-butyloxy group, and a 4-n-propoxy-n-butyloxy group; aliphatic acyl groups such as a formyl group, an acetyl group, a propionyl group, a butanoyl group, a pentanoyl group, a hexanoyl group, a heptanoyl group, an octanoyl group, a nonanoyl group, and a decanoyl group; chain alkyloxycarbonyl groups such as a methoxycarbonyl group, an ethoxycarbonyl group, an n-propoxycarbonyl group, an n-butyloxycarbonyl group, an n-pentyloxycarbonyl group, an n-hexylcarbonyl group, an n-heptyloxycarbonyl group, an n-octyloxycarbonyl group, an n-nonyloxycarbonyl group, and an n-decyloxycarbonyl group; aliphatic acyloxy groups such as a formyloxy group, an acetyloxy group, a propionyloxy group, a butanoyloxy group, a pentanoyloxy group, a hexanoyloxy group, a heptanoyloxy group, an octanoyloxy group, a nonanoyloxy group, and a decanoyloxy group.

In the formula (A1), ma3 is an integer of 1 or more and 10 or less. The value of ma3 is not particularly limited as long as the value is 1 or more and 10 or less, and can be appropriately selected depending on the structure of X, The value of ma3 is preferably 1 or more and 4 or less, and more preferably 1 or 2.

In the formula (A1-1), X is an organic group having 1 or more and 100 or less carbon atoms. The number of carbon atoms in the organic group as X is preferably 2 or more and 80 or less, and more preferably 6 or more and 50 or less. The organic group as X may include a heteroatom such as O, N, S, P, B, Si, or a halogen atom. Note here that in the compound represented by the formula (A1-1), two amino groups are each bonded to a carbon atom in the organic group as X.

The organic group as X may be an aliphatic group, an aromatic group, or a combination of an aliphatic group and an aromatic group. The organic group as X may be a group bonded via a bond including a heteroatom such as an oxygen atom, a sulfur atom, or a nitrogen atom. The bond including a heteroatom such as an oxygen atom, a sulfur atom, or a nitrogen atom included in the organic group as X include-CONH—, —NH—, —N═N—, —CH═N—, —COO—, —O—, —CO—, —SO—, —SO₂—, —S—, —S—S—, and the like, and —O—, —CO—, and —S— are preferable.

When the organic group as X is an aliphatic group, the aliphatic group may be a saturated aliphatic group or an unsaturated aliphatic group. When the organic group as X is an aliphatic group, the aliphatic group is preferably an aliphatic hydrocarbon group. When the organic group as X is an aliphatic group, the aliphatic group may be a chain or a cyclic group, or a combination of a chain aliphatic group and a cyclic aliphatic group. The chain aliphatic group may have a branch.

When the organic group as X is an aliphatic group, the aliphatic group is preferably a group obtained by removing (ma1+ma3+2) hydrogen atoms from an alkylene group having 1 to 20 carbon atoms, more preferably a group obtained by removing (ma1+ma3+2) hydrogen atoms from an alkylene group having 1 to 16 carbon atoms, and further preferably a group obtained by removing (ma1+ma3+2) hydrogen atoms from an alkylene group having 1 to 12 carbon atoms.

When the organic group as X is a group including an aromatic group, the groups composed of X, Ar, R^{a1}, and R^{a2} in the formula (A1-1) include the following formulae (11) to (15).

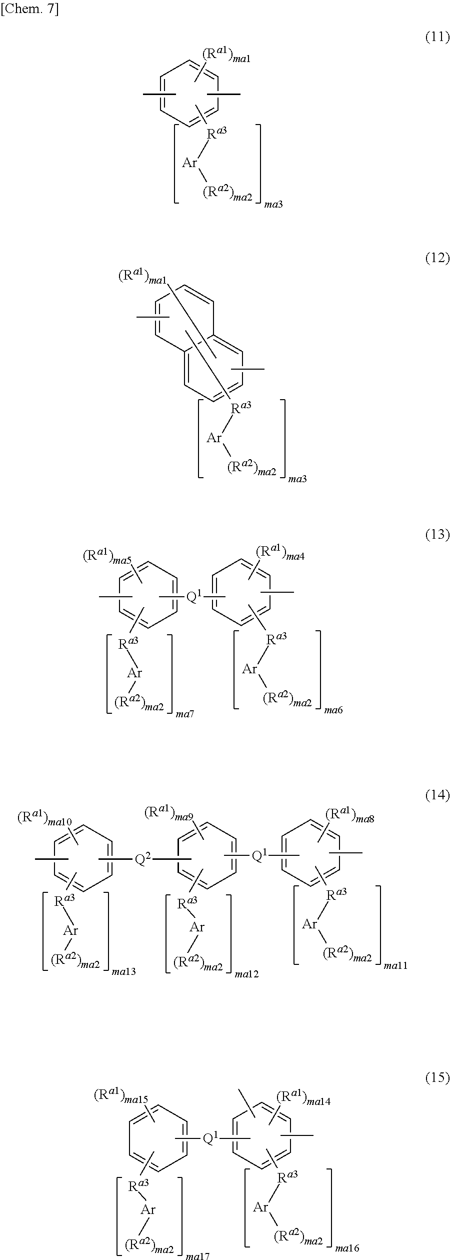

In the formulae (11) to (15), Ar, R^{a1}, R^{a2}, ma1, ma2, and ma3 are the same as those in the formula (A1). In the formula (13), ma4 and ma5 are each independently an integer of 0 or more and 4 or less. ma6 and ma7 are each independently an integer of 0 or more and 4 or less. The sum of ma6 and ma7 is 1 or more and 8 or less. In the formula (14), ma8, ma9, and ma10 are each independently an integer of 0 or more and 4 or less. The sum of ma8, ma9, and ma10 is 0 or more and 10 or less. ma11, ma12, and ma13 are each independently an integer of 0 or more and 4 or less. The sum of ma11, ma12, and ma13 is 1 or more and 10 or less. In the formula (15), ma14 is an integer of 0 or more and 3 or less. ma15 is an integer of 0 or more and 5 or less. The sum of ma14 and ma15 is 0 or more and 8 or less. ma16 is an integer of 0 or more and 3 or less. ma17 is an integer of 0 or more and 5 or less. The sum of ma16 and ma17 is 1 or more and 8 or less.

In the formula (11), ma1 is preferably 0. ma2 is preferably 0. ma3 is preferably 1 or 2.

In the formula (12), ma1 is preferably 0. ma2 is preferably 0. ma3 is preferably 1 or 2.

In the formula (13), ma2 is preferably 0. ma4 and ma5 are each preferably 0. ma6 and ma7 are each preferably 0, 1, or 2. The sum of ma6 and ma7 is 1 or more, and preferably 4 or less.

In the formula (14), ma2 is preferably 0. ma8, ma9, and ma10 are each preferably 0. ma11, ma12, and ma13 are each preferably 0, 1, or 2. The sum of ma11, ma12, and ma13 is preferably 1 or more and 6 or less.

In the formula (15), ma2 is preferably 0. ma14 and ma15 are each preferably 0. ma16 and ma17 are each preferably 0, 1, or 2. The sum of ma16 and ma17 is preferably 1 or more and 4 or less.

In the formulae (11) to (15), R^{a3} is a single bond or a divalent linking group. However, the divalent linking group is not a group including an aromatic group. Examples of divalent linking groups include aliphatic hydrocarbon groups having 1 or more and 20 or less carbon atoms, —CONH—, —NH—, —N═N—, —CH═N—, —COO—, —O—, —CO—, —SO—, —SO₂—, —S—, and —S—S—, and a combination of two or more selected from these groups. The number of carbon atoms in the linking group is preferably 1 or more and 20 or less, more preferably 1 or more and 12 or less, and even more preferably 1 or more and 6 or less. The aliphatic hydrocarbon group as a linking group may include one or more unsaturated bonds, may include a branch, and may include a ring structure. Specific examples of aliphatic hydrocarbon groups as linking groups include a methylene group, an ethane-1,2-diyl group (an ethylene group), an ethane-1,1-diyl group, a propane-1,3-diyl group, a propane-1,2-diyl group, a propane-1,1-diyl group, a propane-2,2-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, a heptadecane-1,17-diyl group, an octadecane-1,18-diyl group, a nonadecane-1,19-diyl group, an icosane-1,20-diyl group, an ethene-1,2-diyl group (vinylene group), a propene-1,3-diyl group, an ethyne-1,2-diyl group, a propyne-1,3-diyl group, and the like.

Suitable examples of the linking group include an alkylene group having 1 or more and 6 or less carbon atoms, an alkenylene group having 2 or more and 6 or less carbon atoms, an alkynylene group having 2 or more and 6 or less carbon atoms, an alkyleneoxy group having 1 or more and 6 or less carbon atoms, an alkenyleneoxy group having 2 or more and 6 or less carbon atoms, an alkynyleneoxy group having 2 or more and 6 or less carbon atoms, an alkylenethio group having 1 or more and 6 or less carbon atoms, an alkenylenethio group having 2 or more and 6 or less carbon atoms, an alkynylenethio group having 2 or more and 6 or less carbon atoms, an alkylene amino group having 1 or more and 6 or less carbon atoms, an alkenylene amino group having 2 or more and 6 or less carbon atoms, an alkynylene amino group having 2 or more and 6 or less carbon atoms, —CONH—, —NH—, —COO—, —O—, —CO—, —SO—, —SO₂—, —S—, —OCONH—, —OCOO—, and the like.

From the viewpoint of a low dielectric loss tangent and good mechanical properties of a polyimide resin formed using the polyimide resin precursor, among the divalent groups represented by the formula (A1-1), a divalent group represented by the following formula (A1-2) is preferable.

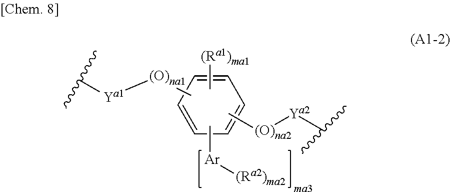

In the formula (A1-2), R^{a1}, R^{a2}, Ar, ma1, ma2, and ma3 are the same as those in the formula (A1-1). Y^{a1} is an organic group having 1 or more and 20 or less carbon atoms, or a single bond. Ya2 is an organic group having 1 or more and 20 or less carbon atoms. na1 is 0 or 1. na2 is 0 or 1. When na1 is 1, Y^{a1} is not a single bond.

In the formula (A1-2), the organic group as Y^{a1} may include a hetero atom such as O, N, S, P, B, Si, or a halogen atom. The organic group as Y^{a1} is preferably a hydrocarbon group. The hydrocarbon group as Y^{a1} may be an aliphatic hydrocarbon group, an aromatic hydrocarbon group, or a combination of an aliphatic hydrocarbon group and an aromatic hydrocarbon group. The hydrocarbon group as Y^{a1} is preferably an aromatic hydrocarbon group, and more preferably a phenylene group or a naphthalenediyl group. Suitable specific examples of the aromatic hydrocarbon group as Y^{a1} include a p-phenylene group, an m-phenylene group, an o-phenylene, a naphthalene-1,4-diyl group, a naphthalene-1,2-diyl group, a naphthalene-1,3-diyl group, a naphthalene-1,5-diyl group, a naphthalene-1,6-diyl group, a naphthalene-1,7-diyl group, a naphthalene-1,8-diyl group, a naphthalene-2,6-diyl group, a naphthalene-2,7-diyl group, and a naphthalene-2,3-diyl group. Among these aromatic hydrocarbon groups, a p-phenylene group and an m-phenylene group are preferable, and a p-phenylene group is more preferable.

In the formula (A1-2), na2 is preferably 1, and more preferably na1 and na2 are both 1, and Y^{a1} is an organic group. In this case, due to the high degree of steric freedom of the ether bond, the structural unit derived from the diamine compound (A-1) having a divalent group represented by the formula (A1-2) is likely to be packed well. Therefore, it is believed that a polyimide resin precursor that gives a polyimide resin excellent in the mechanical properties, thermal properties, electrical properties, and so on can be easily obtained.

In the formula (A1-2), ma1 is preferably 0. ma2 is preferably 0. ma3 is preferably 1 or 2.

Specific examples of the diamine compound (A-1) described above include the following compounds.

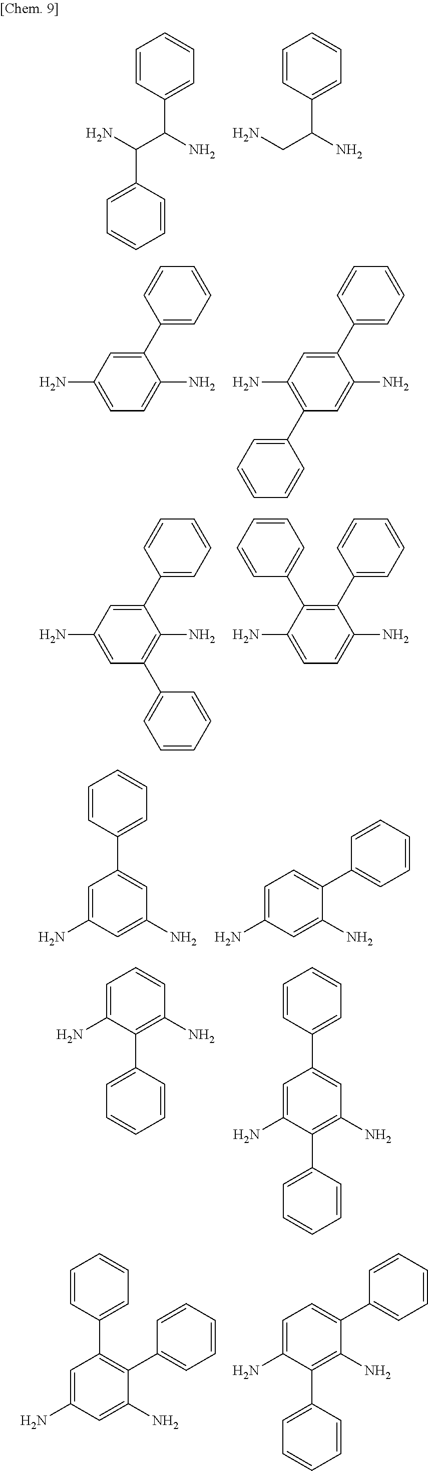

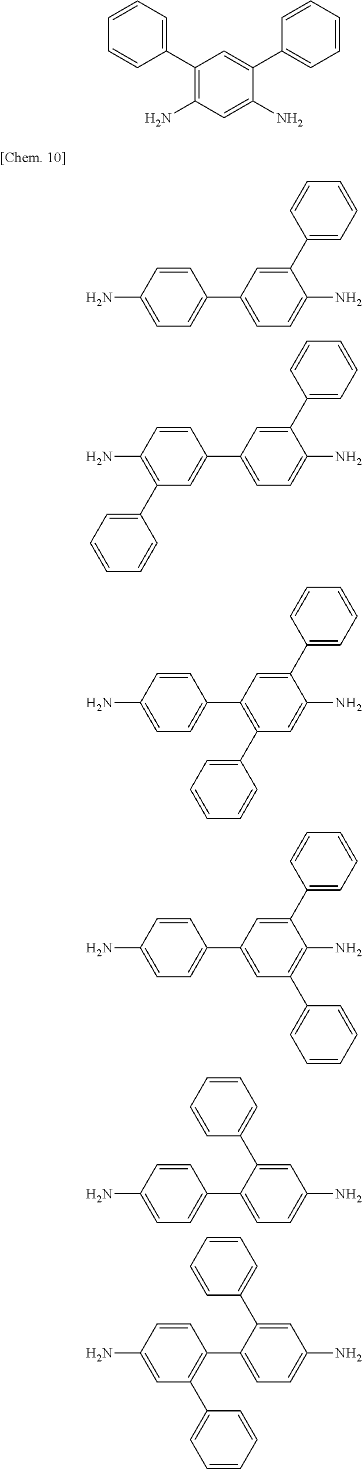

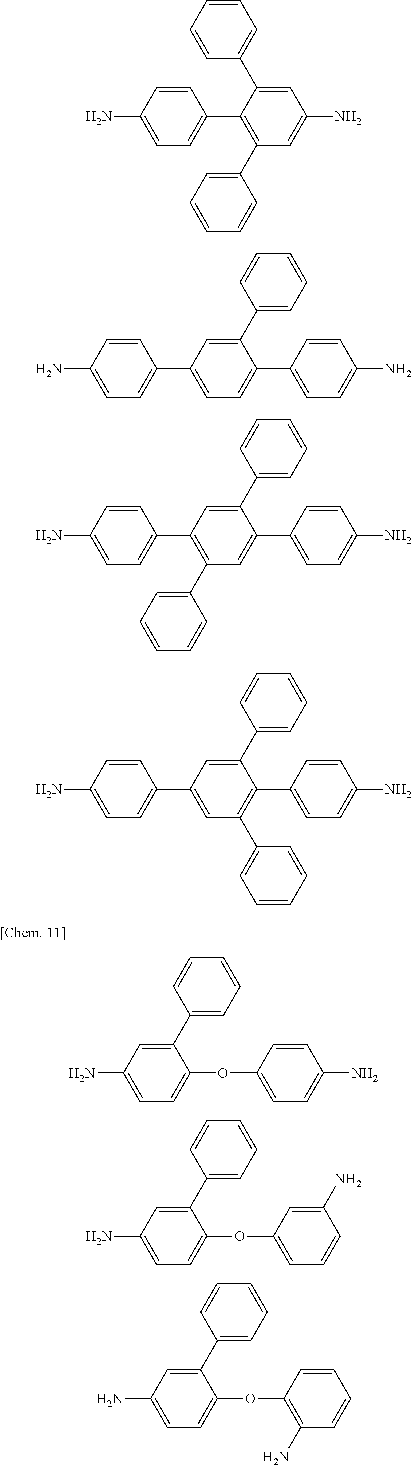

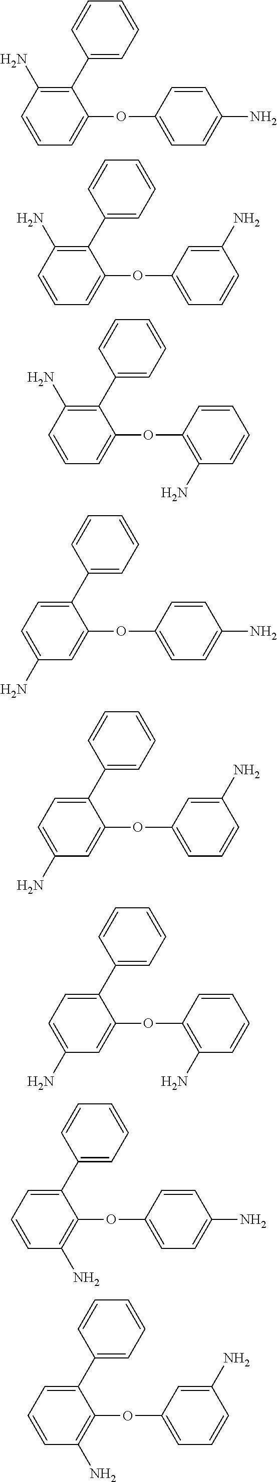

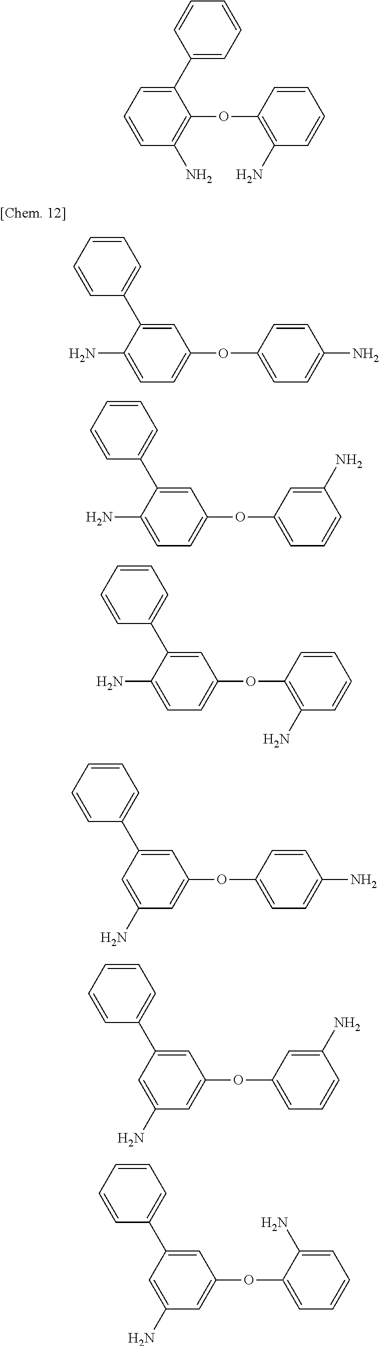

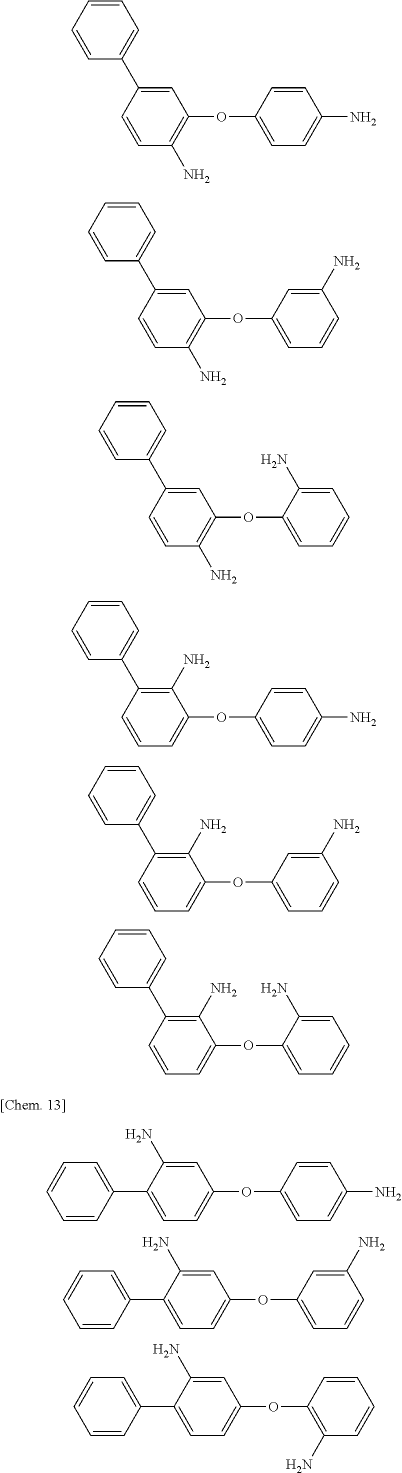

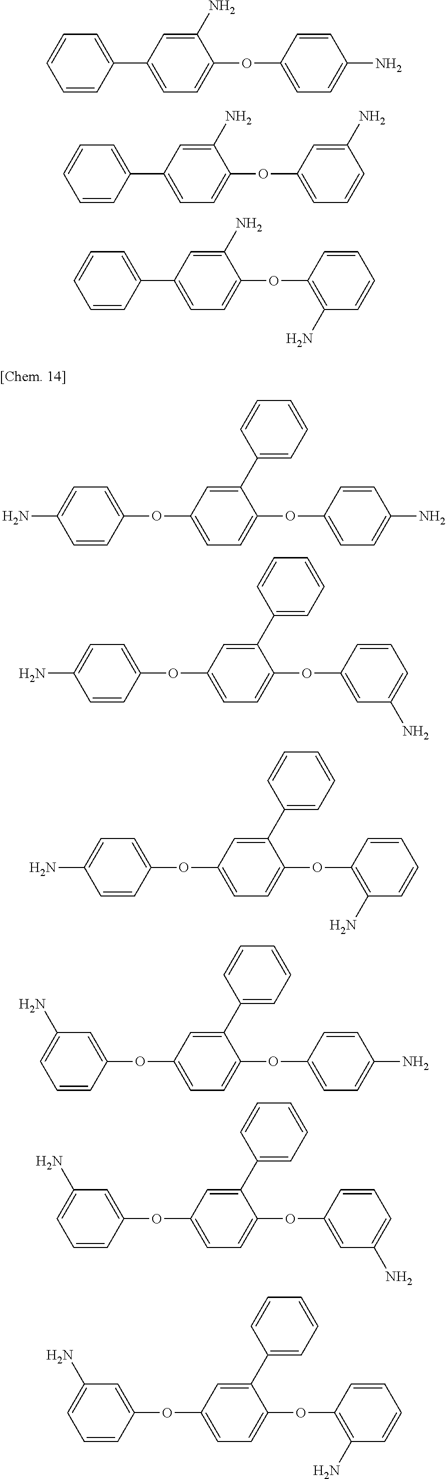

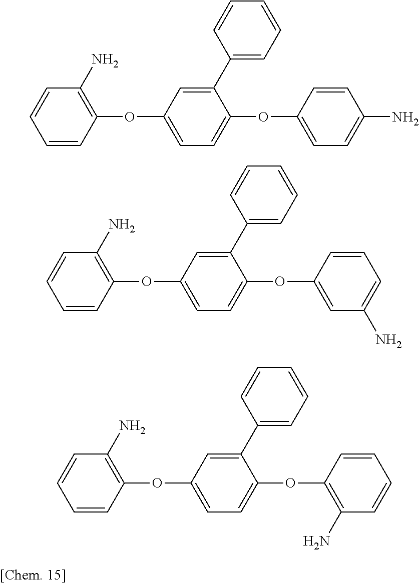

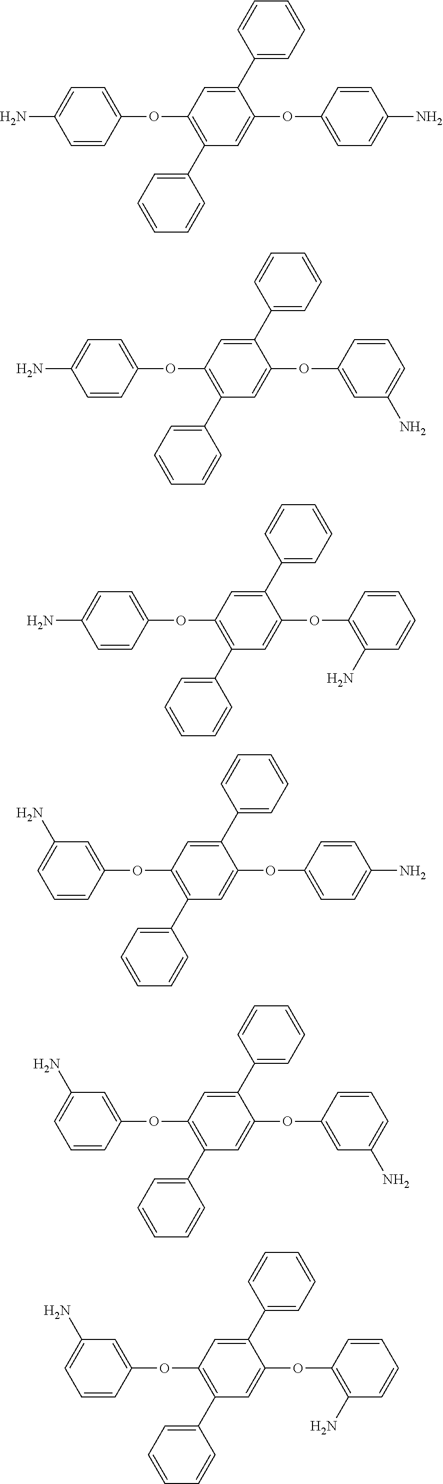

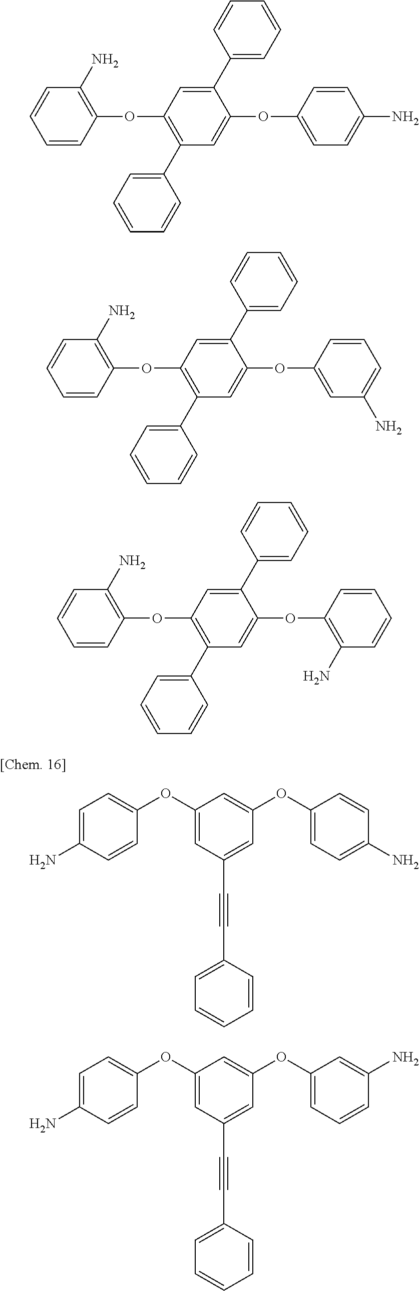

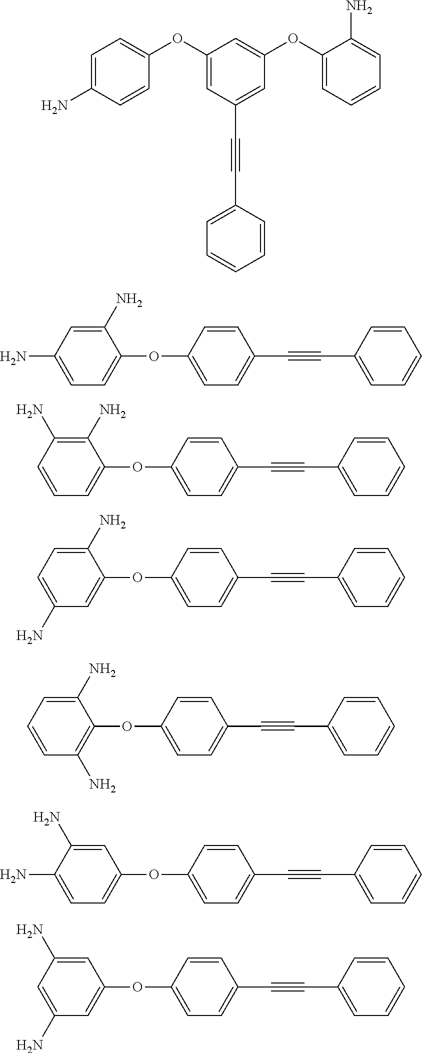

### (Diamine Compound (A-2))

A diamine compound (A-2) has a partial structure represented by the following formula (A2-1) and is a diamine compound that does not correspond to the diamine compound (A-1).

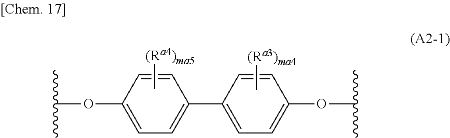

In the formula (A2-1), R^{a3} and R^{a4} are each independently an alkyl group having 1 or more and 4 or less carbon atoms, an alkoxy group having 1 or more and 4 or less carbon atoms, or a halogen atom. ma4 and ma5 are each independently an integer of 0 or more and 4 or less.

In the formula (A2-1), examples of the alkyl group having 1 or more and 4 or less carbon atoms as R^{a3} and R^{a4} include a methyl group, an ethyl group, an n-propyl group, an isopropyl group, an n-butyl group, an isobutyl group, a sec-butyl group, and a tert-butyl group. Among these alkyl groups, a methyl group and an ethyl group are preferable, and a methyl group is more preferable. In the formula (A2-1), examples of the alkoxy group having 1 to 4 carbon atoms as R^{a3} and R^{a4} include a methoxy group, an ethoxy group, an n-propyloxy group, an isopropyloxy group, an n-butyloxy group, an isobutyloxy group, a sec-butyloxy group, and a tert-butyloxy group. Among these alkoxy groups, a methoxy group and an ethoxy group are preferable, and a methoxy group is more preferable

In the formula (A2-1), examples of the halogen atom as R^{a3} and R^{a4} include a fluorine atom, a chlorine atom, a bromine atom, and an iodine atom. Among these halogen atoms, a chlorine atom and a bromine atom are preferable.

In the formula (A2-1), ma4 and ma5 are each independently an integer of 0 or more and 4 or less. Since the diamine compound (A-2) is easily available, ma4 and ma5 are each preferably an integer of 0 or more and 2 or less, and 0 is more preferable.

Examples of a suitable group as the divalent group having a partial structure represented by the formula (A2-1) include a divalent group represented by the following formula (A2-2).

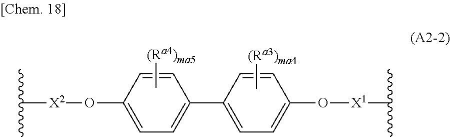

In the formula (A2-2), X¹ and X² are each independently is an aromatic hydrocarbon group optionally substituted with one or more groups selected from the group consisting of an alkyl group having 1 or more and 4 or less carbon atoms, an alkoxy group having 1 or more and 4 or less carbon atoms, and a halogen atom. R^{a3}, R^{a4}, ma4, and ma5 are the same as those in the formula (A2-1). However, the upper limit of the number of carbon atoms in the divalent group represented by the formula (A2-2) is 40.

X¹ and X² in the formula (A2-2) are each independently a divalent aromatic hydrocarbon group which may be substituted with one or more groups selected from the group consisting of an alkyl group having 1 or more and 4 or less carbon atoms, an alkoxy group having 1 or more and 4 or less carbon atoms, and a halogen atom. Examples of the alkyl group having 1 or more and 4 or less carbon atoms as a substituent include a methyl group, an ethyl group, an n-propyl group, an isopropyl group, an n-butyl group, an isobutyl group, a sec-butyl group, and a tert-butyl group. Among these alkyl groups, a methyl group and an ethyl group are preferable, and a methyl group is more preferable. Examples of the alkoxy group having 1 or more and 4 or less carbon atoms as a substituent include a methoxy group, an ethoxy group, an n-propyloxy group, an isopropyloxy group, an n-butyloxy group, an isobutyloxy group, a sec-butyloxy group, and a tert-butyloxy group. Among these alkoxy groups, a methoxy group and an ethoxy group are preferable, and a methoxy group is more preferable. Examples of the halogen atom as a substituent include a fluorine atom, a chlorine atom, a bromine atom, and an iodine atom. Among these halogen atoms, a chlorine atom and a bromine atom are preferable.

The numbers of carbon atoms in the aromatic hydrocarbon groups as X¹ and X² are not particularly limited as long as the number of carbon atoms in the divalent group represented by the formula (A2-2) is 40 or less. Note here that the number of carbon atoms in the above-mentioned aromatic hydrocarbon group does not include the number of carbon atoms in the substituents. The aromatic hydrocarbon groups as X¹ and X² preferably include phenylene groups such as an o-phenylene group, an m-phenylene group, and a p-phenylene group, naphthalenediyl groups such as a naphthalene-1,4-diyl group, a naphthalene-1,3-diyl group, a naphthalene-2,6-diyl group, and a naphthalene-2,7-diyl group, and biphenyldiyl groups such as a biphenyl-4,4′-diyl group, a biphenyl-3,4′-diyl group, and a biphenyl-3,3′-diyl group.

As X¹ and X², a p-phenylene group, an m-phenylene group, a naphthalene-1,4-diyl group, and a biphenyl-4,4′-diyl group are preferable, a p-phenylene group, a biphenyl-4,4′-diyl group are more preferable, and a p-phenylene group is further preferable.

Specific examples of the diamine compound (A-2) having a divalent group having the partial structure represented by the formula (A2-1) described above include the following compounds,

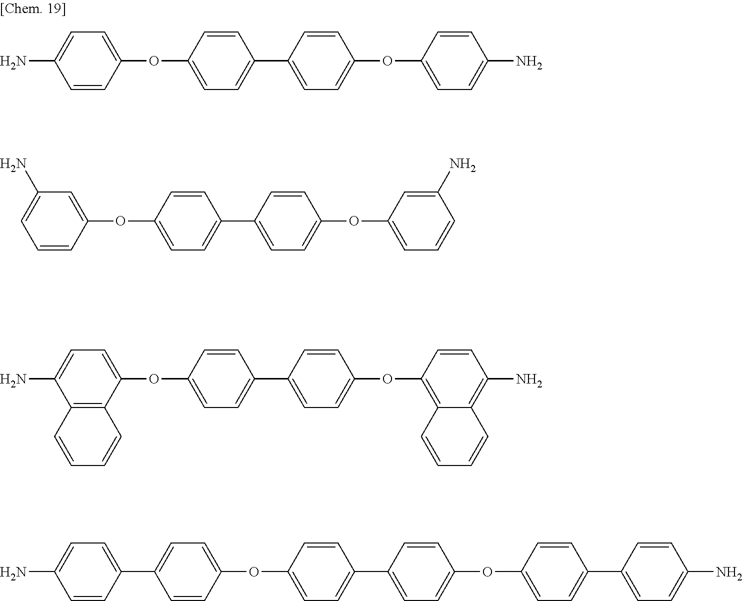 [SMILES: Nc1ccc(Oc2ccc(-c3ccc(Oc4ccc(N)cc4)cc3)cc2)cc1 ; Nc1cccc(Oc2ccc(-c3ccc(Oc4cccc(N)c4)cc3)cc2)c1 ; Nc1ccc(Oc2ccc(-c3ccc(Oc4ccc(N)c5ccccc45)cc3)cc2)c2ccccc12 ; Nc1ccc(-c2ccc(Oc3ccc(-c4ccc(Oc5ccc(-c6ccc(N)cc6)cc5)cc4)cc3)cc2)cc1]

### (Diamine Compound (A-3))

A diamine compound (A-3) has a partial structure represented by the following formula (A3) and is a diamine compound that does not correspond to the diamine compound (A-1) or the diamine compound (A-2).

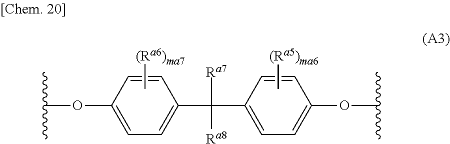

In the formula (A3), R^{a5} and R^{a6} are each independently an alkyl group having 1 or more and 4 or less carbon atoms, an alkoxy group having 1 or more and 4 or less carbon atoms, or a halogen atom. ma6 and ma7 are each independently an integer of 0 or more and 4 or less. R^{a7} and R^{a8} are each independently a hydrogen atom, an alkyl group having 1 or more and 4 or less carbon atoms, a halogenated alkyl group having 1 or more and 4 or less carbon atoms, or a phenyl group. R^{a7} and R^{a8} may be combined with each other to form a ring.

In the formula (A3), examples of the alkyl group having 1 or more and 4 or less carbon atoms as Ra⁵ and Ra⁶ include a methyl group, an ethyl group, an n-propyl group, an isopropyl group, an n-butyl group, an isobutyl group, a sec-butyl group, and a tert-butyl group. Among these alkyl groups, a methyl group and an ethyl group are preferable, and a methyl group is more preferable. In the formula (A3), the alkoxy group having 1 or more and 4 or less carbon atoms as Ra⁵ and Ra⁶ includes a methoxy group, an ethoxy group, an n-propyloxy group, an isopropyloxy group, an n-butyloxy group, an isobutyloxy group, a sec-butyloxy group, and a tert-butyloxy group. Among these alkoxy groups, a methoxy group and an ethoxy groups are preferable, and a methoxy group is more preferable. In the formula (A3), examples of the halogen atom as R^{a5} and Ra⁶ include a fluorine atom, a chlorine atom, a bromine atom, and an iodine atom. Among these halogen atoms, a chlorine atom and a bromine atom are preferable.

In the formula (A3), ma6 and ma7 are each independently an integer of 0 or more and 4 or less. Since the diamine compound (A-3) is easily available, ma6 and ma7 are each preferably an integer of 0 or more and 2 or less, and 0 is more preferable.

In the formula (A3), examples of the alkyl group having 1 or more and 4 or less carbon atoms as R^{a7} and Ra⁸ include a methyl group, an ethyl group, an n-propyl group, an isopropyl group, an n-butyl group, an isobutyl group, a sec-butyl group, and a tert-butyl group. In the formula (A3), examples of the halogenated alkyl group having 1 or more and 4 or less carbon atoms as R^{a7} and R^{a1} include a chloromethyl group, a dichloromethyl group, a trichloromethyl group, a bromomethyl group, a dibromomethyl group, a tribromomethyl group, a fluoromethyl group, a difluoromethyl group, a trifluoromethyl group, a 1,1-difluoroethyl group, and a 1,1,2,2,2-pentafluoroethyl group. As R^{a7} and R^{a8} in the formula (A3), a hydrogen atom, a methyl group, an ethyl group, a trifluoromethyl group, and a phenyl group are preferable because the polyimide resin precursor has good solubility in an organic solvent and the diamine compound (A-3) can be easily obtained. Furthermore, it is also preferable that R^{a7} and R^{a8} combine with each other to form a cycloalkylidene group having 5 or more and 8 or less carbon atoms, such as a cyclopentylidene group, a cyclohexylidene group, a cycloheptylidene group, and a cyclooctylidene group,

Suitable specific examples of the partial structure represented by the formula (A3) include the following structures.

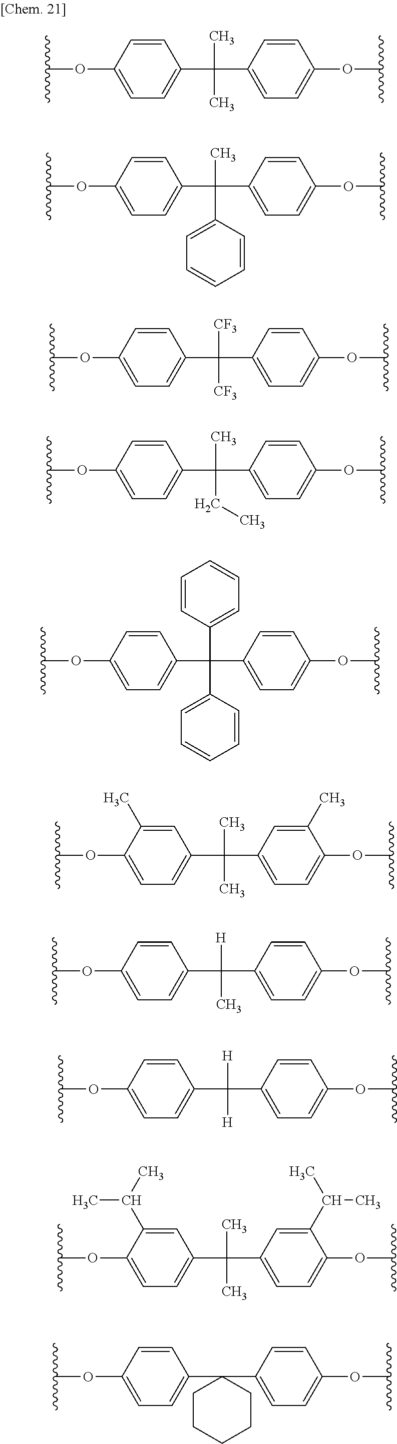

Examples of compounds suitable as the diamine compound (A-3) include compounds represented by the following formula (A3-1).

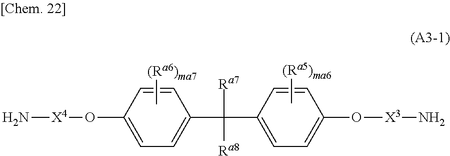

In the formula (A3-1), X³ and X⁴ are each independently is an aromatic hydrocarbon group optionally substituted with one or more groups selected from the group consisting of an alkyl group having 1 or more and 4 or less carbon atoms, an alkoxy group having 1 or more and 4 or less carbon atoms, and a halogen atom. R^{a5}, R^{a6}, R^{a7}, R^{a8}, and ma6 and ma1 are the same as those in the formula (A3).

X³ and X⁴ in the formula (A3-1) are each independently a divalent aromatic hydrocarbon group which may be substituted with one or more groups selected from the group consisting of an alkyl group having 1 or more and 4 or less carbon atoms, an alkoxy group having 1 or more and 4 or less carbon atoms, and a halogen atom. Examples of the alkyl group having 1 or more and 4 or less carbon atoms as a substituent include a methyl group, an ethyl group, an n-propyl group, an isopropyl group, an n-butyl group, an isobutyl group, a sec-butyl group, and a tert-butyl group. Among these alkyl groups, a methyl group and an ethyl group are preferable, and a methyl group is more preferable. Examples of the alkoxy group having 1 or more and 4 or less carbon atoms as a substituent include a methoxy group, an ethoxy group, an n-propyloxy group, an isopropyloxy group, an n-butyloxy group, an isobutyloxy group, a sec-butyloxy group, and a tert-butyloxy group. Among these alkoxy groups, a methoxy group and an ethoxy group are preferable, and a methoxy group is more preferable. Examples of the halogen atom as a substituent include a fluorine atom, a chlorine atom, a bromine atom, and an iodine atom. Among these halogen atoms, a chlorine atom and a bromine atom are preferable.

The number of carbon atoms in the aromatic hydrocarbon groups as X³ and X⁴ is not particularly limited, and is preferably, for example, 6 or more and 50 or less, and more preferably 6 or more and 20 or less. Note here that the number of carbon atoms in the above-mentioned aromatic hydrocarbon group does not include the number of carbon atoms in the substituents. The aromatic hydrocarbon groups as X³ and X⁴ preferably include phenylene groups such as an o-phenylene group, an m-phenylene group, and a p-phenylene group, naphthalenediyl groups such as a naphthalene-1,4-diyl group, a naphthalene-1,3-diyl group, a naphthalene-2,6-diyl group, and a naphthalene-2,7-diyl group, and biphenyldiyl groups such as a biphenyl-4,4′-diyl group, a biphenyl-3,4′-diyl group, and a biphenyl-3,3′-diyl group.

As X³ and X⁴, a p-phenylene group, an m-phenylene group, a naphthalene-1,4-diyl group, and a biphenyl-4,4′-diyl group are preferable, a p-phenylene group, a biphenyl-4,4′-diyl group are more preferable, and a p-phenylene group is further preferable.

Specific examples of the diamine compound (A-3) represented by the formula (A3) described above include the following compounds.

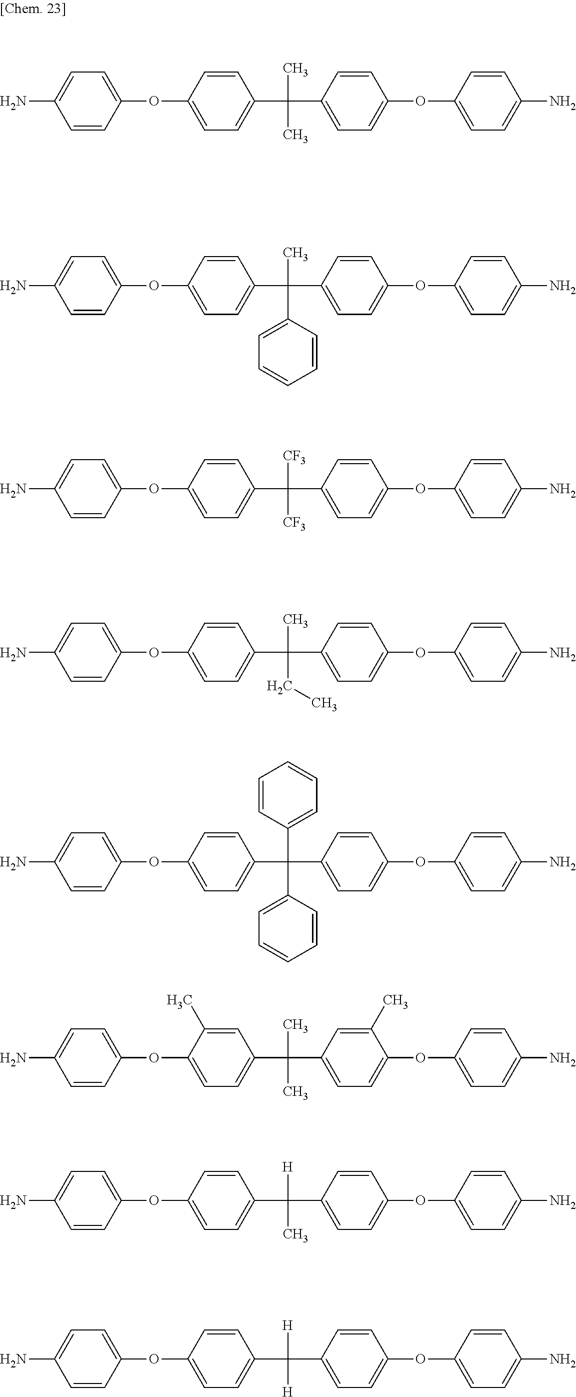

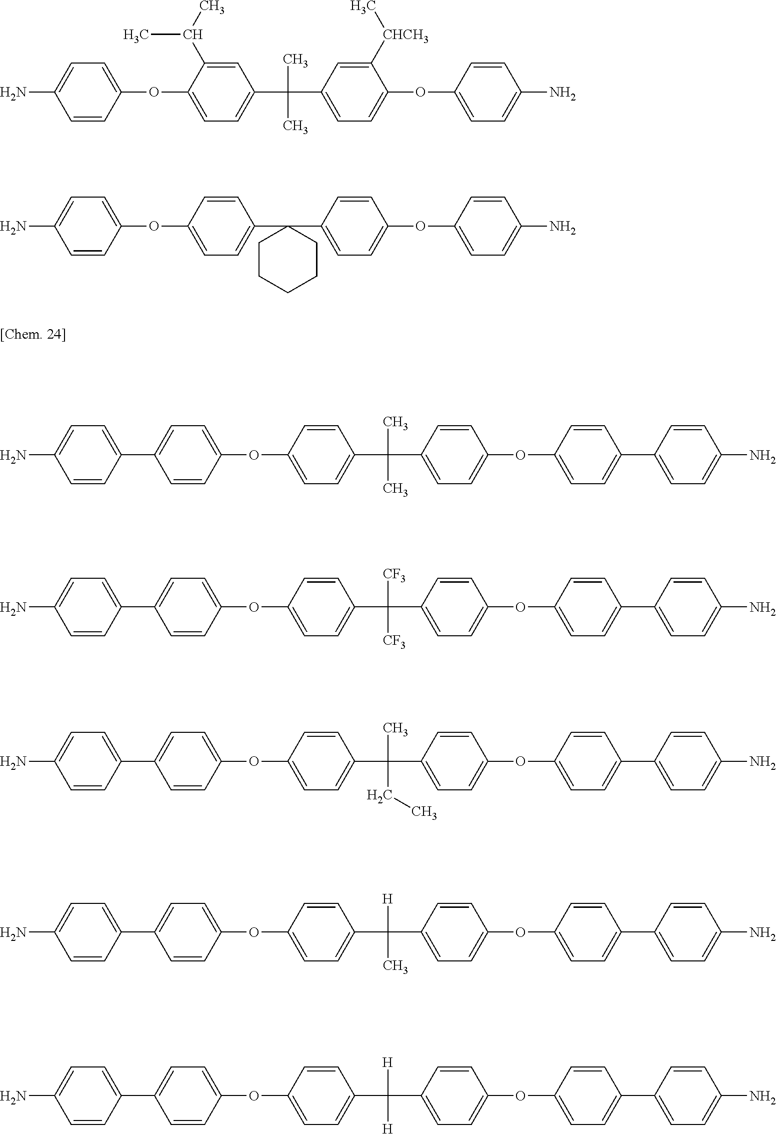

### (Dimer Diamine Compound (A-4))

A dimer diamine compound (A-4) is also preferable as the diamine compound because it is easy to obtain a polyimide resin precursor that gives a polyimide resin with a low dielectric constant in a high frequency band and a low dielectric loss tangent. The dimer diamine compound (A-4) is a diamine compound in which two terminal carboxy groups of dimer acid are substituted with an aminomethyl group or an amino group. Dimer acid is a known dibasic acid obtained by intermolecular polymerization reaction of unsaturated fatty acids. The industrial manufacturing process for producing dimer acids is largely standardized. Typically, a dimer acid is obtained by dimerizing an unsaturated fatty acid having 11 or more and 22 or less carbon atoms in the presence of a clay catalyst or the like. Industrially obtained dimer acids are mainly composed of dibasic acids having 36 carbon atoms obtained by dimerizing unsaturated fatty acids having 18 carbon atoms such as oleic acid, linoleic acid, and linolenic acid. Industrially obtained dimer acids contain arbitrary amounts of monomer acids having 18 carbon atoms, trimer acids having 54 carbon atoms, and other polymerized fatty acids having 20 or more and 54 or less carbon atoms, depending on the degree of purification. As the dimer diamine compound (A-4), diamine compounds represented by the following formula (31) are preferable.

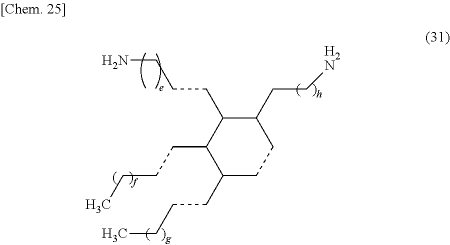

In the formula (31), e, f, g, and h are each an integer of 0 or more. e+f is an integer of 6 or more and 17 or less, and g+h is an integer of 8 or more and 19 or less. In the formula (31), the wavy line denotes a carbon-carbon single bond or a carbon-carbon double bond.

Furthermore, since it is easy to obtain a polyimide resin precursor capable of forming a polyimide resin having excellent elongation, the diamine compound represented by formula (31) is preferably a compound represented by the following formula (32).

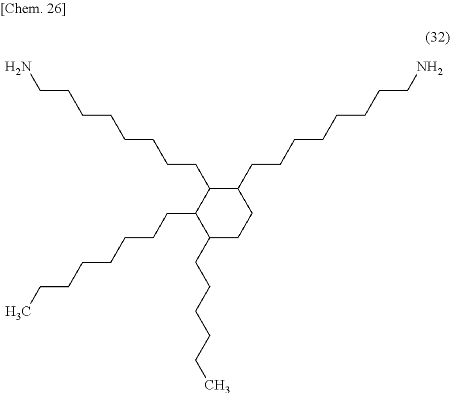 [SMILES: CCCCCCCCC1C(CCCCCC)CCC(CCCCCCCCN)C1CCCCCCCCN]

Commercially available products of the diamine compounds represented by the formula (31) include Versamine 551 (manufactured by BASF) and Priamine 1074 (manufactured by Croda Japan), which include the compound represented by the following formula (33), and Versamine 552 (manufactured by BASF), Priamine 1073 (manufactured by Croda Japan), and Priamine 1075 (manufactured by Croda Japan), which include the compound represented by the following formula (32). Such a commercially available dimer diamine compound (A-4) is usually a mixture including a plurality of types of amine compounds.

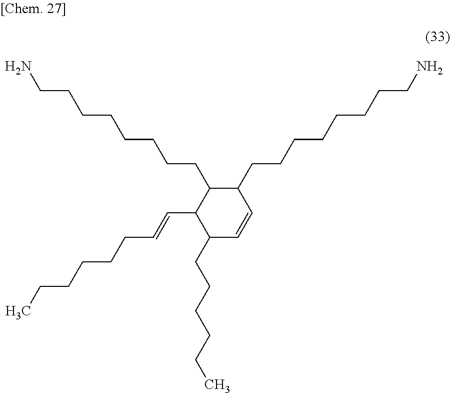 [SMILES: CCCCCC/C=C/C1C(CCCCCC)C=CC(CCCCCCCCN)C1CCCCCCCCN]

Furthermore, by reacting a diamine compound represented by the formula (31) with acid halide derived from trimellitic anhydride, a tetracarboxylic dianhydride represented by the following formula (34) can be obtained. It is also preferable to use a tetracarboxylic dianhydride represented by the following formula (34) as a raw material for producing a polyimide resin precursor.

In the formula (34), i, j, k, and l are each an integer of 0 or more, i+j is an integer of 6 or more and 17 or less, and k+1 is an integer of 8 or more and 19 or less. In the formula (34), the wavy line denotes a carbon-carbon single bond or a carbon-carbon double bond.

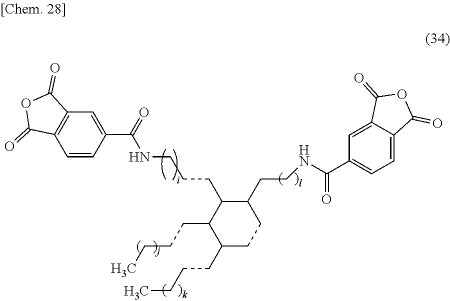

The ratio of the number of moles of one or more compounds selected from the group consisting of a diamine compound (A-1), a diamine compound (A-2), a diamine compound (A-3), and a dimer diamine compound (A-4) to the total number of moles of the diamine compound is preferably 10% by mol or more and 100% by mol or less, more preferably 15% by mol or more and 100% by mol or less, and further more preferably 20% by mol or more and 100% by mol or less.

[Dicarboxylic Acid that is Reactant of Tetracarboxylic Dianhydride and Alcohol]

Dicarboxylic acid is a reactant of a tetracarboxylic dianhydride and an alcohol. The polyimide resin precursor includes, as the organic group as R^{A1} or R^{A2} in the formula (1), an unsaturated group G1 having 3 or more and 30 or less carbon atoms that does not include a (meth)acryloyl group but includes one or more ethylenically unsaturated double bonds. The polyimide resin precursor optionally includes a (meth)acryloyl group-containing group G2, as the organic group as R^{A1} or R^{A2} in the above-described formula (1). Consequently, the dicarboxylic acid includes a dicarboxylic acid having the unsaturated group G1 and can include a dicarboxylic acid having the (meth)acryloyl group-containing group G2. Such a dicarboxylic acid is obtained by causing a reaction between an alcohol with a hydroxy group bonded to the unsaturated group G1 or an alcohol with a hydroxy group bonded to the (meth)acryloyl group-containing group G2 and a tetracarboxylic acid dianhydride. As a result of using such a dicarboxylic acid, a photosensitive composition including the polyimide resin precursor has good photosensitivity, and a polyimide resin with a low dielectric loss tangent can be formed using the polyimide resin precursor. Hereinafter, in this specification, unless otherwise specified, “dicarboxylic acid” means a dicarboxylic acid that is a reaction product of tetracarboxylic dianhydride and the above-mentioned alcohol. Hereinafter, tetracarboxylic dianhydride and alcohol will be described below.

### (Tetracarboxylic Dianhydride)

The tetracarboxylic dianhydride is not particularly limited as long as the desired effect is not impaired. As the tetracarboxylic dianhydride, typically, a tetracarboxylic dianhydride conventionally used in the production of polyamic acids and polyimide resins can be used. Examples of the tetracarboxylic dianhydride include a compound represented by the following formula (A3).

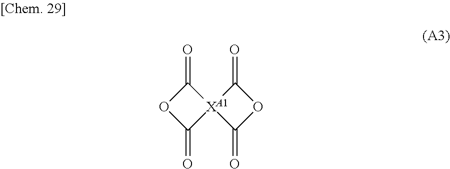

In the formula (A3), X^{A1} is a tetravalent organic group having 4 or more and 40 or less carbon atoms. X^{A1} may include one or a plurality of substituents in addition to the acid anhydride groups represented by two —CO—O—CO— in the formula (A3). Suitable examples of the substituent include a fluorine atom, an alkyl group having 1 or more and 6 or less carbon atoms, an alkoxy group having 1 or more and 6 or less carbon atoms, a fluorinated alkyl group having 1 or more and 6 or less carbon atoms, and a fluorinated alkoxy group having 1 or more and 6 or less carbon atoms. Furthermore, the compound represented by the formula (A3) may include a carboxy group or a carboxylic acid ester group in addition to the acid anhydride group. When the substituent is a fluorinated alkyl group or a fluorinated alkoxy group, a perfluoroalkyl group or a perfluoroalkoxy group are preferable. Regarding the above substituents, the same is true to one or a plurality of substituents which the aromatic group described below may have on the aromatic ring.

The number of carbon atoms constituting X^{A1} is more preferably 8 or more, and further preferably 12 or more. Furthermore, the number of carbon atoms constituting x^{A1} is preferably 40 or less, and further preferably 30 or less. X^{A1} may be an aliphatic group, an aromatic group, or a combination of these structures. XML may include a halogen atom, an oxygen atom, a nitrogen atom, and a sulfur atom in addition to a carbon atom and a hydrogen atom. When X^{A1} includes an oxygen atom, a nitrogen atom, or a sulfur atom, the oxygen atom, nitrogen atom, or sulfur atom may be included in A¹ as a group selected from a nitrogen-containing heterocyclic group, —CONH—, —NH—, —N—N—, —CH═N—, —COO—, —O—, —CO—, —SO—, —SO₂—, —S—, and —S—S—, and more preferably included in X^{A1} as a group selected from —O—, —CO—, and —S—.

The tetracarboxylic acid dianhydride represented by the formula (A3) may be an aliphatic tetracarboxylic acid dianhydride having two dicarboxylic acid anhydride groups bonded to an aliphatic group or an aromatic tetracarboxylic acid dianhydride having at least one dicarboxylic acid anhydride group bonded to an aromatic group. Note here that the aromatic tetracarboxylic dianhydride preferably has two dicarboxylic acid anhydride groups bonded to an aromatic group.

The aliphatic tetracarboxylic dianhydride may contain an alicyclic structure. The alicyclic structure may be polycyclic. Examples of aliphatic tetracarboxylic dianhydrides that do not have an alicyclic structure include 1,2,3,4-tetracarboxylic dianhydride (for example, Rikacid BT-100, manufactured by New Japan Chemical Co., Ltd.). Examples of the aliphatic tetracarboxylic dianhydride having an alicyclic structure include cyclobutanetetracarboxylic dianhydride, cyclopentane-1,2,3,4-tetracarboxylic dianhydride, cyclohexane-1,2,4,5-tetracarboxylic dianhydride, norbornane-2-spiro-α-cyclopentanone-α′-spiro-2″-norbornane-5,5″,6,6″-tetracarboxylic dianhydride (for example, Enehyde (registered trademark) CpODA, manufactured by Eneos), 2,2-bis(2,3-dicarboxyphenoxy)hexafluoropropane dianhydride[5,5′-(1,4-phenylene)bisnorbornane]-2,2′,3,3′-tetracarboxylic dianhydride (for example, Enehyde (registered trademark) BzDA, manufactured by Eneos), 1,3,3a,4,5,9b-hexahydro-5 (tetrahydro-2,5-dioxo-3-furanyl) naphtho[1,2-C]furan-1,3-dione (for example, Rikacid TDA-100, manufactured by New Japan Chemical Co., Ltd.), and the like.

Examples of the aromatic tetracarboxylic dianhydride represented by the formula (A3) and having two dicarboxylic anhydride groups bonded to an aromatic group include pyromellitic dianhydride, 1,4-bis(3,4-dicarboxyphenoxy)benzene dianhydride, 4,4′-oxydiphthalic dianhydride, 3,3′,4,4′-biphenyltetracarboxylic dianhydride, 2,3,3′,4′-biphenyltetracarboxylic dianhydride, 3,3′,4,4′-benzophenonetetracarboxylic dianhydride, 2,2′,3,3′-benzophenonetetracarboxylic dianhydride, 3,3′,4,4′-diphenylsulfonetetracarboxylic dianhydride, 3,3′,4,4′-diphenylsulfide tetracarboxylic dianhydride, trimellitic acid (3,4-dicarboxyphenyl)dianhydride, 1,2,5,6-naphthalenetetracarboxylic dianhydride, 2,3,6,7-naphthalenetetracarboxylic dianhydride, 2,3,5,6-pyridinetetracarboxylic dianhydride, 3,4,9,10-perylenetetracarboxylic dianhydride, bis(2,3-dicarboxyphenoxy)methane dianhydride, 1,1-bis(2,3-dicarboxyphenoxy)ethane dianhydride, 2,2-bis[4-(3,4-dicarboxyphenyloxy)phenyl]propane dianhydride, 4,4′-bis(3,4-dicarboxyphenylcarbonyloxy)biphenyl dianhydride, 2,6-bis(3,4-dicarboxyphenylcarbonyloxy)naphthalene dianhydride, 1,2-bis(3,4-dicarboxyphenylcarbonyloxy)ethane dianhydride (for example, Rikacid TMEG100, manufactured by New Japan Chemical Co., Ltd.), and 1,10-bis(3,4-dicarboxyphenylcarbonyloxy) decane dianhydride (for example, 10BTA, manufactured by Kurogane Kasei Co., Ltd.), and the like. Among these aromatic tetracarboxylic dianhydrides, 2,2-bis[4-(3,4-dicarboxyphenyloxy)phenyl]propane dianhydride, 4,4′-bis(3,4-dicarboxyphenylcarbonyloxy)biphenyl dianhydride, 4,4′-bis(3,4-dicarboxyphenyloxy)biphenyl dianhydride, 2,6-bis(3,4-dicarboxyphenylcarbonyloxy)naphthalene dianhydride, and α,ω-bis(3,4-dicarboxyphenylcarbonyloxy)alkane dianhydride are preferable because a cured product with excellent electrical properties is easily formed. The α,ω-bis(3,4-dicarboxyphenylcarbonyloxy)alkane dianhydride is a compound represented by the following formula (a1).

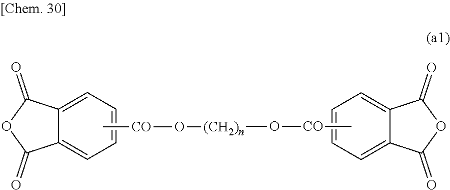

n in the formula (a1), which is the number of carbon atoms of the linear alkylene group in α,ω-bis(3,4-dicarboxyphenylcarbonyloxy)alkane dianhydride is an integer of 1 or more, preferably 1 or more and 20 or less, and more preferably 2 or more and 12 or less. Suitable examples of the α,ω-bis(3,4-dicarboxyphenylcarbonyloxy)alkane dianhydride include 1,2-bis(3,4-dicarboxyphenylcarbonyloxy)ethane dianhydride (for example, Rikacid TMEG100, manufactured by New Japan Chemical Co., Ltd.), and 1,10-bis(3,4-dicarboxyphenylcarbonyloxy) decane dianhydride (for example, 10BTA, manufactured by Kurogane Kasei Co., Ltd.), and the like.

It is also preferable that the aromatic tetracarboxylic acid dianhydride is biphenyltetracarboxylic acid dianhydride from the viewpoint that warpage of a polyimide resin film formed by using a composition including a polyimide resin precursor is suppressed and photolithographic properties of the composition is good when photosensitivity is imparted to the composition containing the polyimide resin precursor. Examples of biphenyltetracarboxylic dianhydride include 3,3′,4,4′-biphenyltetracarboxylic dianhydride, 2,3,3′,4′-biphenyltetracarboxylic dianhydride, and 2,2′,3,3′-biphenyltetracarboxylic dianhydride, and 3,3′,4,4′-biphenyltetracarboxylic dianhydride are preferable.

The aromatic tetracarboxylic dianhydride may also be, for example, compounds represented by the following formulae (a3-2) to (a3-4).

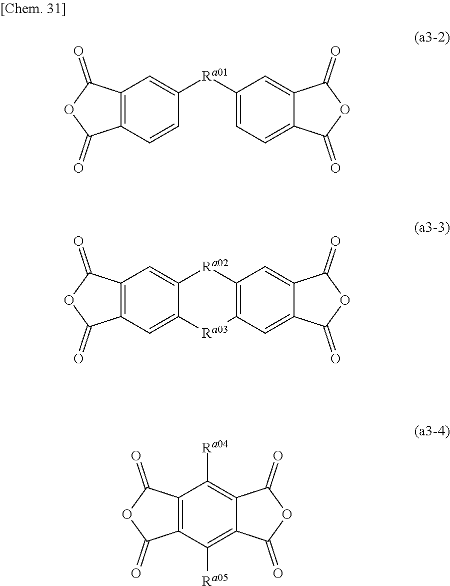

In the formulae (a3-2) and (a3-3) above, R^{a01}, R^{a02} and R^{a03} each represent an aliphatic group optionally substituted with halogen, an oxygen atom, a sulfur atom, an aromatic group via one or more divalent elements, or a divalent group constituted by a combination thereof. R^{a02} and R^{a03} may be the same as or different from each other. In other words, R^{a01}, R^{a02} and R^{a03} may include a carbon-carbon single bond, a carbon-oxygen-carbon ether bond, or a halogen element (fluorine, chlorine, bromine, iodine). Examples of the compound represented by the formula (a3-2) include 2,2-bis(3,4-dicarboxyphenoxy)propane dianhydride, bis(3,4-dicarboxyphenoxy)methane dianhydride, 1,1-bis(3,4-dicarboxyphenoxy)ethane dianhydride, 1,3-bis(3,4-dicarboxyphenoxy)benzene, 2,2-bis(3,4-dicarboxyphenoxy)hexafluoropropane dianhydride, 1,4-bis(3,4-dicarboxyphenoxy)benzene dianhydride, and the like.

Furthermore, in the above formula (a3-4), R^{a04}, and R^{a05} represent monovalent substituents composed of an aliphatic group which may be substituted with a halogen, an aromatic group via one or more divalent elements, a halogen, or a combination thereof. R^{a04} and R^{a05} may be the same as or different from each other. As the compound represented by the formula (a3-4), difluoropyromellitic dianhydride, dichloropyromellitic dianhydride, and the like, can also be used.

It is also preferable that the polyimide resin precursor has a radically polymerizable group-containing group on its molecular chain in addition to the residue derived from the alcohol described above. Therefore, the tetravalent organic group A² in the formula (A3) may be a group represented by the following formulae (a3-5) to (a3-7).

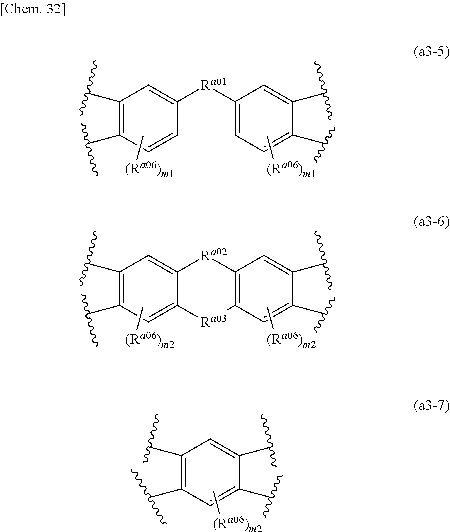

R^{a01}, R^{a02}, and R^{a03} in the formulae (a3-5) to (a3-7) are the same as R^{a01}, R^{a02}, and R^{a03} in the above-mentioned formulae (a3-2), (a3-3), and (a3-4). R^{a06} in the formulae (a3-5), (a3-6), and (a3-7) is a radically polymerizable group-containing group. The radically polymerizable group-containing group is described later.

### (Alcohol)

As described above, the dicarboxylic acid is a reactant of a tetracarboxylic dianhydride and an alcohol. The alcohol includes an alcohol with a hydroxy group bonded to the unsaturated group G1 described above and optionally includes an alcohol with a hydroxy group bonded to the (meth)acryloyl group-containing group G2. Hereinafter, the alcohol with a hydroxy group bonded to the unsaturated group G1 is referred to as alcohol AG1. The alcohol with a hydroxy group bonded to the (meth)acryloyl group-containing group G2 is referred to as alcohol AG2.

The proportion of the sum of the number of moles of the unsaturated group G1 and the number of moles of the (meth)acryloyl group-containing group G2 to the total number of moles of the organic groups as R^{A1} and R^{A2} in the whole structural units of the polyimide resin precursor is 60 mol % or more, more preferably 80 mols or more, further preferably 90 mol % or more, and particularly preferably 100 mol %. Consequently, the proportion of the sum of the number of moles of the alcohol AG1 and the number of moles of the alcohol AG2 to the number of moles of the alcohol is also 60 mol % or more, more preferably 80 mol % or more, further preferably 90 mol % or more, and particularly preferably 100 mol %.

The proportion of the number of moles of the unsaturated group G1 to the total number of moles of the organic groups as R^{A1} and R^{A2} in the whole structural units of the polyimide resin precursor is 10 mol % or more, preferably 30 mol % or more, more preferably 70 mol % or more, further preferably 50 mol % or more, further more preferably 80 mol % or more, and particularly preferably 100 mol %. Consequently, the proportion of the number of moles of the alcohol AG1 to the number of moles of the alcohol is also 10 mol % or more, preferably 30 mols or more, more preferably 50 mol % or more, further preferably 70 mol % or more, further more preferably 80 mol % or more, and particularly preferably 100 mol %.

### Alcohol AG1

The alcohol AG1 is an alcohol with a hydroxy group bonded to an unsaturated group G1 having 3 or more and 30 or less carbon atoms that does not include a (meth)acryloyl group but includes one or more ethylenically unsaturated double bonds. Accordingly, the number of carbon atoms in the alcohol AG1 is also 3 or more and 30 or less. The number of carbon atoms in the unsaturated group G1 is preferably 3 or more and 30 or less, more preferably 4 or more and 30 or less, further preferably 5 or more and 30 or less, and particularly preferably 5 or more and 25 or less. Accordingly, the number of carbon atoms in the alcohol AG1 is also preferably 3 or more and 30 or less, more preferably 4 or more and 30 or less, further preferably 5 or more and 30 or less, and particularly preferably 5 or more and 25 or less.

The structures of the alcohol AG1 and the unsaturated group G1 may be linear or branched. The alcohol AG1 and the unsaturated group G1 may include a cyclic group. The cyclic group may be an alicyclic group or an aromatic group. The unsaturated group G1 of the alcohol AG1 may include a heteroatom, such as O, N, S, P, B, Si, or a halogen atom, as long as the desired effect is not impaired.

The numbers of the ethylenically unsaturated double bonds in the alcohol AG1 and the unsaturated group G1 are not particularly limited. The number of the ethylenically unsaturated double bonds is preferably 1 or more and 4 or less and more preferably 1 or 2.

The unsaturated group G1 constituting the alcohol AG1 is preferably an unsaturated aliphatic hydrocarbon group, more preferably a linear unsaturated aliphatic hydrocarbon group, and further preferably a linear unsaturated aliphatic hydrocarbon group. The number of carbon atoms in the unsaturated aliphatic hydrocarbon group is preferably 5 or more and 30 or less.

Preferable specific examples of the alcohol AG1 include an allyl alcohol; a butenol, such as but-3-en-1-yl alcohol and but-2-en-1-yl alcohol; a pentenol, such as pent-4-en-1-yl alcohol, pent-3-en-1-yl alcohol, and pent-2-en-1-yl alcohol; a hexenol, such as hex-5-en-1-yl alcohol, hex-4-en-1-yl alcohol, hex-3-en-1-yl alcohol, and hex-2-en-1-yl alcohol; a heptenol, such as hept-6-en-1-yl alcohol, hept-5-en-1-yl alcohol, hept-4-en-1-yl alcohol, hept-3-en-1-yl alcohol, and hept-2-en-1-yl alcohol; an octenol, such as oct-7-en-1-yl alcohol, oct-6-en-1-yl alcohol, oct-5-en-1-yl alcohol, oct-4-en-1-yl alcohol, oct-3-en-1-yl alcohol, and oct-2-en-1-yl alcohol; a nonenol, such as non-8-en-1-yl alcohol, non-7-en-1-yl alcohol, non-6-en-1-yl alcohol, non-5-en-1-yl alcohol, non-4-en-1-yl alcohol, non-3-en-1-yl alcohol, and non-2-en-1-yl alcohol; a decenol, such as dec-9-en-1-yl alcohol, dec-8-en-1-yl alcohol, dec-7-en-1-yl alcohol, dec-6-en-1-yl alcohol, dec-5-en-1-yl alcohol, dec-4-en-1-yl alcohol, dec-3-en-1-yl alcohol, and dec-2-en-1-yl alcohol; an undecenol, such as undec-10-en-1-yl alcohol; a dodecenol, such as dodec-11-en-1-yl alcohol; a tridecenol, such as tridec-12-en-1-yl alcohol; a tetradecenol, such as tetradec-13-en-1-yl alcohol; a pentadecenol, such as pentadec-14-en-1-yl alcohol; a hexadecenol, such as hexadec-15-en-1-yl alcohol; a heptadecenol, such as heptadec-16-en-1-yl alcohol; an octadecenol, such as octadec-17-en-1-yl alcohol and octadec-9-en-1-yl alcohol (oleyl alcohol); a nonadecenol, such as nonadec-18-en-1-yl alcohol; an icosenol, such as icosen-19-en-1-yl alcohol; and an octadienol, such as octadeca-9,12-dien-1-yl alcohol (linoleyl alcohol).

Suitable specific examples of the unsaturated group G1 include an allyl group; a butenyl group, such as a but-3-en-1-yl group and a but-2-en-1-yl group; a pentenyl group, such as a pent-4-en-1-yl group, a pent-3-en-1-yl group, and a pent-2-en-1-yl group; a hexenyl group, such as a hex-5-en-1-yl group, a hex-4-en-1-yl group, a hex-3-en-1-yl group, and a hex-2-en-1-yl group; a heptenyl group, such as a hept-6-en-1-yl group, a hept-5-en-1-yl group, a hept-4-en-1-yl group, a hept-3-en-1-yl group, and a hept-2-en-1-yl group; an octenyl group, such as an oct-7-en-1-yl group, an oct-6-en-1-yl group, an oct-5-en-1-yl group, an oct-4-en-1-yl group, an oct-3-en-1-yl group, and an oct-2-en-1-yl group; a nonenyl group, such as a non-8-en-1-yl group, a non-7-en-1-yl group, a non-6-en-1-yl group, a non-5-en-1-yl group, a non-4-en-1-yl group, a non-3-en-1-yl group, and a non-2-en-1-yl group; a decenyl group, such as a dec-9-en-1-yl group, a dec-8-en-1-yl group, a dec-7-en-1-yl group, a dec-6-en-1-yl group, a dec-5-en-1-yl group, a dec-4-en-1-yl group, a dec-3-en-1-yl group, and a dec-2-en-1-yl group; an undecenyl group, such as an undec-10-en-1-yl group; a dodecenyl group, such as a dodec-11-en-1-yl group; a tridecenyl group, such as a tridec-12-en-1-yl group; a tetradecenyl group, such as a tetradec-13-en-1-yl group; a pentadecenyl group, such as a pentadec-14-en-1-yl group; a hexadecenyl group, such as a hexadec-15-en-1-yl group; a heptadecenyl group, such as a heptadec-16-en-1-yl group; an octadecenyl group, such as an octadec-17-en-1-yl group and an octadec-9-en-1-yl group (oleyl group); a nonadecenyl group, such as a nonadec-18-en-1-yl group; an icosenyl group, such as an icosen-19-en-1-yl group; and an octadienyl group, such as an octadeca-9,12-dien-1-yl group (linoleyl group).

### Alcohol AG2

The alcohol AG2 is an alcohol with a hydroxy group bonded to a (meth)acryloyl group-containing group G2. The structures and the numbers of carbon atoms of the alcohol AG2 and the (meth)acryloyl group-containing group G2 are not particularly limited, as long as the desired effect is not impaired. The number of carbon atoms in the (meth)acryloyl group-containing group G2 is preferably 3 or more and 30 or less, more preferably 3 or more and 25 or less, and further preferably 4 or more and 20 or less. Accordingly, the number of carbon atoms in the alcohol AG2 is also preferably 3 or more and 30 or less, more preferably 3 or more and 25 or less, and further preferably 4 or more and 20 or less.

The structures of the alcohol AG2 and the (meth)acryloyl group-containing group G2 may be linear or branched. The alcohol AG2 and the (meth)acryloyl group-containing group G2 may include a cyclic group. The cyclic group may be an alicyclic group or an aromatic group. The (meth)acryloyl group-containing group G2 of the alcohol AG2 may include a heteroatom, such as O, N, S, P, B, Si, or a halogen atom, as long as the desired effect is not impaired.

The numbers of the (meth)acryloyl groups in the alcohol AG2 and the (meth)acryloyl group-containing group G2 are not particularly limited. The number of the (meth)acryloyl groups is preferably 1 or more and 4 or less and more preferably 1 or 2.

From the viewpoint of easily forming a polyimide resin with a low dielectric loss tangent, the alcohol AG2 is an alcohol including a combination of a secondary hydrocarbon group and a (meth)acryloyl group or preferably includes an alcohol including a combination of a methylol group and a (meth)acryloyl group. Hereinafter, an alcohol including a combination of a secondary hydrocarbon group and a (meth)acryloyl group and an alcohol including a combination of a methylol group and a (meth)acryloyl group are also referred to as “alcohol AG2-1”. An alcohol corresponding to the alcohol AG2 but not corresponding to the alcohol AG2-1 is also referred to as “alcohol AG2-2”.

In the specification of this application, the methylol group is defined as a hydroxymethyl group bonding to a secondary carbon atom, a tertiary carbon atom, a carbon atom bonding to one carbon atom and one heteroatom, a carbon atom bonding to two heteroatoms, or a carbon atom in an aromatic ring. For example, a hydroxyethyl group consists of a hydroxymethyl group and a methylene group. However, according to the above definition, in the specification and claims of this application, a hydroxymethyl group included in a hydroxyethyl group and bonded to a primary carbon atom in a methylene group does not correspond to the methylol group.

When the alcohol AG2-1 is produced, due to the production method, a mixture including the alcohol AG2-2 may be unavoidably generated together with the alcohol AG2-1. For example, when the alcohol AG2-1 is produced by causing a reaction between a polyol including a secondary hydrocarbon group or a methylol group and a primary hydroxy group, and a (meth)acrylic acid halide or the like, an alcohol including a (meth)acryloyl group together with a primary hydroxyl group may be produced as a by-product. As long as a dicarboxylic acid including an ester group derived from the alcohol AG2-1 can be produced in a desired amount, a mixture including the alcohol AG2-2 together with the alcohol AG2-1 generated by such a method can be used as the alcohol to be reacted with a tetracarboxylic acid dianhydride.

Alcohol AG2-1 may include a combination of two or more hydroxyl groups. Alcohol AG2-1 may include a combination of a secondary hydroxyl group and a methylol group. Preferably, alcohol AG2-1 includes one secondary hydroxyl group or one methylol group.

When alcohol AG2-1 has two or more ethylenically unsaturated double bonds, alcohol AG2-1 is preferably a (meth)acrylate such as glycerin, trimethylolpropane, pentaerythritol, or dipentaerythritol and the like. Suitable specific examples of the alcohol AG2-1 having two or more (meth)acryloyl groups include glycerin-1,3-di(meth)acrylate, glycerin-1,2-di(meth)acrylate, trimethylolpropane di(meth)acrylate, pentaerythritol tri(meth)acrylate, and dipentaerythritol penta(meth)acrylate. These compounds may have a combination of an acryloyl group and a methacryloyl group.

When alcohol AG2-1 has one (meth)acryloyl group, alcohol AG2-1 is at least one selected from a compound represented by the following formula (I) and a compound represented by the following formula (II).

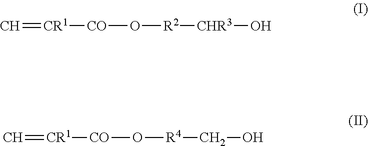

In the formula (I), R¹ is a hydrogen atom or a methyl group. R² is a divalent organic group bonded through a C—O bond to an oxygen atom in an ester bond and bonded through a C—C bond to a carbon atom to which R³ is bonded. R³ is a monovalent organic group bonded through a C—C bond to a carbon atom to which R³ is bonded. R² and R³ are bonded optionally to form a ring. In the formula (II), R′ is a hydrogen atom or a methyl group. R⁴ is a divalent organic group bonded through a C—O bond to an oxygen atom in an ester bond and bonded through a C—C bond to a methylol group in the formula (II),

In the above formula (I), R² is a divalent organic group bonded through a C—O bond to an oxygen atom in an ester bond and bonded through a C—C bond to a carbon atom to which R³ is bonded. The divalent organic group may be a group including a halogen atom, and a heteroatom such as O, S, and N. The number of carbon atoms in the divalent organic group as R² in the formula (I) is not particularly limited. The number of carbon atoms in the divalent organic group is, for example, preferably 1 or more and 20 or less, more preferably 1 or more and 12 or less, and further preferably 1 or more and 8 or less.

The divalent organic group as R² in the formula (I) is preferably a divalent hydrocarbon group. The divalent hydrocarbon group may include a cyclic group. The cyclic group may be an aliphatic ring, an aromatic ring, or a condensed ring in which an aliphatic ring and an aromatic ring are condensed. The divalent hydrocarbon group as R² is preferably an alkylene group.

Suitable examples of the alkylene group include a methylene group, an ethane-1,2-diyl group (ethylene group), an ethane-1,1-diyl group, a propane-1,3-diyl group, a propane-1,2-diyl group, a propane-1,1-diyl group, a butane-1,4-diyl group, a pentane-1,5-diyl group, a hexane-1,6-diyl group, a heptane-1,7-diyl group, and an octane-1,8-diyl group. Among these, a methylene group, an ethane-1,2-diyl group (ethylene group), a propane-1,3-diyl group, a butane-1,4-diyl group, and a pentane-1,5-diyl group are preferable.

In the formula (I), R³ is a monovalent organic group that is bonded through a C—C bond to the carbon atom to which R³ is bonded. The monovalent organic group may be a group including a halogen atom, and a heteroatom such as O, S, and N. The number of carbon atoms in the monovalent organic group as R³ in the formula (I) is not particularly limited. The number of carbon atoms in the monovalent organic group is preferably 1 or more and 20 or less, more preferably 1 or more and 12 or less, and further preferably 1 or more and 8 or less.

The monovalent organic group as R³ in the formula (I) may be a chain aliphatic group, a cyclic group, or a group consisting of a chain aliphatic group and a cyclic group. The cyclic group may be an aliphatic ring, an aromatic ring, or a condensed ring in which an aliphatic ring and an aromatic ring are condensed.

Specific examples of the monovalent organic group as R³ in the formula (I) include alkyl groups such as a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, and an n-octyl group; alkoxyalkyl group such as a methoxymethyl group, an ethoxymethyl group, an n-propyloxymethyl group, an n-butyloxymethyl group, a 2-methoxyethyl group, a 2-ethoxyethyl group, a 2-n-propyloxyethyl group, a 2-n-butyloxyethyl group, a 3-methoxypropyl group, a 3-ethoxypropyl group, a 3-n-propyloxypropyl group, a 3-n-butyloxypropyl group, a 4-methoxybutyl group, a 4-ethoxybutyl group, a 4-n-propyloxybutyl group, and a 4-n-butyloxybutyl group; aryloxyalkyl groups such as a phenoxymethyl group, a 2-phenoxyethyl group, a 3-phenoxypropyl group, and a 4-phenoxybutyl group; cycloalkyloxyalkyl groups such as a cyclopentyloxymethyl group, a 2-cyclopentyloxyethyl group, a 3-cyclopentyloxypropyl group, a 4-cyclopentyloxybutyl group, a cyclohexyloxymethyl group, a 2-cyclohexyloxyethyl group, 3-cyclohexyloxypropyl group, a 4-cyclohexyloxybutyl group, cycloheptyloxymethyl group, a 2-cycloheptyloxyethyl group, a 3-cycloheptyloxypropyl group, and a 4-cycloheptyloxybutyl group.

Suitable specific examples of the divalent group represented by —R²—CHR³— in the formula (I) include the following groups. In the following specific examples, * is a terminal of a bonding hand bonded to an oxygen atom in an ester bond in the formula (I). ** is a terminal of a bonding hand bonded to a hydroxyl group in the formula (I).

Note here that since a polyimide resin formed using a polyimide resin precursor shows a low dielectric loss tangent and has excellent chemical resistance, the divalent group represented by —R²—CHR³— in the formula (I) preferably includes a cyclic group. Such a cyclic group may be an aromatic group, an alicyclic group, or a condensed cyclic group in which an aromatic ring and an aliphatic ring are condensed,

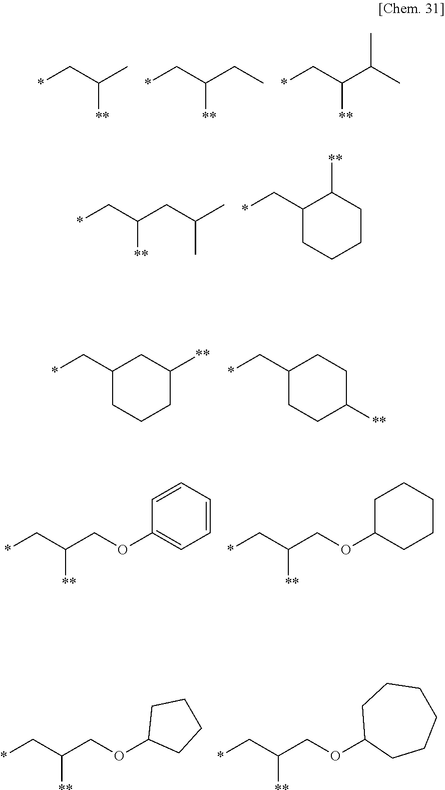

Preferable specific examples of the compound represented by the formula (I) include the following compounds.

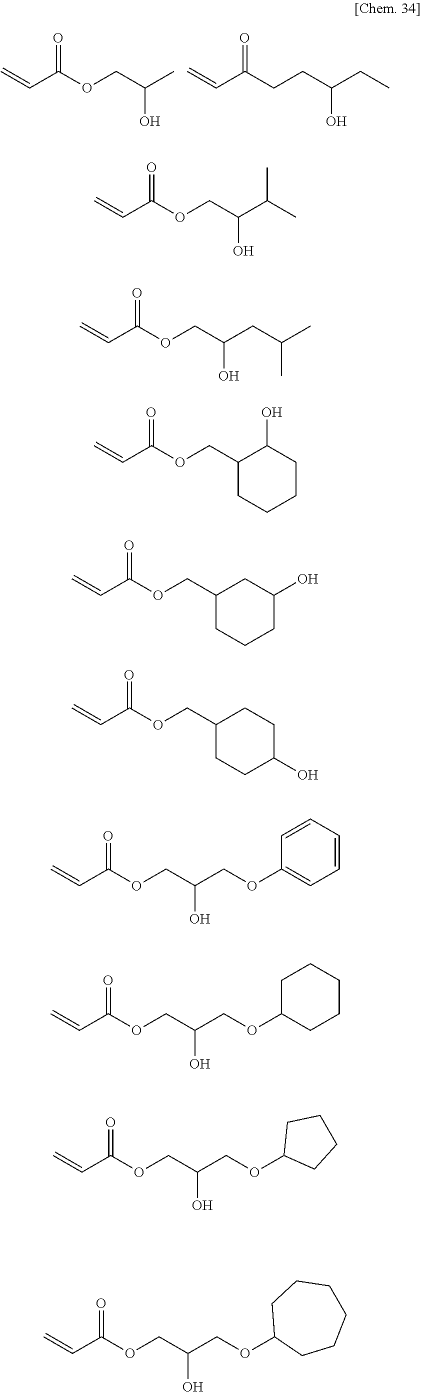

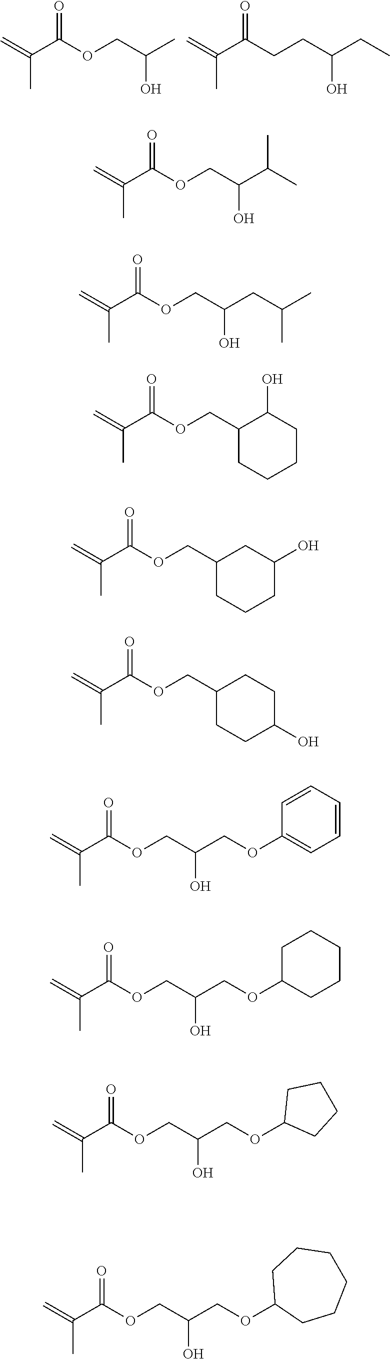

In the above formula (II), R⁴ is a divalent organic group that is bonded through a C—O bond to the oxygen atom in the ester bond and bonded through a C—C bond to a methylol group in the formula (II). The divalent organic group may be a group including a halogen atom, and a heteroatom such as O, S, and N. The number of carbon atoms in the divalent organic group as RA in the formula (II) is not particularly limited. The number of carbon atoms in the divalent organic group is preferably 1 or more and 20 or less, more preferably 1 or more and 12 or less, and further preferably 1 or more and 8 or less.

The divalent organic group as R⁴ in the formula (II) may be a chain aliphatic group, a cyclic group, or a group consisting of a chain aliphatic group and a cyclic group. The cyclic group may be an aliphatic ring, an aromatic ring, or a condensed ring in which an aliphatic ring and an aromatic ring are condensed.

Suitable specific examples of the divalent group represented by R⁴ in the formula (II) include the following groups. In the following specific examples, * is a terminal of a bonding hand bonded to an oxygen atom in an ester bond in the formula (II). ** is a terminal of a bonding hand bonded to a methylol group in the formula (II).

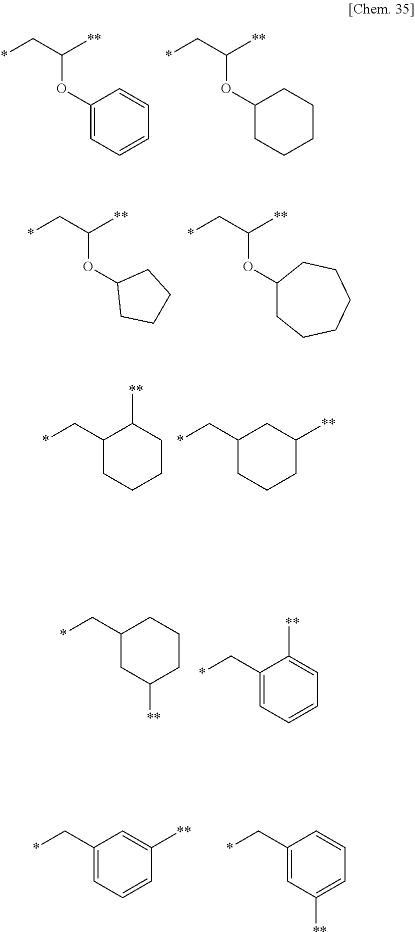

Preferable specific examples of the compound represented by the formula (II) include the following compounds.

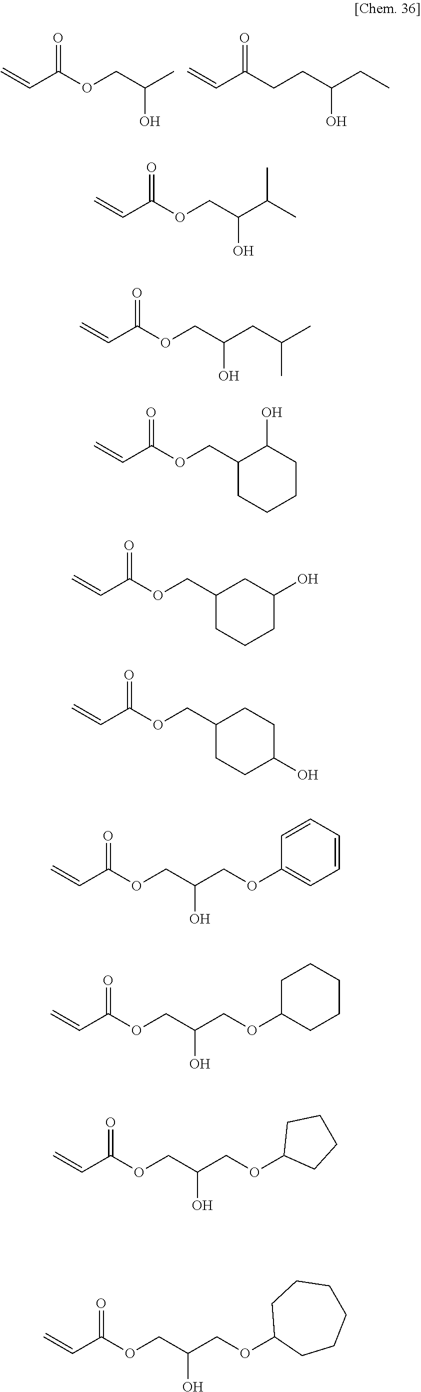

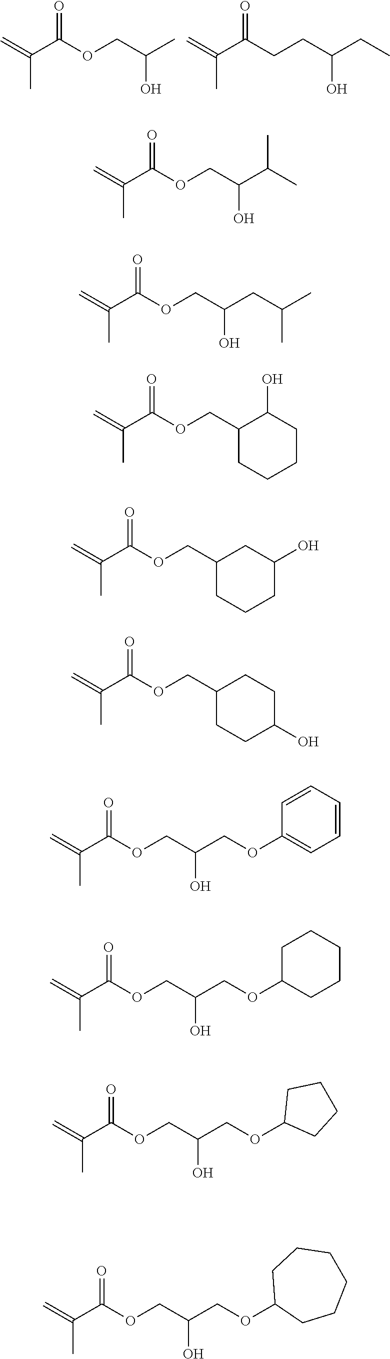

### Alcohol AG3

Alcohol AG3 is an alcohol not corresponding to the alcohol AG1 and the alcohol AG2. The alcohol may include the alcohol AG3 as long as the desired effect is not impaired. Accordingly, the polyimide resin precursor may include an organic group G3, which is an organic group not corresponding to the unsaturated group G1 and the (meth)acryloyl group-containing group G2, as the organic group as R^{A1} or R^{A2}.

A structure of the alcohol AG3 is not particularly limited as long as the desired effect is not impaired.

Examples of the alcohol AG3 include alkane monools such as methanol, ethanol, n-propanol, isopropanol, n-butanol, n-pentanol, and n-hexanol; phenols or naphthols such as phenol, p-cresol, m-cresol, o-cresol, q-naphthol, and B-naphthol; monoethers of glycols such as ethylene glycol monomethyl ether, ethylene glycol monoethyl ether, propylene glycol monomethyl ether, propylene glycol monoethyl ether, 1,3-propanediol monomethyl ether, 1,3-propanediol monoethyl ether, diethylene glycol monomethyl ether, diethylene glycol monoethyl ether, dipropylene glycol monomethyl ether, and dipropylene glycol monoethyl ether; an alcohol having radically a polymerizable group that does not correspond to the alcohol I.

### (Production of Dicarboxylic Acid)

A dicarboxylic acid can be obtained by reacting the above-described tetracarboxylic dianhydride with an alcohol. Alcohol reacts with carboxylic acid anhydride groups to generate carboxy groups and ester groups.

A dicarboxylic acid can be obtained by reacting the tetracarboxylic dianhydride described above with an alcohol represented by R^{a21}—OH. R^{a21} is a residue obtained by removing a hydroxyl group from the alcohol described above. Such a dicarboxylic acid has two pairs of a carboxy group and a group represented by —CO—O—R^{a21} positioned on adjacent carbon atoms in the dicarboxylic acid.

The dicarboxylic acid having 2 pairs of a carboxy group and a group represented by —CO—O—R^{a21} may have isomers in which the position of the carboxy group and the position of the group represented by —CO—O—R^{a21} differs. As the dicarboxylic acid above, one of such isomers may be used alone, or two or more of such isomers may be used in combination. The specification and claims of the present application allow the polyimide resin precursor to contain a plurality of types of structural units derived from a plurality of isomers of dicarboxylic acids.

As an example, the dicarboxylic acid corresponding to pyromellitic dianhydride includes a compound represented by the following formula (a4-a1) and a compound represented by the following formula (a4-a2) as isomers. The dicarboxylic acid corresponding to 1,4-bis(3,4-dicarboxyphenoxy)benzene dianhydride include a compound represented by the following formula (a4-b1), a compound represented by the following formula (a4-b2), and a compound represented by the following formula (a4-b3) as isomers. In the following formula (a4-a1), formula (a4-a2), and formulae (a4-b1) to (a4-b3), R^{a21} is the same as mentioned above respectively.

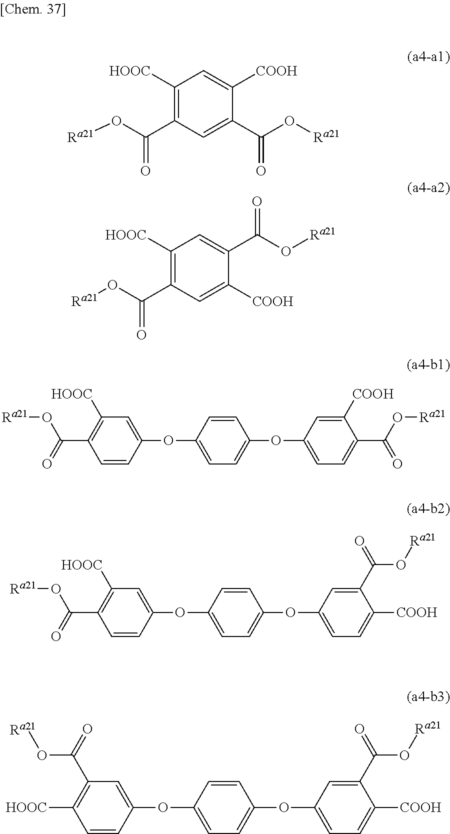

Examples of the dicarboxylic acid corresponding to the tetracarboxylic acid dianhydride represented by the above formulae (a3-2) to (a3-4) include compounds represented by the following formulae (a4-2a) to (a4-2c), (a4-3a) to (a4-3c), and (24-4a) to (a4-4c). In the formulae (a4-2a) to (a4-2c), (a4-3a) to (a4-3c), and (a4-4a) to (a4-4c), R^{a01} to R^{a05} are the same as those in the formulae (a3-2) to (a3-4). In the formulae (a4-2a) to (a4-2c), (a4-3a) to (a4-3c), and (a4-4a) to (a4-4c), R^{a21} is as described above.

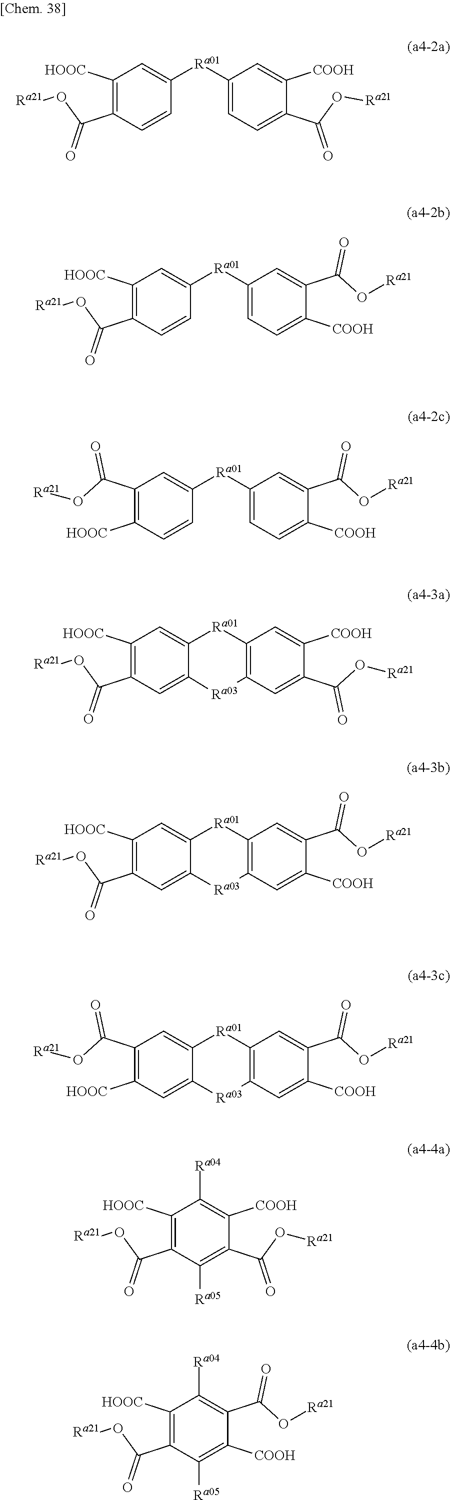

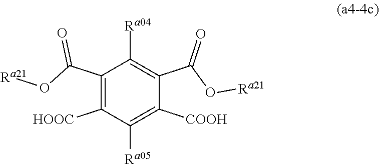

Examples of the dicarboxylic acid corresponding to the tetracarboxylic dianhydride represented by the above formulae (a3-5) to (a3-7) include compounds represented by the following formulae (a4-5a) to (a4-5c), (a4-6a) to (a4-6c), (24-7a), and (a4-7b). In the formulae (a4-5a) to (a4-5c), (a4-6a) to (a4-6c), (a4-7a), and (a4-7b), R^{a01} to R^{a03}, R^{a06}, m1, and m2 are the same as those in the formulae (a3-5) to (a3-7). In the Formulae (a4-5a) to (a4-5c), (a4-6a) to (a4-6c), (a4-7a), and (a4-7b), R^{a21} is as described above.

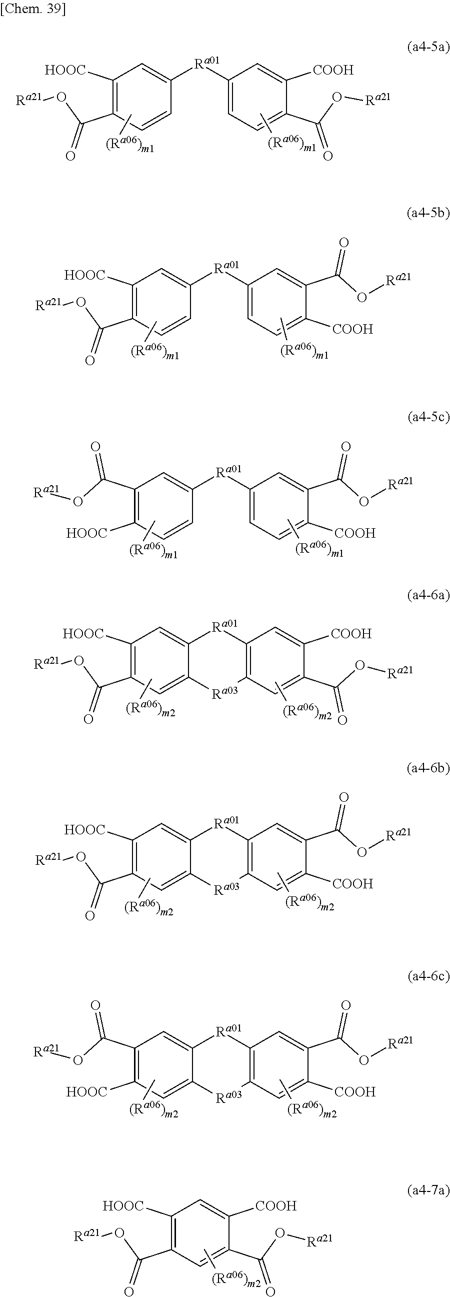

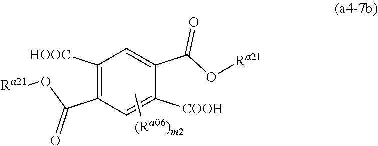

The reaction between tetracarboxylic dianhydride and alcohol is usually carried out in an organic solvent. The organic solvent used for the reaction of tetracarboxylic dianhydride and alcohol is not particularly limited as long as the solvent can dissolve tetracarboxylic dianhydride and alcohol and does not react with tetracarboxylic dianhydride and alcohol. Organic solvents can be used alone or in combination of two or more.

Examples of the organic solvent used for the reaction of tetracarboxylic dianhydride and alcohol include nitrogen-containing polar solvents such as N-methyl-2-pyrrolidone, N-ethyl-2-pyrrolidone, 1,3-dimethyl-2-imidazolidinone, N,N-dimethylacetamide, N,N-dimethylpropionamide, N,N-dimethylisobutyramide, N,N-diethylacetamide, N,N-dimethylformamide, N,N-diethylformamide, N,N-dimethylisobutyric acid amide, methoxy-N,N-dimethylpropionamide, butoxy-N,N-dimethylpropionamide, N-methylcaprolactam, N,N′-dimethylpropyleneurea, N,N,N′,N′-tetramethylurea, and pyridine; dimethyl sulfoxide; sulfolane; lactones such as γ-butyrolactone, γ-valerolactone, δ-valerolactone, γ-caprolactone, ε-caprolactone, and α-methyl-γ-caprolactone; esters such as methyl acetate, ethyl acetate, butyl acetate, and diethyl oxalate; carbonates such as ethylene carbonate and propylene carbonate; ketones such as acetone, methyl ethyl ketone, methyl isobutyl ketone, and cyclohexanone; acetonitrile; ethers such as ethylene glycol dimethyl ether, diethylene glycol dimethyl ether, diethylene glycol diethyl ether, dioxane, and tetrahydrofuran; halogenated hydrocarbons such as dichloromethane, 1,2-dichloroethane, 1,4-dichlorobutane, chlorobenzene, and o-dichlorobenzene; hydrocarbons such as hexane, heptane, benzene, toluene, and xylene. These organic solvents may be used alone or in combination of two or more.

Among these organic solvents, nitrogen-containing polar solvents such as N-methyl-2-pyrrolidone, N,N-dimethylacetamide, N,N-diethylacetamide, N,N-dimethylformamide, N,N-diethylformamide, N-methylcaprolactam, and N,N,N′,N′-tetramethylurea are preferable.

The temperature at which the tetracarboxylic dianhydride and alcohol are reacted is not particularly limited as long as the reaction proceeds well. Typically, the reaction temperature between the tetracarboxylic dianhydride and the alcohol is preferably-5° C. or higher and 120° C. or lower, more preferably 0° C. or higher and 80° C. or lower, and particularly preferably 0° C. or higher and 50° C. or lower. The time for reacting the tetracarboxylic dianhydride and the alcohol varies depending on the reaction temperature, but typically, the time is preferably 30 minutes or more and 20 hours or less, more preferably 1 hour or more and 8 hours or less, and particularly preferably 2 hours or more and 6 hours or less.

A small amount of polymerization inhibiting agent may be used for the purpose of preventing crosslinking between ethylenically unsaturated double bonds during the reaction between the tetracarboxylic dianhydride and the alcohol. Examples of the polymerization inhibiting agent include phenols such as hydroquinone, 4-methoxyphenol, tert-butylpyrocatechol, and bis-tert-butylhydroxytoluene, and phenothiazine. The amount of the polymerization inhibiting agent used is, for example, preferably 0.01% by mol or more and 5% by mol or less with respect to the number of moles of ethylenically unsaturated double bonds.

The reaction between tetracarboxylic dianhydride and alcohol may be carried out in the presence of an organic base such as pyridine, triethylamine, diisopropylethylamine, 4-dimethylaminopyridine, 1,4-azabicyclo[2,2,2]octane, and the like. These bases may be used alone or two or more types of the bases may be used simultaneously.

The amount of alcohol used is preferably 1.8 mol or more and 2.2 mol or less, and more preferably 2 mol or more and 2.1 mol or less, with respect to 1 mol of tetracarboxylic dianhydride.

In the production of the dicarboxylic acid, depending on the production conditions, only one dicarboxylic acid anhydride group is reacted with alcohol to produce a monocarboxylic acid compound having a dicarboxylic acid anhydride group, or a tetracarboxylic acid compound or a tricarboxylic acid compound is produced by reacting a part of a tetracarboxylic acid dianhydride with water in a reaction system. As long as the desired effect is not impaired, a dicarboxylic acid containing at least one selected from the above monocarboxylic acid compounds, tricarboxylic acid compounds, and tetracarboxylic acid compounds can be used in production of the polyimide resin precursor. When the dicarboxylic acid includes at least one kind selected from the above monocarboxylic acid compounds, tricarboxylic acid compounds, and tetracarboxylic acid compounds as an impurity, the content of at least one kind selected from the above monocarboxylic acid compounds, tricarboxylic acid compounds, and tetracarboxylic acid compounds as an impurity in the dicarboxylic acid is preferably 30% by mass or less, more preferably 10% by mass or less, further preferably 5% by mass or less, and particularly preferably 1% by mass or less with respect to the mass of the dicarboxylic acid including the mass of the impurity.

### [Production Method for Polyimide Resin Precursor]

A production method for a polyimide resin precursor is not particularly limited as long as the method is capable of polycondensing the above-mentioned diamine compound and the dicarboxylic acid until the weight average molecular weight of the polyimide resin precursor increases to a desired degree. A preferable method includes a method of condensing the above-mentioned diamine compound and dicarboxylic acid in the presence of a condensing agent. It is also preferable to use a condensation aid together with the condensation agent, if necessary. The condensing agent and the condensing aid are not particularly limited as long as they are compounds conventionally used for condensing dicarboxylic acids and diamine compounds.

Preferable condensing agents include at least one selected from the group consisting of dicyclohexylcarbodiimide, diisopropylcarbodiimide, 1-(3-dimethylaminopropyl)-3-ethylcarbodiimide, diisopropylcarbodiimide, 1-(3-dimethylaminopropyl)-3-ethylcarbodiimide hydrochloride, 1-cyclohexyl-3-(2-morpholinoethyl)-carbodiimide methotoluenesulfonate, 1,3-bis(2,2-dimethyl-1,3-dioxolan-4-ylmethyl) carbodiimide, polymer-supported 1-benzyl-3-cyclohexylcarbodiimide, and polymer-supported 1-(3-dimethylaminopropyl)-3-ethylcarbodiimide.

The amount of the condensing agent used is not particularly limited as long as a polyimide resin precursor having a desired molecular weight can be obtained. The amount of the condensing agent used is typically preferably 1 mol or more and 5 mols or less, more preferably 2 mols or more and 4 mols or less, and furthermore preferably 2 mols or more and 3 mols or less, with respect to 1 mol of dicarboxylic acid. Furthermore, the ratio between the amount of dicarboxylic acid and the amount of diamine compound when producing a polyimide resin precursor is not particularly limited as long as a polyimide resin precursor having a desired molecular weight can be produced. When the polyimide resin precursor has an amino group terminal, the raw material ratio represented by (number of moles of dicarboxylic acid)/(number of moles of diamine compound) is preferably in a range from 0.5/1 to 0.95/1, and more preferably in a range from 0.55/1 to 0.80/1. The smaller the value of (number of moles of dicarboxylic acid)/(number of moles of diamine compound) is, the more difficult it is for molecular chain of the polyimide resin precursor to extend, and the easier to obtain a low molecular weight polyimide resin precursor. When the polyimide resin precursor has a carboxy group terminal, the raw material ratio represented by (number of moles of diamine compound)/(number of moles of dicarboxylic acid) is preferably in a range from 0.5/1 to 0.95/1, and more preferably in a range from 0.55/1 to 0.80/1. The smaller the value of (number of moles of diamine compound)/(number of moles of dicarboxylic acid) is, the more difficult it is for the molecular chain of the polyimide resin precursor to extend, and the easier to obtain a low molecular weight polyimide resin precursor.

Specifically, a dicarboxylic acid and a diamine compound are reacted in an organic solvent in the presence of the above-mentioned condensing agent at, for example, −20° C. or higher and 150° C. or lower, and preferably 0° C. or higher and 50° C. or lower, for 30 minutes or more and 24 hours or less, and preferably for 1 hour or more and 4 hours or less.

As the solvent used in the polycondensation, the above-mentioned solvents that can be used in the reaction between tetracarboxylic dianhydride and alcohol can be used. The amount of the solvent used is preferably 50 parts by mass or more and 10,000 parts by mass or less, more preferably 100 parts by mass or more and 2,000 parts by mass or less, further preferably 150 parts by mass or more and 1,000 parts by mass or less with respect to the total of 100 parts by mass of the dicarboxylic acid and the diamine compound.

The amount of dicarboxylic acid and diamine compound to be used when producing a polyimide resin precursor is not particularly limited, but it is preferable that the diamine compound to be used is preferably 0.8 mol or more and 1.2 mol or less, more preferably 0.9 mol or more and 1.1 mol or less, and particularly preferably 0.95 mol or more and 1.05 mol or less with respect to 1 mol of dicarboxylic acid.

Since it is easy to obtain a polyimide resin precursor that gives a polyimide resin that exhibits excellent dielectric properties in a high frequency band, the polyimide resin precursor preferably includes a divalent aliphatic hydrocarbon group having preferably 2 or more and 50 or less carbon atoms, more preferably 3 or more and 40 or less carbon atoms. The position of the divalent aliphatic hydrocarbon group in the molecular chain of the polyimide resin precursor is not particularly limited. Examples of monomers that provide a divalent aliphatic hydrocarbon group having 2 or more and 50 or less carbon atoms in the molecular chain include the dimer diamine compound (A-4) described above and the α,ω-bis(3,4-dicarboxyphenylcarbonyloxy)alkane dianhydride described above.

Since it is easy to obtain a polyimide resin precursor giving a polyimide resin that exhibits excellent dielectric properties in a high frequency band, the polyimide resin composition preferably includes a structural unit derived from a carboxylic acid derived from a tetracarboxylic dianhydride represented by the following formula (a1) and/or a structural unit derived from a diamine compound represented by the following formula (a2). The tetracarboxylic dianhydride represented by the formula (a1) and the diamine compound represented by the formula (a2) are as described above,

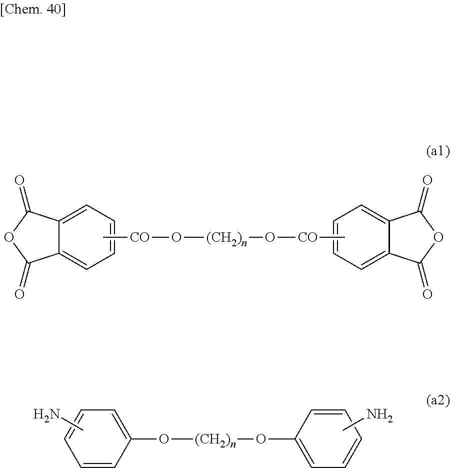

In the formulae (a1) and (a2), n is an integer of 1 or more.

The weight average molecular weight of the polyimide resin precursor may be appropriately set according to its use. The weight average molecular weight of the polyimide resin precursor can be measured as a weight average molecular weight in terms of polystyrene by GPC (gel permeation chromatography). The weight average molecular weight of the polyimide resin precursor in terms of polystyrene is, for example, 5,000 or more, preferably 15,000 or more, and more preferably 250,000,000 or more, from the viewpoint of obtaining a resin film with good mechanical properties. On the other hand, the weight average molecular weight of the obtained polyimide resin precursor in terms of polystyrene is, for example, 100,000 or less, preferably 80,000 or less, and more preferably 50,000 or less, from the viewpoint of solubility in organic solvents. This weight average molecular weight may be set to the above value by adjusting the blending amounts of the dicarboxylic acid and diamine compound described above, and reaction conditions such as the solvent, reaction temperature and the like.

For the purpose of improving the storage stability of photosensitive resin compositions including a polyimide resin precursor, further improving the mechanical properties of polyimide resin films, and improving the reproducibility of polymerization when producing polyimide resin precursors and the like, the main chain terminal of the polyimide resin precursor may be sealed with a terminal sealing agent and the like. Examples of the terminal sealing agent include monoamines, acid anhydrides, monocarboxylic acids, monoacid halides, monoactive ester compounds, and the like. As the monoamine used for terminal-sealing, well-known compounds can be used. Examples of monoamines include aromatic monoamines such as aniline, 2-ethynylaniline, 3-ethynylaniline, 4-ethynylaniline, 3-hydroxyaniline, 4-hydroxyaniline, 3-aminothiophenol, and 4-aminothiophenol; aliphatic monoamines optionally having a branched structure having 3 or more and 20 or less carbon atoms such as hexylamine and octylamine; monoamines having an alicyclic structure such as cyclohexylamine; aminosilanes such as trimethoxyaminopropylsilane and triethoxyaminopropylsilane. Among acid anhydrides, monoacid halides, and monoactive ester compounds used as terminal sealing agents, acid anhydrides are preferable. As the acid anhydride, well-known acid anhydrides and derivatives thereof can be used. Examples thereof include phthalic anhydride, tetrahydrophthalic anhydride, hexahydrophthalic anhydride, exo-3,6-epoxy-1,2,3,6-tetrahydrophthalic anhydride, succinic anhydride, maleic anhydride, nadic acid anhydride, and derivatives thereof. The introduction rate of the terminal sealing agent in the polyimide resin precursor is preferably 40% by mol or less, more preferably 20% by mol or less, and further preferably 10% by mol or less with respect to the number of moles of all monomers, from the viewpoint of excellent mechanical properties of the polyimide resin film to be formed.

The polyimide resin precursor produced as described above is used for production of polyimide resin in the form of a solution or suspension, or after being separated and recovered from the reaction solution by a well-known method.

### <<Polyimide Resin>>

A polyimide resin is obtained by imidizing the polyimide resin precursor described above. The polyimide resin exhibits a low dielectric loss tangent in a high frequency band and has excellent chemical resistance. The method of imidization of the polyimide resin precursor is not particularly limited. The imidization may be performed by heating or using an imidization agent.

When imidization is carried out by heating, heating may be carried out with respect to a solution or a suspension of the polyimide resin precursor, or may be carried out with respect to a solid polyimide resin precursor. When imidization is carried out by heating the solution of polyimide resin precursor, heating is preferably carried out while removing water produced as a by-product during imidization. The heating conditions for imidization are not particularly limited as long as the polyimide resin precursor is not decomposed and imidization progresses well. When heating a solution of a polyimide resin precursor, typically, the heating temperature is preferably 80° C. or more 220° C. or less, more preferably 100° C. or more 200° C. or less, and particularly preferably 120° C. or more and 180° C. or less. When heating a solid polyimide resin precursor, the heating temperature is typically preferably 180° C. or more and 400° C. or less, and more preferably 200° C. or more and 350° C. or less. Although the heating time depends on the heating temperature, typically, the heating time is preferably 1 hour or more and 24 hours or less, and more preferably 2 hours or more and 12 hours or less.

When imidization of a polyimide resin precursor is carried out with an imidizing agent, imidization is usually carried out by adding the imidizing agent to a solution or a suspension of the polyimide resin precursor. As an organic solvent that can be used when imidization is carried out with an imidizing agent, for example, the same organic solvent as those can be used for preparing the polyimide resin precursor can be used. When imidization is carried out with an imidizing agent, the concentration of the polyimide resin precursor in the solution or suspension of the polyimide resin precursor is not particularly limited. Typically, the concentration of the polyimide resin precursor in the solution or suspension of the polyimide resin precursor is preferably 5% by mass or more and 50% by mass or less, and more preferably 10% by mass or more and 30% by mass or less. The amount of the imidizing agent used is not particularly limited. The amount of the imidizing agent used is selected depending on the type of imidizing agent so that the polyimide resin precursor is imidized to a desired degree. The reaction temperature when imidization is carried out with an imidizing agent is not particularly limited. The reaction temperature is, for example, preferably 0° C. or higher and 100° C. or lower, and more preferably 5° C. or higher and 50° C. or lower. The time for the imidization reaction when an imidization agent is used is not particularly limited. The imidization reaction is preferably carried out for 30 minutes or more to about 24 hours, more preferably 1 hour or more and 12 hours or less, and further preferably 2 hours or more and 6 hours or less, depending on the type of imidization agent.

Examples of the imidizing agents include dehydrating agents such as acetic anhydride, propionic anhydride, benzoic anhydride, trifluoroacetic anhydride, acetyl chloride, tosyl chloride, mesyl chloride, ethyl chloroformate, triphenylphosphine and dibenzimidazolyl disulfide, dicyclohexylcarbodiimide, carbodiimidazole, 2-ethoxy-1-ethoxycarbonyl-1,2-dihydroquinoline, and oxalic acid N,N′-disuccinimidyl ester; basic compounds such as pyridine, picoline, 2,6-lutidine, collidine, triethylamine, N-methylmorpholine, 4-N,N′-dimethylaminopyridine, isoquinoline, triethylamine, 1,4-diazabicyclo[2.2.2]octane, and 1,8-diazabicyclo[5.4.0]-7-undecene,

### <<Photosensitive Resin Composition>>

A photosensitive resin composition includes a polymerizable resin (A), a photoradical polymerization initiating agent (C), and a solvent(S). The polymerizable resin (A) is the polyimide resin precursor described above. Using such a photosensitive resin composition, a patterned polyimide resin film can be formed by the method described below. The resin film exhibits a low dielectric loss tangent in a high frequency band and has excellent chemical resistance.

The photosensitive resin composition may include a monomer compound (B) having a radically polymerizable group.

Hereinafter, components that are essentially or optionally included in the photosensitive resin composition will be explained.

### <Polymerizable Resin (A)>

The polymerizable resin (A) is the polyimide resin precursor described above.

### <Monomer Compound (B)>

As the monomer compound (B), a monomer compound including an ethylenically unsaturated double bond as a radically polymerizable group is preferably used. Such a monomer compound (B) may be a monofunctional monomer compound or a polyfunctional monomer compound, and a polyfunctional monomer compound is preferable.

Examples of the monofunctional monomer compounds include (meth)acrylamide, methylol (meth)acrylamide, methoxymethyl (meth)acrylamide, ethoxymethyl (meth)acrylamide, propoxymethyl (meth)acrylamide, butoxymethoxymethyl (meth)acrylamide, N-methylol (meth)acrylamide, N-hydroxymethyl (meth)acrylamide, (meth)acrylic acid, fumaric acid, maleic acid, maleic anhydride, itaconic acid, itaconic anhydride, citraconic acid, citraconic anhydride, crotonic acid, 2-acrylamido-2-methylpropanesulfonic acid, tert-butylacrylamide sulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerin mono(meth)acrylate, tetrahydrofurfuryl (meth)acrylate, dimethylamino(meth)acrylate, glycidyl (meth)acrylate, 2,2,2-trifluoroethyl(meth)acrylate, 2,2,3,3-tetrafluoropropyl (meth)acrylate, and half (meth)acrylate of phthalic acid derivatives. These monofunctional photopolymerizable monomers can be used alone or in combination of two or more.

Examples of the polyfunctional monomer compounds include ethylene glycol di(meth)acrylate, diethylene glycol di(meth)acrylate, triethylene glycol di(meth)acrylate, tetraethylene glycol di(meth)acrylate, polyethylene glycol di(meth)acrylate, propylene glycol di(meth)acrylate, polypropylene glycol di(meth)acrylate, 1,3-butylene glycol di(meth)acrylate, 1,4-butylene glycol di(meth)acrylate, neopentyl glycol di(meth)acrylate, 1,6-hexane glycol di(meth)acrylate, 1,9-nonanediol di(meth)acrylate, 1,10-decanediol di(meth)acrylate, dimethyloltricyclodecane di(meth)acrylate, trimethylolpropane di(meth)acrylate, trimethylolpropane tri(meth)acrylate, trimethylolethane tri(meth)acrylate, trimethylolpropane tri(3-(meth)acryloyloxypropyl)ether, glycerin di(meth)acrylate, tri(meth)acrylate of glycerin ethylene oxide (EO) adduct, tri(meth)acrylate of glycerin propylene oxide (PO) adduct, tri(meth)acrylate of glycerin EO/PO co-adduct, tri(meth)acrylate of trimethylolpropaneethylene EO adduct, tri(meth)acrylate of trimethylolpropane PO adduct, tri(meth)acrylate of trimethylolpropane EO/PO co-adduct, tri(meth)acrylate of trimethylolethane EO adduct, tri(meth)acrylate of trimethylolethane PO adduct, tri(meth)acrylate of trimethylolethane EO/PO co-adduct, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, tetrapentaerythritol nona(meth)acrylate, tetrapentaerythritol deca(meth)acrylate, pentapentaerythritol undeca(meth)acrylate, pentapentaerythritol dodeca(meth)acrylate, dimethylol-tricyclodecane di(meth)acrylate, 1,3-adamantanediol di(meth)acrylate, 1,3,5-adamantane triol di(meth)acrylate, 1,3,5-adamantanetrioltri(meth)acrylate, 1,4-cyclohexanedimethanol di(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl(meth)acrylate, 9,9-bis[4-(2-(meth)acryloyloxyethoxy)phenyl]fluorene, 9,9-bis[4-(2-(meth)acryloyloxypropoxy)-3-methylphenyl]fluorene, 9,9-bis[4-(2-(meth)acryloyloxyethoxy)-3,5-dimethylphenyl]fluorene, ethylene glycol diglycidyl ether di(meth)acrylate, diethylene glycol diglycidyl ether di(meth)acrylate, phthalic acid diglycidyl ester di(meth)acrylate, glycerin triacrylate, glycerin polyglycidyl ether poly(meth)acrylate, urethane (meth)acrylate (i.e., tolylene diisocyanate), a reactant of trimethylhexamethylene diisocyanate, hexamethylene diisocyanate, and 2-hydroxyethyl (meth)acrylate, tri((meth)acryloyloxyethyl) isocyanurate, methylene bis(meth)acrylamide, (meth)acrylamide methylene ether, polyfunctional monomer compounds such as condensates of polyhydric alcohol, N-methylol(meth)acrylamide, triacrylic formal, and the like. These polyfunctional monomer compounds can be used alone or in combination of two or more.

Also, urethane (meth)acrylates described in Japanese Examined Patent Application Publication No. S48-41708, Japanese Examined Patent Application Publication No. S50-6034, and Japanese Unexamined Patent Application Publication No. S51-37193; polyester (meth)acrylates described in Japanese Unexamined Patent Application Publication No. S48-64183, Japanese Examined Patent Application Publication No. S49-43191, and Japanese Examined Patent Application Publication No. S52-30490; epoxy (meth)acrylates as reaction products of epoxy resin and (meth)acrylic acid; compounds described in paragraphs to of Japanese Unexamined Patent Application Publication No. 2008-292970; polyfunctional (meth)acrylate obtained by reacting a polyfunctional carboxylic acid with a compound having an epoxy group such as glycidyl (meth)acrylate and an ethylenically unsaturated group; a compound having a fluorene ring and two or more groups having an ethylenically unsaturated bond or cardo resin, described in Japanese Unexamined Patent Application Publication No. 2010-160418, Japanese Unexamined Patent Application Publication No. 2010-129825, and Japanese Patent No. 4364216, etc.; unsaturated compounds described in Japanese Examined Patent Application Publication No. S46-43946, Japanese Examined Patent Application Publication No. H1-40337, and Japanese Examined Patent Application Publication No. H1-40336; vinylphosphonic acid compounds described in Japanese Unexamined Patent Application Publication No. H2-25493; compound including a perfluoroalkyl group described in Japanese Unexamined Patent Application Publication No. S61-22048; photopolymerizable monomers and oligomers described in Journal of Japan Adhesion Society, vol. 20, No. 7 in pages 300-308 (1984) are also preferably used.

Among these monomer compounds (B) having ethylenically unsaturated double bonds, polyfunctional monomer compounds having trifunctionality or more are preferable, a polyfunctional monomer compound having four or more functionalities is more preferable, and a polyfunctional monomer compound having five or more functionalities is even more preferable, since the adhesion of the polyimide resin film to the substrate and the strength of the polyimide resin film tend to be increased.

The content of the monomer compound (B) in the photosensitive resin composition is not particularly limited as long as it does not impede the purpose of the present invention. The content of the monomer compound (B) in the photosensitive resin composition is preferably 0.1 parts by mass or more and 50 parts by mass or less, more preferably 0.5 parts by mass or more and 40 parts by mass or less, and particularly preferably 1 part by mass or more and 25 parts by mass or less when the mass of the photosensitive resin composition excluding the mass of the solvent(S) described below is 100 parts by mass.

### <Photoradical Polymerization Initiatoing Agent (C)>

The photoradical polymerization initiating agent (C) is not particularly limited, and conventionally known photopolymerization initiating agents can be used.

Specifically, the photoradical polymerization initiating agent (C) includes 1-hydroxycyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 1-(4-isopropylphenyl)-2-hydroxy-2-methylpropan-1-one, 2-hydroxy-1-{4-[4-(2-hydroxy-2-methyl-propionyl)-benzyl]phenyl}-2-methyl-propan-1-one, 1-(4-dodecylphenyl)-2-hydroxy-2-methylpropan-1-one, 2,2-dimethoxy-1,2-diphenylethan-1-one, bis(4-dimethylaminophenyl) ketone, 2-methyl-1-[4-(methylthio)phenyl]-2-morpholinopropan-1-one, 2-benzyl-2-dimethylamino-1-(4-morpholinophenyl)-butan-1-one, 2-(4-methylbenzyl)-2-dimethylamino-1-(4-morpholinophenyl)-butan-1-one, 1-phenyl-1,2-propanedione-2-(0-ethoxycarbonyl) oxime, 1-phenyl-1,2-propanedione-2-(O-methoxycarbonyl) oxime, 1-phenyl-2-(benzoyloximimino)-1-propanone, 1-phenyl-1,2-butadione-2-(0-methoxycarbonyl) oxime, 1,3-diphenylpropanetrione-2-(0-ethoxy carbonyl) oxime, ethanone, 1-phenyl-1,2-propanedione-2-(0-benzoyl) oxime, 1-phenyl-3-ethoxypropanetrione-2-(0-benzoyl) oxime, O-acetyl-1-[6-(2-methylbenzoyl)-9-ethyl-9H-carbazol-3-yl]ethanone oxime (Irgacure OXE02, manufactured by BASE Japan), (9-ethyl-6-nitro-9H-carbazole-3-yl) [4-(2-methoxy-1-methylethoxy)-2-methylphenyl]methanone O-acetyloxime, 1-[9-ethyl-6-(2-methylbenzoyl)-9H-carbazole-3-yl]-, 1-(0-acetyloxime), 2-(benzoyloxyimino)-1-[4-(phenylthio)phenyl]-1-octanone (Irgacure OXE01, manufactured by BASF Japan), NCI-831 (manufactured by ADEKA), NCI-930 (manufactured by ADEKA), OXE-03 (manufactured by BASF Japan), OXE-04 (manufactured by BASE Japan), 2,4,6-trimethylbenzoyldiphenylphosphine oxide, bis(2,4,6-trimethylbenzoyl)-phenylphosphine oxide, bis(2,6-dimethoxybenzoyl)-2,4,4-trimethylpentylphosphine oxide, 4-benzoyl-4′-methyldimethylsulfide, 4-dimethylaminobenzoic acid, methyl 4-dimethylaminobenzoate, ethyl 4-dimethylaminobenzoate, butyl 4-dimethylaminobenzoate, 2-ethylhexyl 4-dimethylaminobenzoate, 2-isoamyl 4-dimethylaminobenzoate, ethyl 4-diethylbenzoate, benzyl-β-methoxyethyl acetal, benzyl dimethyl ketal, 1-phenyl-1,2-propanedione-2-(O-ethoxycarbonyl) oxime, methyl o-benzoylbenzoate, methyl benzoylformate, ethyl benzoylformate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, anthraquinone, 2-ethylanthraquinone, 2-tert-butylanthraquinone, octamethylanthraquinone, 2-aminoanthraquinone, β-chloroanthraquinone, 1,2-benzanthraquinone, 2,3-diphenylanthraquinone, anthrone, benzanthrone, dibenzsuberone, methylene anthrone, azobisisobutyronitrile, benzoyl peroxide, cumene hydroperoxide, 2-mercaptobenzimidazole, 2-mercaptobenzoxazole, 2-mercaptobenzothiazole, 2-(o-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′-dichlorobenzophenone, 3,3-dimethyl-4-methoxybenzophenone, 4-hydroxybenzophenone, 4-phenylbenzophenone, fluorenone, benzyl, benzoin, benzoin methyl ether, benzoin ethyl ether, benzoin isopropyl ether, benzoin-n-butyl ether, benzoin isobutyl ether, acetophenone, 2,2-diethoxyacetophenone, p-dimethylacetophenone, p-dimethylaminopropiophenone, 2-hydroxy-2-methylpropiophenone, dichloroacetophenone, trichloroacetophenone, p-tert-butylacetophenone, 2-phenylacetophenone, p-dimethylaminoacetophenone, p-tert-butyltrichloroacetophenone, p-tert-butyldichloroacetophenone, α,α-dichloro-4-phenoxyacetophenone, thioxanthone, 2-methylthioxanthone, 2-isopropylthioxanthone, 2,4-dimethylthioxanthone, 2,4-diethylthioxanthone, 2-chlorothioxanthone, 2,4-dichlorothioxanthone, 2-hydroxy-3-(3,4-dimethyl-9-oxo-9H-thioxanthene-2-yloxy)-N,N,N-trimethyl-1-propanaminium chloride, 4-azidobenzalacetophenone, 2,6-bis(p-azidobenzylidene)cyclohexane, 2,6-bis(p-azidobenzylidene)-4-methylcyclohexanone, dibenzosuberone, pentyl-4-dimethylaminobenzoate, 9-phenylacridine, 1,7-bis-(9-acridinyl)heptane, 1,5-bis-(9-acridinyl)pentane, 1,3-bis-(9-acridinyl)propane, p-methoxytriazine, 2,4,6-tris(trichloromethyl)-s-triazine, 2-methyl-4,6-bis(trichloromethyl)-s-triazine, 2-[2-(5-methylfuran-2-yl) ethenyl]-4,6-bis(trichloromethyl)-s-triazine, 2-[2-(furan-2-yl) ethenyl]-4,6-bis(trichloromethyl)-s-triazine, 2-[2-(4-diethylamino-2-methylphenyl) ethenyl]-4,6-bis(trichloromethyl)-s-triazine, 2-[2-(3,4-dimethoxyphenyl) ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy) styrylphenyl-s-triazine, 2,4-bis-trichloromethyl-6-(2-bromo-4-methoxy) styrylphenyl-s-triazine, 4-benzoyl-4′-methyl diphenyl ketone, dibenzyl ketone, 4-benzoyl-4′-methyl-diphenyl sulfide, alkylated benzophenone, 3,3′,4,4′-tetra(t-butylperoxycarbonyl)benzophenone, 4-benzoyl-N,N-dimethyl-N-[2-(1-oxo-2-propenyloxy)ethyl]benzenemethanaminium bromide, (4-benzoylbenzyl)trimethylammonium chloride, 2-hydroxy-3-(4-benzoylphenoxy)-N,N,N-trimethyl-1-propenaminium chloride monohydrate, naphthalenesulfonyl chloride, quinolinesulfonyl chloride, N-phenylthioacridone, benzthiazole disulfide, triphenylphosphine, carbon tetrabromide, and tri-bromophenyl sulfone. These photoradical polymerization initiating agents (C) can be used alone or in combination of two or more thereof. From the viewpoint that sensitivity is good, an oxime ester-based photopolymerization initiating agent is preferable as the photoradical polymerization initiating agent (C).

Among the photoradical polymerization initiating agents (C), oxime ester compounds are preferable from the viewpoint of sensitivity of the photosensitive resin composition. As the oxime ester compound, a compound having a partial structure represented by the following formula (c1) is preferable.

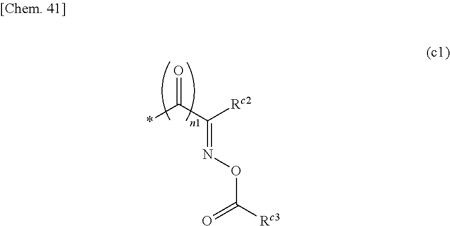

In the formula (c1), n1 is 0 or 1. R^{c2} is a monovalent organic group. R^{c3} is a hydrogen atom, an aliphatic hydrocarbon group having 1 or more and 20 or less carbon atoms which may have a substituent, or an aryl group which may have a substituent. * is a bonding hand.

The content of the photoradical polymerization initiating agent (C) in the photosensitive resin composition is not particularly limited as long as the photosensitive resin composition has desired photolithographic properties. The content of the photoradical polymerization initiating agent (C) in the photosensitive resin composition is typically preferably 0.01 parts by mass or more and 20 parts by mass or less, more preferably 0.1 parts by mass or more and 15 parts by mass or less, and further preferably 1 part by mass or more and 10 parts by mass or less with respect to the total 100 parts by mass of the mass of the resin (A) and the mass of the monomer compound (B).

### <Thiol Compound (D)>

The photosensitive resin composition may include a thiol compound (D). Consequently, a polyimide resin having excellent elongation and tensile strength is easily formed using the photosensitive resin composition. The number of mercapto groups in the thiol compound (D) is not particularly limited. The number of mercapto groups in the thiol compound (D) is preferably 2 or more, more preferably 2 or more and 10 or less, and further preferably 2 or more and 6 or less.

Specific examples of the compound having two or more mercapto groups include 1,2-benzenedithiol, 1,3-benzenedithiol, 1,4-benzenedithiol, 1,2-bis(mercaptomethyl)benzene, 1,3-bis(mercaptomethyl)benzene, 1,4-bis(mercaptomethyl)benzene, 1,2-bis(mercaptoethyl)benzene, 1,3-bis(mercaptoethyl)benzene, 1,4-bis(mercaptoethyl)benzene, 1,2,3-trimercaptobenzene, 1,2,4-trimercaptobenzene, 1,3,5-trimercaptobenzene, 1,2,3-tris(mercaptomethyl)benzene, 1,2,4-tris(mercaptomethyl)benzene, 1,3,5-tris(mercaptomethyl)benzene, 1,2,3-tris(mercaptoethyl)benzene, 1,2,4-tris(mercaptoethyl)benzene, 1,3,5-tris(mercaptoethyl)benzene, 2,5-toluenedithiol, 3,4-toluenedithiol, 1,3-di(p-methoxyphenyl)propane-2,2-dithiol, 1,3-diphenylpropane-2,2-dithiol, phenylmethane-1,1-dithiol, 2,4-di(p-mercaptophenyl)pentane, 1,2-bis(mercaptoethylthio)benzene, 1,3-bis(mercaptoethylthio)benzene, 1,4-bis(mercaptoethylthio)benzene, 1,2,3-tris(mercaptomethylthio)benzene, 1,2,4-tris(mercaptomethylthio)benzene, 1,3,5-tris(mercaptomethylthio)benzene, 1,2,3-tris(mercaptoethylthio)benzene, 1,2,4-tris(mercaptoethylthio)benzene, and 1,3,5-tris(mercaptoethylthio)benzene.

The thiol compound (D) having two or more mercapto groups is preferably a mercaptoalkanoate of polyol having two or more hydroxy groups, from the viewpoint of easiness of obtaining or synthesis or the viewpoint of solubility stability in a curable composition. The mercaptoalkanoate of polyol having two or more hydroxy groups may have a hydroxy group but preferably does not have a hydroxy group.

The number of carbon atoms of a mercaptoalkanoic acid that gives the mercaptoalkanoate is not particularly limited, but is preferably 2 or more and 6 or less or preferably 3 or 4. Specific examples of the mercaptoalkanoic acid that gives the mercaptoalkanoate include thioglycolic acid, 2-mercaptopropionic acid, 3-mercaptopropionic acid, 2-mercaptobutanoic acid, 3-mercaptobutanoic acid, 4-mercaptobutanoic acid, 2-mercaptopentanoic acid, 3-mercaptopentanoic acid, 4-mercaptopentanoic acid, 5-mercaptopentanoic acid, 2-mercaptohexanoic acid, 3-mercaptohexanoic acid, 4-mercaptohexanoic acid, and 5-mercaptohexanoic acid. Among these, 2-mercaptopropionic acid and 3-mercaptobutanoic acid are preferable.

The polyol that gives the mercaptoalkancate may include an aromatic group. Examples of the polyol not including an aromatic group include ethylene glycol, 1,3-propanediol, propylene glycol, 1,4-butanediol, 1,5-pentanediol, 1,6-hexanediol, 1,7-heptanediol, 1,8-octanediol, 1,9-nonanediol, 1,10-decanediol, diethylene glycol, triethylene glycol, tetraethylene glycol, dipropylene glycol, tripropylene glycol, tetrapropylene glycol, 1,4-cyclohexanediol, 1,3-cyclohexanediol, 1,2-cyclohexanediol, 1,4-cyclohexanedimethanol, hydrogenated bisphenol A, glycerin, diglycerin, triglycerin, trimethylolethane, trimethylolpropane, pentaerythritol, dipentaerythritol, sorbitol, mannitol, sorbitan, sucrose, glucose, mannose, methyl glucoside, and tris(2-hydroxyethyl)isocyanuric acid. Examples of aromatic polyol include a benzenediol, such as hydroquinone, resorcinol, and catechol; a benzenetriol, such as phloroglucinol, pyrogallol, and 1,2,4-benzenetriol; a naphthalenediol, such as 1,2-naphthalenediol, 1,3-naphthalenediol, 1,4-naphthalenediol, 1,5-naphthalenediol, 1,6-naphthalenediol, 1,7-naphthalenediol, 1,5-naphthalenediol, 2,3-naphthalenediol, 2,6-naphthalenediol, and 2,7-naphthalenediol; a naphthalenetriol, such as 1,4,5-naphthalenetriol, 1,2,4-naphthalenetriol, 1,3,8-naphthalenetriol, and 1,2,7-naphthalenetriol; a bisphenol, such as bisphenol A, bisphenol AP, bisphenol AF, bisphenol B, bisphenol BP, bisphenol C, bisphenol E, bisphenol F, bisphenol S, and bisphenol Z; a tetrahydroxybiphenyl, such as 3,3′,4,4′-tetrahydroxybiphenyl, and 3,3′,5,5′-tetrahydroxybiphenyl; calixarene; a novolac resin, such as phenol novolac, cresol novolac, and naphthol novolac.

Among the above-mentioned polyols, ethylene glycol, 1,3-propanediol, propylene glycol, 1,4-butanediol, 1,5-pentanediol, 1,6-hexanediol, diethylene glycol, dipropylene glycol, glycerin, diglycerin, trimethylolethane, trimethylolpropane, pentaerythritol, dipentaerythritol, and tris(2-hydroxyethyl)isocyanuric acid are preferable, and 1,4-butanediol, trimethylolethane, trimethylolpropane, pentaerythritol, and tris(2-hydroxyethyl)isocyanuric acid are more preferable.

As the mercaptoalkanoate of the polyol described above, 1,4-butanediol di(2-mercaptopropionate), 1,4-butanediol di(3-mercaptobutanoate), trimethylolethane tri(2-mercaptopropionate), trimethylolethane tri(3-mercaptobutanoate), trimethylolpropane tri(2-mercaptopropionate), trimethylolpropane tri(3-mercaptobutanoate), pentaerythritol tetra(2-mercaptopropionate), pentaerythritol tetra(3-mercaptobutanoate), tris(2-hydroxyethyl)isocyanuric acid tri(2-mercaptopropionate), and tris(2-hydroxyethyl)isocyanuric acid tri(3-mercaptobutanoate) are preferable, and 1,4-butanediol di(3-mercaptobutanoate), trimethylolethane tri(3-mercaptobutanoate), trimethylolpropane tri(3-mercaptobutanoate), pentaerythritol tetra(3-mercaptobutanoate), and tris(2-hydroxyethyl)isocyanuric acid tri(3-mercaptobutanoate) are more preferable.

The amount of the thiol compound (D) to be used is not particularly limited as long as the purpose of the present invention is not inhibited. The amount of the thiol compound (D) to be used is preferably 0.1 parts by mass or more and 20 parts by mass or less, more preferably 0.5 parts by mass or more and 15 parts by mass or less, and further preferably 1 part by mass or more and 12 parts by mass or less per 100 parts by mass of the sum of the mass of the resin (A) and the mass of the monomer compound (B).

### <Solvent(S)>

The photosensitive resin composition usually includes a solvent(S) for the purpose of adjusting coating properties and the like. The type of solvent(S) is not particularly limited as long as it dissolves the resin (A) and other components well. As the solvent(S), an organic solvent is usually used.

In view of the good solubility of the resin (A), specific examples of the solvent(S) include nitrogen-containing polar solvents such as N,N-dimethylformamide, N,N-dimethylacetamide, N,N-diethylformamide, N-methyl-2-pyrrolidone, N-ethyl-2-pyrrolidone, hexamethylphosphoramide, 1,3-dimethyl-2-imidazolidinone, N,N-dimethylisobutyric acid amide, 3-methoxy-N,N-dimethylpropionamide, 3-butoxy-N,N-dimethylpropionamide, N,N-dimethylpropionamide, N,N-dimethylisobutyramide, N,N-dimethylpropylene urea; ketones such as acetone, methyl ethyl ketone, methyl isobutyl ketone, 2-heptanone, 3-heptanone, diisobutyl ketone, cyclopentanone, cyclohexanone, and isophorone; esters such as γ-butyrolactone, γ-valerolactone, δ-valerolactone, γ-caprolactone, ε-caprolactone, α-methyl-γ-butyrolactone, methyl lactate, ethyl lactate, methyl acetate, ethyl acetate, n-propyl acetate, n-butyl acetate, isobutyl acetate, isopentyl acetate, n-pentyl formate, n-butyl propionate, isopropyl butyrate, ethyl butyrate, n-butyl butyrate, methyl methoxy acetate, ethyl methoxy acetate, n-butyl methoxy acetate, methyl ethoxy acetate, ethyl ethoxy acetate, methyl 3-methoxypropionate, ethyl 3-methoxypropionate, methyl 3-ethoxypropionate, ethyl 3-ethoxypropionate, methyl 2-methoxypropionate, ethyl 2-methoxypropionate, methyl 2-ethoxypropionate, ethyl 2-ethoxypropionate, methyl 2-methoxy-2-methylpropionate, methyl 2-ethoxy-2-methylpropionate, methyl pyruvate, ethyl pyruvate, n-propyl pyruvate, methyl acetoacetate, ethyl acetoacetate, methyl 2-oxobutanoate, ethyl 2-oxobutanoate, propylene glycol monomethyl ether acetate, propylene glycol monoethyl ether acetate, propylene glycol monopropyl ether acetate, 3-methyl-3-methoxybutyl acetate, methyl cellosolve acetate, and ethyl cellosolve acetate; alcohol such as diacetone alcohol and 3-methyl-3-methoxybutanol; glycol ethers such as ethylene glycol monomethyl ether, ethylene glycol monoethyl ether, propylene glycol monomethyl ether, propylene glycol monoethyl ether, diethylene glycol monomethyl ether, diethylene glycol monoethyl ether, diethylene glycol mono-n-butyl ether, and diethylene glycol dimethyl ether; aromatic ethers such as anisole; cyclic ethers such as dioxane and tetrahydrofuran; cyclic esters such as ethylene carbonate and propylene carbonate; aromatic solvents such as anisole, toluene, and xylene; aliphatic hydrocarbons such as limonene; sulfoxides such as dimethyl sulfoxide.

The amount of the solvent(S) used is not particularly limited as long as a uniform liquid photosensitive resin composition can be prepared. The photosensitive resin composition may be in the form of a suspension or a solution, and is preferably a solution. Typically, the solvent(S) is used such that the solid content concentration of the photosensitive resin composition is preferably 15% by mass or more and 50% by mass or less, and more preferably 20% by mass or more and 45% by mass or less,

### <Other Ingredients>

The photosensitive resin composition may contain various additive agents other than the components described above, if necessary. Examples of the additive agents include coloring agents, dispersing agents, sensitizing agents, adhesion promoting agents, polymerization inhibitors, anti-oxidizing agents, ultraviolet absorbers, anti-aggregation agents, antifoaming agents, surface active agents, imidization promoting agents, nitrogen-containing heterocyclic compounds as adhesion promoters, silane coupling agents and the like. Moreover, the photosensitive resin composition may contain various fillers or reinforcing materials as necessary.

As the sensitizing agent, well-known compounds can be used. Examples of the sensitizing agent include bis(dimethylamino)benzophenone, bis(diethylamino)benzophenone, diethylthioxanthone, N-phenyldiethanolamine, N-phenylglycine, 7-diethylamino-3-benzoylcoumarin, 7-diethylamino-4-methyl coumarin, N-phenylmorpholine, and derivatives thereof.

As the polymerization inhibiting agent, well-known compounds can be used. Examples of the polymerization inhibiting agent include compounds having a phenolic hydroxyl group, nitroso compounds, N-oxide compounds, quinone compounds, N-oxyl compounds, and phenothiazine compounds. More specifically, as the polymerization inhibiting agents, Irganox1010, Irganox1035, Irganox1098, Irganox1135, Irganox245, Irganox259, Irganox3114, (all manufactured by BASF Japan), 2,6-di-tert-butyl-p-cresol, and 4-methoxyphenol are preferred, and Irganox 1010, 2,6-di-tert-butyl-p-cresol, and 4-methoxyphenol are more preferred.

When the photosensitive resin composition includes a photoradical polymerization initiating agent (C), from the viewpoint of achieving both excellent developability of the photosensitive resin composition and good antioxidant effect, the amount of the polymerization inhibitor used is preferably 0.005% by mass or more and 1% by mass or less, more preferably 0.01% by mass or more and 0.5% by mass or less, and 0.03% by mass or more and 0.3% by mass or less with respect to the mass of the resin (A).

The nitrogen-containing heterocyclic compound coordinates and stabilizes a metal surface, thereby improving the adhesion of the resin film formed using the photosensitive resin composition to the metal surface. As the nitrogen-containing heterocyclic compound, well-known compounds can be used. Examples of the nitrogen-containing heterocyclic compound include imidazole, pyrazole, indazole, carbazole, triazole, pyrazoline, pyrazolidine, tetrazole, pyridine, piperidine, pyrimidine, pyrazine, triazine, cyanuric acid, isocyanuric acid, and derivatives thereof. Specific examples of nitrogen-containing heterocyclic compounds preferred from the viewpoint of coordination with metals include triazoles such as 1H-benzotriazole, 4-methyl-1H-methylbenzotriazole, 5-methyl-1H-methylbenzotriazole, 4-carboxy-1H-methylbenzotriazole, and 5-carboxy-1H-methylbenzotriazole, and tetrazoles such as 1H-tetrazole, 5-methyl-1H-tetrazole, and 5-phenyl-1H-tetrazole.

From the viewpoint of achieving both excellent developability of the photosensitive resin composition and improvement of the adhesion of the polyimide resin film formed using the photosensitive resin composition to the substrate, and the like, the amount of the nitrogen-containing heterocyclic compound used is preferably 0.01% by mass or more and 5% by mass or less, more preferably 0.05% by mass or more and 3% by mass or less, with respect to the mass of the resin (A).

By blending a silane coupling agent into a photosensitive resin composition, adhesion of a resin film formed using the photosensitive resin composition to a substrate or the like can be improved. As the silane coupling agent, known compounds can be used. Examples of the silane coupling agent include 3-aminopropyltrimethoxysilane, 3-aminopropyltriethoxysilane, vinyltrimethoxysilane, vinyltriethoxysilane, 3-mercaptopropyltrimethoxysilane, 3-mercaptopropyltriethoxysilane, 3-glycidoxypropyltrimethoxysilane, 3-glycidoxypropyltriethoxysilane, 2-(epoxycyclohexyl)ethyltrimethoxysilane, 2-(epoxycyclohexyl)triethoxysilane, tris(3-trimethoxysilylpropyl)isocyanurate, tris(3-triethoxysilylpropyl)isocyanurate, a reactant of 3-aminopropyltrimethoxysilane and an acid anhydride, a reactant of 3-aminopropyltriethoxysilane and an acid anhydride, and the like. Examples of the acid anhydrides to be reacted with 3-aminopropyltrimethoxysilane or 3-aminopropyltriethoxysilane include succinic anhydride, maleic anhydride, nadic anhydride, 3-hydroxyphthalic anhydride, pyromellitic dianhydride, 3,3′,4,4′-biphenyltetracarboxylic dianhydride, 2,2′,3,3′-benzophenonetetracarboxylic dianhydride, 4,4′-oxydiphthalic dianhydride, and the like.

The amount of the silane coupling agent used is preferably 0.01% by mass or more and 10% by mass or less with respect to the mass of the resin (A).

By blending a surface active agent into a photosensitive resin composition, the coatability of the photosensitive resin composition is improved, and the wettability of the photosensitive resin composition with a substrate is also improved. As the surface active agent, well-known compounds can be used. Examples of the surface active agent include fluorine surface active agents, nonionic surface active agents, cationic surface active agents, anionic surface active agents, silicone surface active agents, and the like.

The amount of the surface active agent used is preferably 0.001% by mass or more and 1% by mass or less with respect to the mass of the resin (A).

Polymerizable resin (A) can be converted into polyimide resin by heating. Accordingly, the photosensitive resin composition may contain a cyclization accelerator. The cyclization accelerator promotes the production of a polyimide resin by cyclizing a polyamide resin including a structural unit derived from a polyamic acid or a dicarboxylic acid compound that can be synthesized by a reaction between a tetracarboxylic dianhydride and an alcohol. When the photosensitive resin composition includes a cyclization accelerator, the mechanical properties and weather resistance reliability of a resin film formed using the photosensitive resin composition while producing a polyimide resin through cyclization are improved. As the cyclization accelerator, well-known thermal base generating agents and thermal acid generating agents are used.

The amount of each additive agents used is not particularly limited as long as it does not impede the purpose of the present invention. Additive agents with an amount to be used not listed above may be adjusted appropriately within the range of, for example, 0.001% by mass or more and 60% by mass or less, and preferably 0.01% by mass or more and 5% by mass or less, with respect to the mass of the solid content of the photosensitive resin composition.

### <Method for Preparing Photosensitive Resin Composition>

A photosensitive resin composition can be prepared by uniformly mixing the above-described essential components and, if necessary, arbitrary components in desired amounts. The mixing method is not particularly limited. For the purpose of removing foreign substances in the photosensitive resin composition, it is preferable to filter the photosensitive resin composition using a filter,

### <<Photosensitive Dry Film>>

A photosensitive dry film includes a substrate film, and a photosensitive layer formed on the surface of the substrate film. The photosensitive layer is made of the aforementioned photosensitive resin compositions.

As the substrate film, a film having optical transparency is preferable. Specific examples thereof include a polyethylene terephthalate (PET) film, a polypropylene (PP) film, a polyethylene (PE) film, and the like. In view of excellent balance between the optical transparency and the breaking strength, a polyethylene terephthalate (PET) film is preferable.

The aforementioned photosensitive resin composition is applied on the substrate film to form a photosensitive layer, and thereby a photosensitive dry film is produced. When the photosensitive layer is formed on the substrate film, a photosensitive resin composition is applied and dried on the substrate film using an applicator, a bar coater, a wire bar coater, a roller coaster, a curtain flow coater, and the like, so that a film thickness after drying is preferably 0.5 μm or more and 300 μm or less, more preferably 1 μm or more and 300 μm or less, and particularly preferably 3 μm or more and 100 μm or less.

The photosensitive dry film may include a protective film on the photosensitive layer. Examples of the protective film include a polyethylene terephthalate (PET) film, a polypropylene (PP) film, a polyethylene (PE) film, and the like.

### <<Resin Film Forming Method>>

By a method including applying a photosensitive resin composition on a substrate to form a coating film; and drying the coating film to obtain a resin film, a resin film including the polyimide resin precursor described above can be formed.

The substrate is not particularly limited, and any conventionally known substrate can be used, and examples thereof include a substrate for electronic components, a substrate on which a predetermined wiring pattern is formed, and the like. As the substrate, a silicon substrate, a glass substrate, and the like, can also be used.

A coating film having a desired thickness is formed by applying a liquid photosensitive resin composition onto a substrate to form a coating film, and then removing a solvent from the applied photosensitive resin composition. A thickness of the coating film is not particularly limited, but is preferably 0.5 μm or more, more preferably 0.5 μm or more and 300 μm or less, particularly preferably 1 μm or more and 150 μm or less, and most preferably 3 μm or more and 100 μm or less.

As a method for applying the photosensitive resin composition onto the substrate, methods such as a spin coating method, a slit coating method, a roll coating method, a screen printing method, an applicator method, and the like, can be employed.

The method of drying the photosensitive resin composition applied onto the substrate is not particularly limited. Preferably, drying is carried out by heating. The heating conditions during drying vary depending on the type of each component in the photosensitive resin composition, blending ratio, coating film thickness, and the like, but are usually 70° C. or more and 200° C. or less, and preferably 80° C. or more and 150° C. or less, and the time is about 2 minutes or more and 120 minutes or less. As mentioned above, a resin film including the polyimide resin precursor described above is formed.

### <<Method for Forming Patterned Resin Film>>

A patterned resin film is formed by a method including: applying the photosensitive resin composition described above on a substrate to form a coating film;
exposing by position-selectively irradiating the coating film with active rays or radiation; and
developing the exposed coating film to obtain a patterned resin film. The patterned resin film includes the above-mentioned polyimide resin precursor.

The substrate and the method of applying the photosensitive resin composition are as described above for the resin film forming method. The photosensitive resin composition applied onto the substrate is usually dried to form a coating film. The method for drying the photosensitive resin composition applied onto the substrate is not particularly limited. Preferably, drying is performed by heating. The heating conditions during drying vary depending on the type of each component in the photosensitive resin composition, blending ratio, coating film thickness, and the like, but are usually 70° C. or more and 200° C. or less, and preferably 80° C. or more and 150° C. or less, and the time is about 2 minutes or more and 120 minutes or less.

The coating film formed as described above is exposed by irradiating active ray or radiation in a position-selective manner. Position-selective exposure is usually performed by position-selectively irradiating active ray or radiation, such as ultraviolet rays or visible rays having a wavelength of 300 nm or more and 500 nm or less, through a mask with a predetermined pattern.

As a radiation source, a low-pressure mercury lamp, a high-pressure mercury lamp, an ultra-high-pressure mercury lamp, a metal halide lamp, an argon gas laser, and the like, can be used. Furthermore, radiation includes microwaves, infrared rays, visible rays, ultraviolet rays, X-rays, γ-rays, electron beams, proton beams, neutron beams, ion beams, and the like. The irradiation amount of radiation varies depending on the composition of the resin film-forming photosensitive resin, the thickness of the photosensitive layer, and the like, but, for example, in the case of using an ultra-high pressure mercury lamp, the amount of irradiation is 100 mJ/cm² or more and 10000 mJ/cm² or less.

Next, the exposed coating film is developed according to a conventionally known method, and unnecessary portions are dissolved and removed, thereby forming a resin film patterned into a predetermined shape. At this time, a developing solution depending on the components contained in the photosensitive resin composition is used. When the above-mentioned polyimide resin precursor is a resin having an alkali-soluble group such as a carboxyl group, an alkaline aqueous solution can be used as the developing solution. Moreover, the above-mentioned solvent (S) can be used as the developing solution.

As alkaline developing solutions, an aqueous solution of an alkali such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide (tetramethylammonium hydroxide), tetraethylammonium hydroxide, pyrrole, piperidine, 1,8-diazabicyclo[5,4,0]-7-undecene, and 1,5-diazabicyclo[4,3,0]-5-nonane can be used. Furthermore, an aqueous solution obtained by adding an appropriate amount of a water-soluble organic solvent such as methanol or ethanol or a surface active agent to the aqueous solution of the above-mentioned alkali can also be used as the developing solution.

The development time varies depending on the composition of the photosensitive resin composition, the thickness of the coating film, and the like, but is usually 1 minute or more and 30 minutes or less. The developing method may be any of a liquid filling method, a dipping method, a paddle method, a spray developing method, and the like.

After development, washing is carried out for 30 seconds or more and 90 seconds or less, if necessary, and the patterned resin film is dried using an air gun, an oven, or the like. In this way, a resin film patterned into a desired shape is formed on the surface of the substrate. The cleaning solvent is not particularly limited. As an example, water, alcohol, or the like, can be used as a washing solvent in the case of alkaline development. When developing is carried out with a solvent(S), the solvent(S) can be used as long as solvent shock does not occur.

The polyimide resin precursor included in the resin film can be imidized by heating. Therefore, after development, the polyimide resin precursor in the resin film can be imidized by baking the developed coating film if necessary. The conditions for converting the polyimide resin precursor into polyimide resin by heating are as described above. Furthermore, baking is preferably carried out in an atmosphere of an inert gas such as nitrogen or argon from the viewpoint of preventing oxidation of the resin film and obtaining a resin film with good mechanical properties.

The patterned polyimide resin film formed as described above can be suitably used, for example, as an insulating film for semiconductor devices, an interlayer insulating film for rewiring layers, an insulating film or a protective film in touch panel displays, organic electroluminescent display panels, and the like. Since the photosensitive resin composition described above has good resolution, the patterned resin film formed as described above can be preferably used for particularly as an interlayer insulating film for a rewiring layer in a three-dimensional mounting device and the like. Furthermore, the patterned resin film formed as described above can be suitably used as a photoresist for electronics, galvanic (electrolytic) resist, etching resist, solder top resist, and the like. Furthermore, the patterned resin film formed as described above can also be used for manufacturing printing plates such as an offset printing plate or a screen printing plate, for forming etching masks in etching a molded component, and for manufacturing a protective lacquer in an electronic component, particularly a microelectronic component, a dielectric layer, and the like.

As described above, the present inventors provide the following (1) to (8).

(1) A polyimide resin precursor comprising a structural unit represented by the following formula (1):

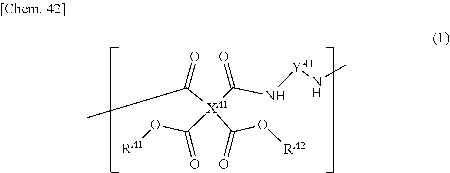

wherein, in the formula (1), X^{A1} and Y^{A1} are organic groups having 4 or more and 40 or less carbon atoms,
R^{A1} and R^{A2} are each independently a hydrogen atom or an organic group having 1 or more and 30 or less carbon atoms, and the organic group as R^{A1} or R^{A2} bonds to an oxygen atom in an ester bond in the formula (1) through a C—O bond,
having the organic group as R^{A1} or R^{A2}, an unsaturated group G1 having 3 or more and 30 or less carbon atoms that does not include a (meth)acryloyl group but includes one or more ethylenically unsaturated double bonds as the organic group as R^{A1} or R^{A2}, and
optionally having a (meth)acryloyl group-containing group G2 as the organic group as R^{A1} or R^{A2}, and
wherein a proportion of a sum of a number of moles of the unsaturated group G1 and the number of moles of the (meth)acryloyl group-containing group G2 to the total number of moles of the organic groups as R^{A1} and R^{A2} in the whole structural units is 60 mol % or more, and
a proportion of a number of moles of the unsaturated group G1 to the total number of moles of the organic groups as R^{A1} and R^{A2} in the whole structural units is 10 mol % or more.
   (2) The polyimide resin precursor according to (1), including, as the unsaturated group G1, an unsaturated aliphatic hydrocarbon group having one or more ethylenically unsaturated double bonds and 5 or more and 30 or less carbon atoms.
   (3) The polyimide resin precursor according to (1) or (2), including, as Y^{A1}, a group represented by the following formula (A1-1):

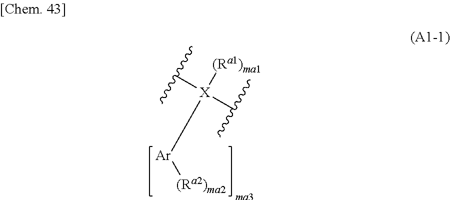

wherein, in the formula (A1-1), X is a tetravalent organic group, R^{a1} is a hydroxy group, a carboxy group, or a halogen atom, R^{a2} is an aliphatic group having 1 or more and 20 or less carbon atoms, a hydroxy group, a carboxy group, a sulfononic acid group, or a halogen atom, Ar is a phenyl group optionally substituted with R^{a2} or a naphthyl group optionally substituted with R^{a2}, ma1 is an integer of 0 or more and 10 or less, ma2 is an integer of 0 or more and 7 or less, and ma3 is an integer of 1 or more and 10 or less.
(4) The polyimide resin precursor according to (1) or (2), including, as YA, a divalent group having a partial structure represented by the following formula (A2-1):

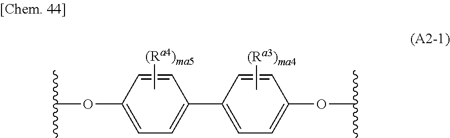

wherein, in the formula (A2-1), R^{a3} and R^{a4} are each independently an alkyl group having 1 or more and 4 or less carbon atoms, an alkoxy group having 1 or more and 4 or less carbon atoms, or a halogen atom, and ma4 and ma5 are each independently an integer of 0 or more and 4 or less.
(5) A photosensitive resin composition comprising a polymerizable resin (A), a photoradical polymerization initiating agent (C), and a solvent(S), in which the polymerizable resin (A) is the polyimide resin precursor according to any one of (1) to (4).
(6) A method for producing a patterned resin film, comprising forming a coating film by applying the photosensitive resin composition according to (5) onto a substrate, position-selectively exposing the coating film to light, and developing the exposed coated film.
(7) A method for producing a patterned polyimide resin film, comprising generating a polyimide resin derived from the polyimide resin precursor by heating the patterned resin film produced by the production method according to (6).

### EXAMPLES

Hereinafter, the present invention will be described in detail with reference to Examples, but the scope of the present invention is not limited to these Examples.

### Examples 1 to 21 and Comparative Examples 1 to 2

In Examples and Comparative Examples, the following DAI to DA4 were used as diamine compounds.

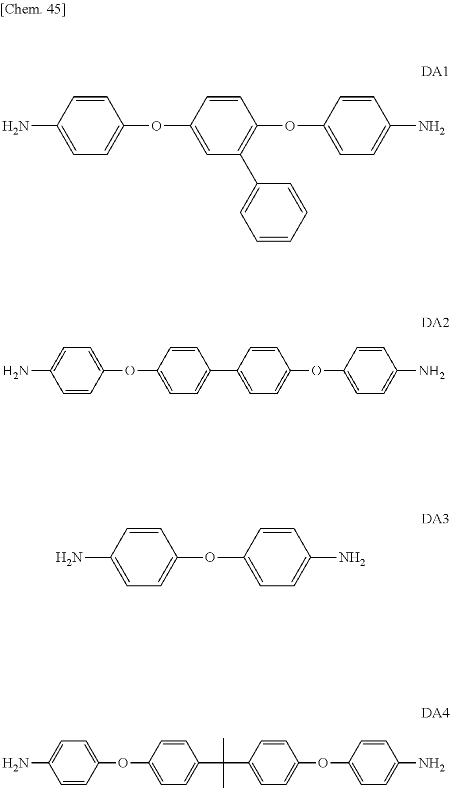 [SMILES: Nc1ccc(Oc2ccc(Oc3ccc(N)cc3)c(-c3ccccc3)c2)cc1 ; Nc1ccc(Oc2ccc(-c3ccc(Oc4ccc(N)cc4)cc3)cc2)cc1 ; Nc1ccc(Oc2ccc(N)cc2)cc1 ; CC(C)(c1ccc(Oc2ccc(N)cc2)cc1)c1ccc(Oc2ccc(N)cc2)cc1]

In Examples and Comparative Examples, the following TCI to TC3 were used as the tetracarboxylic dianhydride,

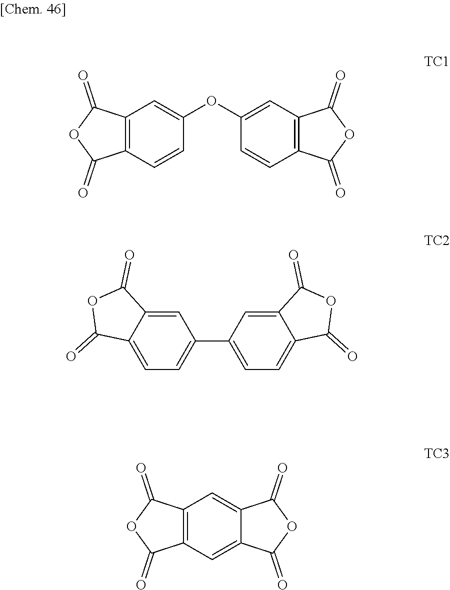 [SMILES: O=C1OC(=O)c2cc(Oc3ccc4c(c3)C(=O)OC4=O)ccc21 ; O=C1OC(=O)c2cc(-c3ccc4c(c3)C(=O)OC4=O)ccc21 ; O=c1oc(=O)c2cc3c(=O)oc(=O)c3cc12]

In Examples and Comparative Examples, with regard to an alcohol that is reacted with a tetracarboxylic acid dianhydride, as the above-described alcohol AG1 including the unsaturated group G1, the following A1 to A6 were used. As the above-described alcohol AG2 including the (meth)acryloyl group-containing group G2, the following M1 to M6 were used. As the alcohol AG3 that does not correspond to the alcohol AG1 and the alcohol AG2, the following B1 to B6 were used.
A1: pent-4-en-1-yl alcohol
A2: hex-5-en-1-yl alcohol
A3: dec-9-en-1-yl alcohol
A4: dec-4-en-1-yl alcohol
A5: octadec-9-en-1-yl alcohol (oleyl alcohol)
A6: octadeca-9,12-dien-1-yl alcohol (linoleyl alcohol)
M1:2-hydroxyethyl methacrylate
M2:2-hydroxypropyl methacrylate
M3:2-hydroxybutyl methacrylate
M4: glycerol 1,3-dimethacrylate
M5:1,4-cyclohexane dimethanol monoacrylate
M6:3-phenoxy-2-hydroxypropyl methacrylate
B1: n-dodecanol
B2: n-heptanol
B3: n-hexanol
B4: n-octadecanol
B5:2-ethylhexylalcohol
B6:2-dodecylhexadecanol

### (Production of Dicarboxylic Acid)

Tetracarboxylic dianhydride of the type listed in Table 1 in an amount of 0.1 mol was dissolved in 100 g of N-methyl-2-pyrrolidone (NMP). To the resulting solution, 0.2 mol of the type of alcohol listed in Table 1, 15.8 g (0.2 mol) of pyridine, and 2.4 g (0.02 mol) of dimethylaminopyridine were added. Next, the solution was stirred at 40° C. for 16 hours to obtain a dicarboxylic acid that is a reactant of tetracarboxylic dianhydride and alcohol.

### (Manufacture of Polyimide Resin Precursor)

A solution including 0.1 mol of the resulting dicarboxylic acid was cooled to 0° C. A condensing agent solution in which 43.3 g (0.21 mol) of dicyclohexylcarbodiimide was dissolved in 40 g of NMP and a diamine solution in which 0.1 mol of the diamine compound of the type listed in Table 1 was dissolved in 40 g of NMP were added dropwise to the cooled solution. After the dropwise addition was completed, the resulting reaction solution was stirred at room temperature for 4 hours to condense the dicarboxylic acid and the diamine compound. After the reaction was completed, 1.92 g of methanol was added to the reaction solution. After removing the settled byproducts by filtration, the filtrate including the polyimide resin precursor was added dropwise to a large amount of isopropyl alcohol aqueous solution. After the dropwise addition, the polyimide resin precursor precipitated in the aqueous solution in isopropyl alcohol was collected by filtration. The collected precipitate was washed three times with isopropyl alcohol. The precipitates after washing were dried under reduced pressure to obtain polyimide resin precursors for each Examples and Comparative Examples,

### (Production of Photosensitive Resin Composition)

A photosensitive resin composition of each of Examples and Comparative Examples was prepared by uniformly dissolving 100 parts by mass of the polyimide resin precursor, 3 parts by mass of a photoradical polymerization initiating agent (Ingacure OXE-02, manufactured by BASE Japan Ltd.), 5 parts by mass of a thiol compound (pentaerythritol tetrakis(3-mercaptobutyrate), KarenzMT (registered trademark) PEL, manufactured by Showa Denko K. K.), and 0.05 parts by mass of a surfactant (BYK 333, manufactured by BYK-Chemie) in N-ethyl-2-pyrrolidone such that the solid content concentration was 27% by mass.

A polyimide resin film was formed using the obtained photosensitive resin composition, and the dielectric loss tangent of the obtained polyimide resin film was evaluated according to the following method. Furthermore, the photolithographic properties of the obtained photosensitive resin composition were evaluated according to the following method. These evaluation results are shown in Table 1.

### <Evaluation of Dielectric Loss Tangent>

After applying the photosensitive resin composition onto a silicon wafer using a spin coater, the thin film of the photosensitive resin composition was baked at 90° C. for 240 seconds. The baked coating film was exposed using a high-pressure mercury lamp at a cumulative light intensity of 2000 mJ/cm². The exposed film was heated in an inert oven under a nitrogen atmosphere in which the temperature was increased to 230° C. at a temperature rising rate of 5° C./min, and the coated film was heated at the same temperature for 1 hour. When the temperature dropped to 100° C., the wafer was taken out and immersed in an aqueous solution of hydrofluoric acid with a concentration of 2% by mass for 5 minutes to 30 minutes, and the resin film was peeled from the wafer to obtain a polyimide resin film. A thickness of the resin film after peeling was 10 μm.

The dielectric loss tangent (tan 8) of the obtained film was measured by the methods described in the IEICE Technical Report of the Institute of Electronics, Information and Communication Engineers, vol. 118, no. 506, MW2018-158, pp. 13-18, March 2019, “Study on millimeter-wave complex permittivity evaluation using cavity resonator method” (Kohei Takahagi (Utsunomiya University), Kazuaki Ebisawa (Tokyo Ohka Kogyo Co., Ltd.), Yoshinori Furugami (Utsunomiya University), Takashi Shimizu (Utsunomiya University). Measurement was carried out using a network analyzer HP8510C (manufactured by Keysight) using a cavity resonator method under conditions of room temperature at 25° C., humidity of 50%, frequency of 36 GHz, and sample thickness of 10 μm. Based on the measured values of the dielectric loss tangent, the dielectric loss tangents were evaluated according to the following criteria.

Very good (indicated by bullseye symbol (⊙)): Dielectric loss tangent is less than 0.05.
Good (indicated by circle symbol (∘)): Dielectric loss tangent value is more than 0.05 and less than 0.07.
Poor (indicated by cross symbol (x)): Dielectric loss tangent value is 0.05 or more.

### <Evaluation of Photolithographic Properties>

The photolithographic properties of the photosensitive resin composition were verified by the following method. The photosensitive resin composition was applied onto a silicon wafer on which a copper sputtered film was formed with a spin coater. Thereafter, the film made of the photosensitive resin composition was baked at 80° C. for 300 seconds to obtain a coating film with a thickness of 14 μm. The coating film was exposed to light using a ghi line exposure machine (manufactured by Ultratech, Inc.) through a negative mask capable of forming a via hole with an opening diameter of 50 μm. The exposed coating film was immersed in cyclopentanone for 120 seconds, and development was performed thereon. In the results of the development, a case in which a pattern with desired size and shape was formed in an exposure dose range of 100 to 3,000 mJ/cm² was decided good (indicated by a circle symbol (∘)). A case in which a pattern with desired size and shape was not formed in an exposure dose range of 100 to 3,000 mJ/cm² was decided as poor (indicated by a cross symbol (x)),

TABLE 1

| | Polyimide resin precursor raw material | | | | | | | | | |
|---|---|---|---|---|---|---|---|---|---|---|
| | | Tetracarboxylic | Alcohol | | | | | | Photoli- | Dielectric |
| | Diamine | acid | AG1 | | AG2 | | AG3 | | thography | loss |
| | compound | dianhydride | Type | mol % | Type | mol % | Type | \|mol % | properties | tangent |
| Example 1 | DA2 | TC1 | A5 | 50 | M1 | 50 | — | — | ○ | ⊙ |
| Example 2 | DA2 | TC2 | A5 | 50 | M1 | 50 | — | — | ○ | ⊙ |
| Example 3 | DA1 | TC2 | A5 | 50 | M1 | 50 | — | — | ○ | ⊙ |
| Example 4 | DA3 | TC1 | A5 | 50 | M1 | 50 | — | — | ○ | ○ |
| Example 5 | DA4 | TC1 | A5 | 50 | M1 | 50 | — | — | ○ | ⊙ |
| Example 6 | DA3 | TC3 | A5 | 50 | M1 | 50 | — | — | ○ | ○ |
| Ezample 7 | DA1 | TC2 | A5 | 50 | M2 | 50 | — | — | ○ | ⊙ |
| Example 8 | DA1 | TC2 | A5 | 50 | M3 | 50 | — | — | ○ | ⊙ |
| Example 9 | DA1 | TC2 | A5 | 50 | M4 | 50 | — | — | ○ | ⊙ |
| Example 10 | DA1 | TC2 | A5 | 50 | M5 | 50 | — | — | ○ | ⊙ |
| Example 11 | DA1 | TC2 | A5 | 50 | M6 | 50 | — | — | ○ | ⊙ |
| Examole 12 | DA1 | TC2 | A5 | 30 | M1 | 70 | — | — | ○ | ⊙ |
| Example 13 | DA1 | TC2 | A5 | 10 | M1 | 90 | — | — | ○ | ○ |
| Example 14 | DA1 | TC2 | A1 | 50 | M1 | 50 | — | — | ○ | ○ |
| Example 15 | DA1 | TC2 | A2 | 50 | M1 | 50 | — | — | ○ | ○ |
| Example 16 | DA1 | TC2 | A3 | 50 | M1 | 50 | — | — | ○ | ⊙ |
| Example 17 | DA1 | TC2 | A4 | 50 | M1 | 50 | — | — | ○ | ⊙ |
| Example 18 | DA1 | TC2 | A6 | 50 | M1 | 50 | — | — | ○ | ⊙ |
| Example 19 | DA2 | TC1 | A4 | 100 | — | — | — | — | ○ | ⊙ |
| Examole 20 | DA2 | TC1 | A5 | 100 | — | — | — | — | ○ | ⊙ |
| Example 21 | DA2 | TC1 | A4 | 70 | M1 | 30 | — | — | ○ | ⊙ |
| Comparative | DA2 | TC1 | — | — | M1 | 50 | B5 | 50 | x | ⊙ |
| Example 1 | | | | | | | | | | |
| Comparative | DA2 | TC2 | — | — | M1 | 50 | B5 | 50 | x | ⊙ |
| Example 2 | | | | | | | | | | |
| Comparative | DA1 | TC2 | — | — | M1 | 50 | B5 | 50 | x | ⊙ |
| Example 3 | | | | | | | | | | |
| Comparative | DA3 | TC1 | — | — | M1 | 50 | B5 | 50 | x | ○ |
| Example 4 | | | | | | | | | | |
| Comparative | DA4 | TC1 | — | — | M1 | 50 | B5 | 50 | x | ⊙ |
| Example 5 | | | | | | | | | | |
| Comparative | DA3 | TC3 | — | — | M1 | 50 | B5 | 50 | x | ○ |
| Example 6 | | | | | | | | | | |
| Comparative | DA | TC2 | — | — | M2 | 50 | B5 | 50 | x | ⊙ |
| Example 7 | | | | | | | | | | |
| Comparative | DA1 | TC2 | — | — | M3 | 50 | B5 | 50 | x | ⊙ |
| Example 8 | | | | | | | | | | |
| Comparative | DA1 | TC2 | — | — | M4 | 50 | B5 | 50 | x | ⊙ |
| Example 9 | | | | | | | | | | |
| Comparative | DA1 | TC2 | — | — | M5 | 50 | B5 | 50 | x | ⊙ |
| Example 10 | | | | | | | | | | |
| Comparative | DA1 | TC2 | — | — | M6 | 50 | B5 | 50 | x | ⊙ |
| Example 11 | | | | | | | | | | |
| Comparative | DA1 | TC2 | — | — | M1 | 70 | B5 | 30 | x | ⊙ |
| Example 12 | | | | | | | | | | |
| Comparative | DA1 | TC2 | — | — | M1 | 90 | B5 | 10 | ○ | X |
| Example 13 | | | | | | | | | | |
| Comparative | DA1 | TC2 | — | — | M1 | 50 | B1 | 50 | x | ○ |
| Example 14 | | | | | | | | | | |
| Comparative | DA1 | TC2 | — | — | M1 | 50 | B2 | 50 | x | ○ |
| Example 15 | | | | | | | | | | |
| Comparative | DA1 | TC2 | — | — | M1 | 50 | B3 | 50 | x | ○ |
| Example 16 | | | | | | | | | | |
| Comparative | DA1 | TC2 | — | — | M1 | 50 | B4 | 50 | x | ⊙ |
| Example 17 | | | | | | | | | | |
| Comparative | DA1 | TC2 | — | — | M1 | 50 | B6 | 50 | x | ⊙ |
| Example 18 | | | | | | | | | | |
| Comparative | DA1 | TC2 | — | — | M1 | 100 | — | — | ○ | x |
| Example 20 | | | | | | | | | | |
| Comparative | DA3 | TC1 | — | — | M1 | 100 | — | — | ○ | x |
| Example 21 | | | | | | | | | | |

According to Examples, it is demonstrated that a polyimide resin precursor comprising a structural unit represented by the above-described formula (1) and including the above-described unsaturated group G1 and (meth)acryloyl group-containing group G2 in predetermined amounts as the organic groups as X^{A1} as Y^{A1} in the formula (1) gives a polyimide resin with a low dielectric loss tangent and a photosensitive resin composition with excellent photolithographic properties. In contrast, according to Comparative Examples, it is demonstrated that a polyimide resin precursor comprising a structural unit represented by the above-described formula (1) but not including the above-described unsaturated group G1 and (meth)acryloyl group-containing group G2 in predetermined amounts as the organic groups as X^{A1} and Y^{A1} in the formula (1) does not give a polyimide resin with a low dielectric loss tangent or does not give a photosensitive resin composition with excellent photolithographic properties.

1. A polyimide resin precursor comprising a structural unit represented by a following formula (1): 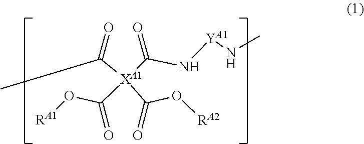
wherein, in the formula (1), X^{A1} and Y^{A1} are organic groups having 4 or more and 40 or less carbon atoms,
R^{A1} and R^{A2} are each independently a hydrogen atom or an organic group having 1 or more and 30 or less carbon atoms, and the organic group as R^{A1} or R^{A2} bonds to an oxygen atom in an ester bond in the formula (1) through a C—O bond,
having the organic group as R^{A1} or R^{A2}, an unsaturated group G1 having 3 or more and 30 or less carbon atoms that does not comprise a (meth)acryloyl group but comprises one or more ethylenically unsaturated double bonds,
optionally having a (meth)acryloyl group-containing group G2 as the organic group as R^{A1} or R^{A2},
wherein a proportion of a sum of a number of moles of the unsaturated group G1 and a number of moles of the (meth)acryloyl group-containing group G2 to a total number of moles of the organic groups as R^{A1} and R^{A2} in the whole structural units is 60 mol % or more, and
a proportion of the number of moles of the unsaturated group G1 to the total number of moles of the organic groups as R^{A1} and R^{A2} in the whole structural units is 10 mol % or more.

2. The polyimide resin precursor according to claim 1, comprising, as the unsaturated group G1, an unsaturated aliphatic hydrocarbon group having one or more ethylenically unsaturated double bonds and 5 or more and 30 or less carbon atoms.

3. The polyimide resin precursor according to claim 1, comprising, as the Y^{A1}, a group represented by a following formula (A1-1): 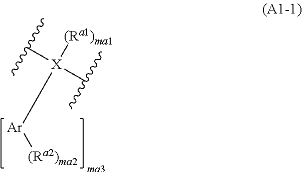
wherein, in the formula (A1-1), X is an organic group having a valence of (ma1+ma3+2), R^{a1} is a hydroxy group, a carboxy group, or a halogen atom, R^{a2} is an aliphatic group having 1 or more and 20 or less carbon atoms, a hydroxy group, a carboxy group, a sulfonic acid group, or a halogen atom, Ar is a phenyl group optionally substituted with R^{a2} or a naphthyl group optionally substituted with R^{a2}, ma1 is an integer of 0 or more and 10 or less, ma2 is an integer of 0 or more and 7 or less, and ma3 is an integer of 1 or more and 10 or less.

4. The polyimide resin precursor according to claim 1, comprising, as the Y^{A1}, a divalent group having a partial structure represented by a following formula (A2-1): 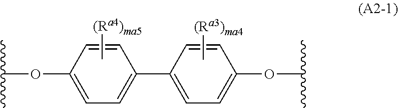
wherein, in the formula (A2-1), R^{a3} and R^{a4} are each independently an alkyl group having 1 or more and 4 or less carbon atoms, an alkoxy group having 1 or more and 4 or less carbon atoms, or a halogen atom, and ma4 and ma5 are each independently an integer of 0 or more and 4 or less.

5. A photosensitive resin composition comprising a polymerizable resin (A), a photoradical polymerization initiating agent (C), and a solvent(S), wherein the polymerizable resin (A) is the polyimide resin precursor according to claim 1.

6. A method for producing a patterned resin film, comprising forming a coating film by applying the photosensitive resin composition according to claim 5 onto a substrate, position-selectively exposing the coating film to light, and developing the exposed coated film.

7. A method for producing a patterned polyimide resin film, comprising generating a polyimide resin derived from the polyimide resin precursor by heating the patterned resin film produced by the production method according to claim 6.
